(19) United States
(12) Patent Application Publication
(10) Pub. No.: US 2015/0325768 A1
(43) Pub. Date: Nov. 12, 2015

(54) THERMOELECTRIC GENERATOR AND PRODUCTION METHOD FOR THE SAME

(71) Applicant: Panasonic Intellectual Property Management Co., Ltd., Osaka (JP)

(72) Inventors: Akihiro SAKAI, Nara (JP); Tsutomo KANNO, Kyoto (JP); Kohei TAKAHASHI, Osaka (JP); Hiromasa TAMAKI, Osaka (JP); Hideo KUSADA, Osaka (JP); Yuka YAMADA, Nara (JP)

(21) Appl. No.: 14/801,176

(22) Filed: Jul. 16, 2015

Related U.S. Application Data
(63) Continuation of application No. PCT/JP2014/001382, filed on Mar. 11, 2014.

(30) Foreign Application Priority Data
Mar. 12, 2013 (JP) 2013-049484

(51) Int. Cl. H01L 35/32; H01L 35/18; H01L 35/02; H01L 35/34

(52) U.S. Cl. CPC H01L 35/32; H01L 35/34; H01L 35/18; H01L 35/02

(57) ABSTRACT

The thermoelectric generator disclosed herein includes: a first and second electrode opposing each other; and a stacked body having a first and second principal face and a first and second end face, the first and second end face being located between the first and second principal face, and the first and second electrode being respectively electrically connected to the first and second end face. The stacked body is structured so that a plurality of first layers of a first material having a relatively low Seebeck coefficient and a relatively high thermal conductivity and a plurality of second layers of a second material having a relatively high Seebeck coefficient and a relatively low thermal conductivity are alternately stacked. The stacked body includes a carbon containing layer in at least one of the first and second principal face.

This is a continuation of International Application No. PCT/JP2014/001382, with an international filing date of Mar. 11, 2014, which claims priority of Japanese Patent Application No. 2013-049484, filed on Mar. 12, 2013, the contents of which are hereby incorporated by reference.

### BACKGROUND

1. Technical Field

The present application relates to a thermoelectric generator which converts heat into electric power. The present application also relates to a production method for the thermoelectric generator.

2. Description of the Related Art

A thermoelectric conversion element is an element which can convert heat into electric power, or electric power into heat. A thermoelectric conversion element made of a thermoelectric material that exhibits the Seebeck effect is able to obtain thermal energy from a heat source at a relatively low temperature (e.g., 200 degrees Celsius or less), and convert it into electric power. With a thermoelectric generation technique based on such a thermoelectric conversion element, it is possible to collect and effectively utilize thermal energy which would conventionally have been dumped unused into the ambient in the form of steam, hot water, exhaust gas, or the like.

Hereinafter, a thermoelectric conversion element which is made of a thermoelectric material may be referred to as a “thermoelectric generator”. A generic thermoelectric generator has a so-called “π structure” in which a p-type semiconductor and an n-type semiconductor of mutually different carrier electrical polarities are combined (for example, Japanese Laid-Open Patent Publication No. 2013-016685). In a “π structure” thermoelectric generator, a p-type semiconductor and an n-type semiconductor are connected electrically in series, and thermally in parallel. In a “π structure”, the direction of temperature gradient and the direction of electric current flow are parallel or antiparallel to each other. This makes it necessary to provide output terminals at the electrodes on the high-temperature heat source side or the low-temperature heat source side. Therefore, complicated wiring structure will be required for a plurality of thermoelectric generators each having a “π structure” to be connected in electrical series.

International Publication No. 2008/056466 (hereinafter “Patent Document 1”) discloses a thermoelectric generator which includes a stacked body sandwiched between a first electrode and a second electrode opposing each other, the stacked body including bismuth layers and metal layers of a different metal from bismuth being alternately stacked. In the thermoelectric generator disclosed in Patent Document 1, the planes of stacking are inclined with respect to the direction of a line connecting the first electrode and the second electrode. Moreover, tube-type thermoelectric generators are disclosed in International Publication No. 2012/014366 (hereinafter “Patent Document 2”) and Kanno et al., preprints from the 72^{nd} Symposium of the Japan Society of Applied Physics, 30a-F-14 “A Tubular Electric Power Generator Using Off-Diagonal Thermoelectric Effects” (2011) and A. Sakai et al., International conference on thermoelectrics 2012 “Enhancement in performance of the tubular thermoelectric generator (TTEG)” (2012).

### SUMMARY

There is a desire for a practical thermoelectric generator, thermoelectric generation unit, and system utilizing a thermoelectric generation technique.

A thermoelectric generator as one implementation of the present disclosure comprises: a first electrode and a second electrode opposing each other; and a stacked body having a first principal face and a second principal face and a first end face and a second end face, the first end face and the second end face being located between the first principal face and the second principal face, and the first electrode and the second electrode being respectively electrically connected to the first end face and the second end face, wherein, the stacked body is structured so that a plurality of first layers of a first material having a relatively low Seebeck coefficient and a relatively high thermal conductivity and a plurality of second layers of a second material having a relatively high Seebeck coefficient and a relatively low thermal conductivity are alternately stacked; planes of stacking of the plurality of first layers and the plurality of second layers are inclined with respect to a direction in which the first electrode and the second electrode oppose each other; the stacked body includes a carbon containing layer in at least one of the first principal face and the second principal face; and a potential difference occurs between the first electrode and the second electrode due to a temperature difference between the first principal face and the second principal face.

The thermoelectric generator according to the present disclosure provides an improved thermoelectric generation practicality.

These general and specific aspects may be implemented using a unit, a system, and a method, and any combination of units, systems, and methods.

Additional benefits and advantages of the disclosed embodiments will be apparent from the specification and Figures. The benefits and/or advantages may be individually provided by the various embodiments and features of the specification and drawings disclosure, and need not all be provided in order to obtain one or more of the same.

### BRIEF DESCRIPTION OF THE DRAWINGS

FIG. 1A is a schematic cross-sectional view of a thermoelectric generator 10.

FIG. 1B is an upper plan view of the thermoelectric generator 10 in FIG. 1A.

FIG. 2 is a diagram showing a state where a high-temperature heat source 120 is in contact with an upper face 10a of the thermoelectric generator 10, and a low-temperature heat source 140 is in contact with a lower face 10b.

FIG. 3 is a perspective view showing the schematic construction of a thermoelectric generation tube T.

FIG. 4A is a schematic cross-sectional view showing an embodiment of the thermoelectric generator according to the present disclosure.

FIG. 4B is another schematic cross-sectional view showing an embodiment of the thermoelectric generator according to the present disclosure.

FIG. 4C is a schematic cross-sectional view showing a thermoelectric generator having intermediate layers as underlying layers of carbon containing layers.

FIG. 4D is a schematic cross-sectional view of a thermoelectric generator 10M having a rectangular solid shape.

FIG. 5 includes (a) to (d), which are a side view, a cross-sectional view, an upper plan view, and a perspective view illustrating the shape of a compact from which a stacked body is made.

FIGS. 6A and 6B are step diagrams showing exemplary production steps for a thermoelectric generator.

FIG. 7A is a step diagram showing an exemplary production step for a thermoelectric generator. FIG. 7B is a schematic cross-sectional view thereof.

FIGS. 8A and 8B are step diagrams showing exemplary production steps for a thermoelectric generator.

FIG. 9A is a step diagram showing an exemplary production step for a thermoelectric generator. FIG. 9B is a schematic cross-sectional view thereof.

FIG. 10 is a step diagram showing an exemplary production step for a thermoelectric generator.

FIG. 11A is a diagram showing electric generation characteristics of thermoelectric generators according to Example and Reference Example. FIG. 11B shows electric generation characteristics of a thermoelectric generator according to Comparative Example.

FIG. 12 is a perspective view showing a schematic construction of an illustrative thermoelectric generation unit 100 according to an embodiment of the present disclosure.

FIG. 13 is a block diagram showing an exemplary construction for introducing a temperature difference between the outer peripheral surface and the inner peripheral surface of the thermoelectric generation tube T.

FIG. 14A is a perspective view showing one of thermoelectric generation tubes T included in the thermoelectric generation unit 100 (which herein is the thermoelectric generation tube T1). FIG. 14B is a diagram showing a schematic cross section of the thermoelectric generation tube T1 as viewed on a plane containing an axis (center axis) of the thermoelectric generation tube T1.

FIG. 15 is a diagram schematically showing an example of electrical connection of thermoelectric generation tubes T1 to T10.

FIG. 16A is a front view showing one implementation of a thermoelectric generation unit according to the present disclosure. FIG. 16B is a diagram showing one of the side faces of the thermoelectric generation unit 100 (shown herein is a right side view).

FIG. 17 is a diagram partially showing an M-M cross section in FIG. 16B.

FIG. 18 includes portions (a) and (b), where (a) is a diagram showing a schematic cross section of a portion of a plate 36, and (b) is a diagram showing the appearance of an electrically conductive member J1 as viewed in the direction indicated by the arrow V1 in portion (a).

FIG. 19A is an exploded perspective view schematically illustrating a channel C61 to house the electrically conductive member J1 and its vicinity. FIG. 19B is a perspective view showing a portion of the sealing surface of the second plate portion 36b (i.e., the surface that faces the first plate portion 36a) associated with openings A61 and A62.

FIG. 20A is a perspective view illustrating an exemplary shape of an electrically conductive ring member 56. FIG. 20B is a perspective view illustrating another exemplary shape of the electrically conductive ring member 56.

FIG. 21A is a schematic cross-sectional view showing the electrically conductive ring member 56 and the thermoelectric generation tube T1. FIG. 21B is a schematic cross-sectional view showing a state where an end of the thermoelectric generation tube T1 has been inserted into the electrically conductive ring member 56. FIG. 21C is a schematic cross-sectional view showing a state where an end of the thermoelectric generation tube T1 has been inserted into the electrically conductive ring member 56 and the electrically conductive member J1.

FIG. 22 is a diagram showing the other side face of the thermoelectric generation unit 100 shown in FIG. 16A (left side view).

FIG. 23 includes portions (a) and (b), where (a) is a diagram showing a schematic cross section of a portion of the plate 34, and (b) is a diagram showing the appearance of an electrically conductive member K1 as viewed in the direction indicated by the arrow V2 in portion (a).

FIG. 24 is an exploded perspective view showing a channel C41 to house the electrically conductive member K1 and its vicinity.

FIG. 25 is a schematic cross-sectional view showing an exemplary structure for separating the medium which flows in contact with the outer peripheral surfaces of the thermoelectric generation tubes T from the medium which flows in contact with the inner peripheral surface of each of the thermoelectric generation tubes T1 to T10 so as to prevent those media from mixing together.

FIG. 26A is a diagram showing an embodiment of a thermoelectric generation system according to the present disclosure. FIG. 26B is a cross-sectional view of the system taken along line B-B shown in FIG. 26A. FIG. 26C is a perspective view illustrating an exemplary construction for a buffer vessel included in the thermoelectric generation system shown in FIG. 26A.

FIG. 27A is a diagram showing another embodiment of a thermoelectric generation system according to the present disclosure. FIG. 27B is a cross-sectional view of the system taken along line B-B shown in FIG. 27A. FIG. 27C is a cross-sectional view of the system taken along line C-C shown in FIG. 27A.

FIG. 28A is a diagram showing still another embodiment of a thermoelectric generation system according to the present disclosure. FIG. 28B is a cross-sectional view of the system taken along line B-B shown in FIG. 28A.

FIG. 29A is a diagram showing yet another embodiment of a thermoelectric generation system according to the present disclosure. FIG. 29B is a cross-sectional view of the system taken along line B-B shown in FIG. 29A.

FIG. 30 is a diagram showing yet another embodiment of a thermoelectric generation system according to the present disclosure.

FIG. 31 is a block diagram showing an exemplary construction for an electric circuit in a thermoelectric generation system according to the present disclosure.

FIG. 32 is a block diagram showing an exemplary construction for an embodiment in which a thermoelectric generation system according to the present disclosure is used.

FIG. 33 is a diagram schematically showing an example of flow directions of a hot medium and a cold medium introduced in the thermoelectric generation unit 100.

FIG. 34A is a schematic cross-sectional view showing the electrically conductive ring member 56 and a portion of the electrically conductive member J1. FIG. 34B is a schematic cross-sectional view showing a state where elastic portions 56r of the electrically conductive ring member 56 have been inserted into a throughhole Jh1 of the electrically conductive member J1.

FIG. 35 is a schematic cross-sectional view of a thermoelectric generation tube having a chamfered portion Cm at an end.

FIG. 36A is a diagram schematically showing directions of an electric current flowing in thermoelectric generation tubes T which are connected in electrical series.

FIG. 36B is a diagram schematically showing directions of an electric current flowing in thermoelectric generation tubes T which are connected in electrical series.

FIG. 37 is a diagram schematically showing the directions of an electric current in two openings A61 and A62 and their surrounding region.

FIGS. 38A and 38B are perspective views each showing a thermoelectric generation tube, the electrodes of which have indicators of their polarity.

FIGS. 39A and 39B are cross-sectional views showing other exemplary structures for separating the hot medium and the cold medium from each other and electrically connecting the thermoelectric generation tube and the electrically conductive member together.

### DETAILED DESCRIPTION

As described above, the applicant of the present application discloses in Patent Documents 1 and 2 a thermoelectric generator having a stacked body that includes bismuth layers and metal layers of a different metal from bismuth, these layers being alternately stacked. In this thermoelectric generator, since the planes of stacking are inclined with respect to the direction of a line connecting the first electrode and the second electrode, the direction of temperature gradient and the direction in which an electric current flows can be made orthogonal, unlike in conventional thermoelectric generators. This permits a positioning of the high-temperature heat source and low-temperature heat source which was not easy for a thermoelectric generation system using conventional thermoelectric generators to attain, whereby a thermoelectric generation system that facilitates the use of the high-temperature heat source and low-temperature heat source is provided.

Prior to illustrating embodiments of the thermoelectric generator according to the present disclosure, The basic construction and operation principles of this thermoelectric generator will be described. As will be described later, the thermoelectric generator according to the present disclosure may permit easier use of the high-temperature heat source and low-temperature heat source when it is tubular. However, the operation principles of the tubular thermoelectric generator can be explained with respect to a thermoelectric generator of a simpler shape, and in fact be better understood when so explained.

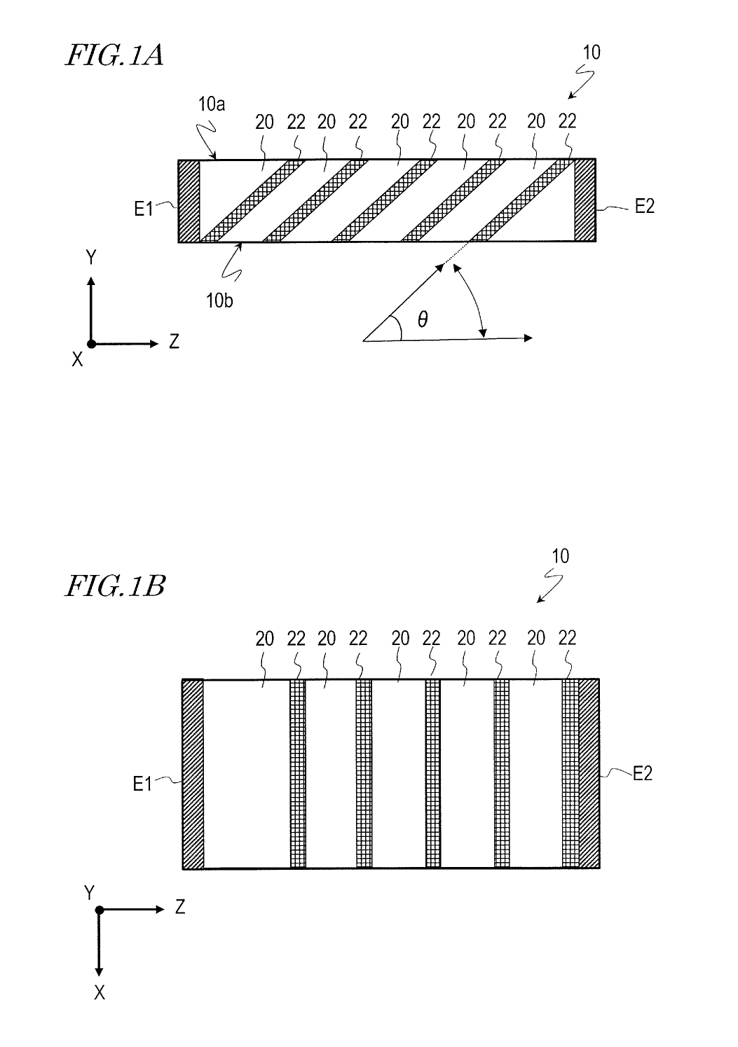

First, FIG. 1A and FIG. 1B will be referred to. FIG. 1A is a schematic cross-sectional view of a thermoelectric generator 10 having a generally rectangular solid shape, and FIG. 1B is an upper plan view of the thermoelectric generator 10. For reference sake, FIG. 1A and FIG. 1B show the X axis, the Y axis, and the Z axis, which are orthogonal to one another. The thermoelectric generator 10 shown in the figure is structured so that metal layers 20 and thermoelectric material layers 22 are alternately stacked (i.e., a stacked body) while being inclined. Although the shape of stacked body in this example is a rectangular solid, the same operation principles will also apply to other shapes.

In the thermoelectric generator 10 shown in the figure, a first electrode E1 and a second electrode E2 are provided in a manner of sandwiching the aforementioned stacked body on the left and on the right. In the cross section shown in FIG. 1A, the planes of stacking are inclined by an angle θ (0<θ<π radian) with respect to the Z-axis direction.

In the thermoelectric generator 10 having such a construction, when a temperature difference is introduced between the upper face 10a and the lower face 10b, heat propagates primarily through the metal layers 20 whose thermal conductivity is higher than that of the thermoelectric material layers 22, and thus a Z axis component occurs in the temperature gradient of each thermoelectric material layer 22. Therefore, an electromotive force along the Z-axis direction occurs in each thermoelectric material layer 22 due to the Seebeck effect, these electromotive forces being superposed in series within the stacked body. Consequently, as a whole, a large potential difference occurs between the first electrode E1 and the second electrode E2. A thermoelectric generator having the stacked body shown in FIG. 1A and FIG. 1B is disclosed in Patent Document 1. The entire disclosure of Patent Document 1 is incorporated herein by reference.

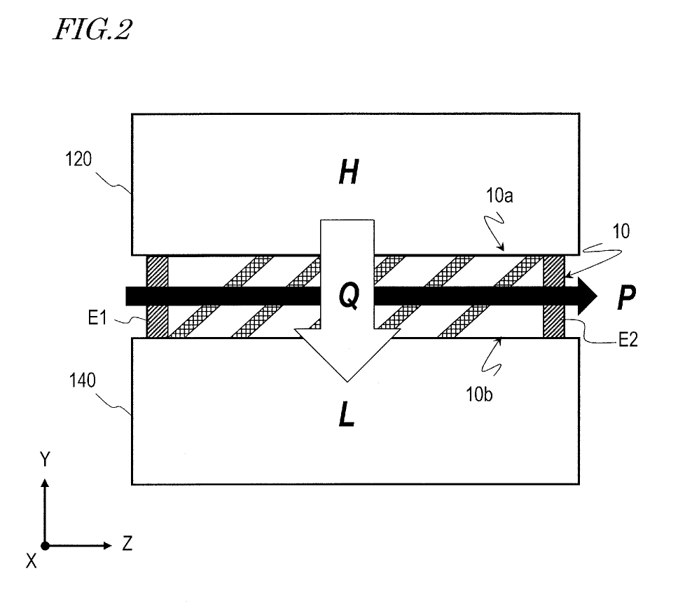

FIG. 2 shows a state where a high-temperature heat source 120 is in contact with the upper face 10a of the thermoelectric generator 10 and a low-temperature heat source 140 is in contact with the lower face 10b. In this state, heat Q flows from the high-temperature heat source 120 to the low-temperature heat source 140 via the thermoelectric generator 10, so that electric power P can be retrieved from the thermoelectric generator 10 via the first electrode E1 and the second electrode E2. From a macroscopic point of view, in the thermoelectric generator 10, the direction of temperature gradient (the Y-axis direction) and the direction of the electric current (the Z-axis direction) are orthogonal, so that there is no need to introduce a temperature difference between the pair of electrodes E1 and E2 for taking out electric power.

For simplicity, a case where the shape of the stacked body of the thermoelectric generator 10 is a rectangular solid has been described above; the following embodiments will be directed to exemplary thermoelectric generators in which the stacked body has a tubular shape. Such a tubular thermoelectric generator will sometimes be referred to as a “thermoelectric generation tube” in the present specification. In the present specification, the term “tube” is interchangeably used with the term “pipe”, and is to be interpreted to encompass both a “tube” and a “pipe”.

FIG. 3 is a perspective view showing an exemplary thermoelectric generation tube T. The thermoelectric generation tube T includes: a tube body Tb in which metal layers 20 and thermoelectric material layers 22, each having a throughhole in the center, are alternately stacked while being inclined; and a pair of electrodes E1 and E2. A method for producing such a thermoelectric generation tube T is disclosed in Patent Document 2, for example. According to the method disclosed in Patent Document 2, metal cups having a hole in the bottom and thermoelectric material cups similarly having a hole in the bottom are alternately stacked together, and subjected to plasma sintering in that state, whereby both are fastened together. The entire disclosure of Patent Document 2 is incorporated herein by reference.

The thermoelectric generation tube T of FIG. 3 is connected to conduits so that a hot medium, for example, flows in the flow path (which hereinafter may be referred to as the “internal flow path”) which is defined by the inner peripheral surface in its interior. In that case, the outer peripheral surface of the thermoelectric generation tube T is placed in contact with a cold medium. Thus, by introducing a temperature difference between the inner peripheral surface and the outer peripheral surface of the thermoelectric generation tube T, a potential difference occurs between the pair of electrodes E1 and E2, thereby enabling electric power to be retrieved.

When any reference is made to “high temperature” or “hot”, or a “low temperature” or “cold”, is made in the present specification, as in “hot medium” and “cold medium”, these terms indicate relatively highness or lowness of temperature between them, rather than any specific temperatures of these media. A “medium” is typically a gas, a liquid, or a fluid composed of a mixture thereof. A “medium” may contain solid, e.g., powder, which is dispersed within a fluid.

The shape of the thermoelectric generation tube T may be anything tubular, without being limited to cylindrical. In other words, when the thermoelectric generation tube T is cut along a plane which is perpendicular to the axis of the thermoelectric generation tube T, the resultant shapes created by sections of the “outer peripheral surface” and the “inner peripheral surface” do not need to be circles, but may be any closed curves, e.g., ellipses or polygons. Although the axis of the thermoelectric generation tube T is typically linear, it is not limited to being linear. These would be clear from the principles of thermoelectric generation which have been described with reference to FIG. 1A, FIG. 1B, and FIG. 2.

Thus, in accordance with the thermoelectric generation tube T disclosed in Patent Document 2, heat utilization occurs through contact of the tube body Tb including the thermoelectric material layers 22 with the hot medium and the cold medium, and the tube body Tb may serve as a partitioning wall between the hot medium and the cold medium. This enhances the efficiency of heat utility as compared to conventional thermoelectric generators.

However, when the tube body Tb comes in contact with the hot medium or the cold medium, if the medium is fluid, the tube body Tb will receive shear stress from the medium, such that the inner peripheral surface or the outer peripheral surface may be abraded. When the hot medium or the cold medium contains an impurity, the impurity may deposit on the inner peripheral surface or outer peripheral surface of the tube body Tb, thereby affecting the electric generation characteristics of the thermoelectric generation tube T and disturbing the medium flows, among other problems.

In view of such problems, the inventors have arrived at a novel thermoelectric generator and thermoelectric generation system. In outline, one implementation of the present disclosure is as follows.

A thermoelectric generator as one implementation of the present disclosure comprises: a first electrode and a second electrode opposing each other; and a stacked body having a first principal face and a second principal face and a first end face and a second end face, the first end face and the second end face being located between the first principal face and the second principal face, and the first electrode and the second electrode being respectively electrically connected to the first end face and the second end face, wherein, the stacked body is structured so that a plurality of first layers of a first material having a relatively low Seebeck coefficient and a relatively high thermal conductivity and a plurality of second layers of a second material having a relatively high Seebeck coefficient and a relatively low thermal conductivity are alternately stacked; planes of stacking of the plurality of first layers and the plurality of second layers are inclined with respect to a direction in which the first electrode and the second electrode oppose each other; the stacked body includes a carbon containing layer in at least one of the first principal face and the second principal face; and a potential difference occurs between the first electrode and the second electrode due to a temperature difference between the first principal face and the second principal face.

The stacked body may include a semiconductor layer or an insulator layer in at least a portion of an underlying layer of the carbon containing layer.

The first principal face and the second principal face may be planes, and the stacked body may have a rectangular solid shape.

The stacked body may have a tubular shape, and the first principal face and the second principal face may be, respectively, an outer peripheral surface and an inner peripheral surface of the tubular shape.

The second material may contain Bi; and the first material may not contain Bi but contain a metal different from Bi.

The carbon containing layer may include a first portion containing the first material and carbon and a second portion containing the second material and carbon.

The stacked body may be a sintered body, and the carbon containing layer may be a portion of the sintered body.

A thermoelectric generation tube as one implementation of the present disclosure comprises the above thermoelectric generator, the stacked body having a tubular shape.

A production method for a thermoelectric generator as one implementation of the present disclosure comprises: step (A) of providing: a plurality of first compacts having a pair of planes of stacking and a first side face and a second side face being located between the pair of planes of stacking and not perpendicular to the pair of planes of stacking, the plurality of first compacts being made of a source material for a first material having a relatively low Seebeck coefficient and a relatively high thermal conductivity; and a plurality of second compacts having a pair of planes of stacking and a first side face and a second side face being located between the pair of planes of stacking and not perpendicular to the pair of planes of stacking, the plurality of second compacts being made of a source material for a second material having a relatively high Seebeck coefficient and a relatively low thermal conductivity; step (B) of forming a multilayer compact by alternately stacking the plurality of first compacts and the plurality of second compacts so that the respective planes of stacking are in contact with each other, and that the first side faces and the second side faces of the plurality of first compacts and the plurality of second compacts respectively constitute a first principal face and a second principal face of the multilayer compact, wherein one selected from among a carbon fiber sheet, a carbon powder, and a graphite sheet is provided on at least one of the first principal face and the second principal face; and step (C) of sintering the multilayer compact with the selected one provided thereon, wherein, after step (C) of sintering, carbon-containing portions are not substantially eliminated from the at least one of the first principal face and the second principal face that had the selected one provided thereon.

In step (C) of sintering, the multilayer compact may be sintered while applying a pressure to the multilayer compact.

Step (C) of sintering may be conducted by a hot pressing technique or a spark plasma sintering technique.

Each of the plurality of first compacts and the plurality of second compacts may have a tubular shape of which first and second side faces define an outer peripheral surface and an inner peripheral surface, the first side face and the second side face being connected by the pair of planes of stacking, and the planes of stacking each defining side faces of a truncated cone.

A thermoelectric generation unit as one implementation of the present disclosure is a thermoelectric generation unit comprising a plurality of aforementioned thermoelectric generation tubes, wherein each of the plurality of thermoelectric generation tubes has an outer peripheral surface and an inner peripheral surface, and a flow path defined by the inner peripheral surface, and generates an electromotive force in an axial direction of the thermoelectric generation tube based on a temperature difference between the inner peripheral surface and the outer peripheral surface; and the thermoelectric generation unit further includes a container housing the plurality of thermoelectric generation tubes inside, the container having a fluid inlet port and a fluid outlet port for allowing a fluid to flow inside the container and a plurality of openings into which the respective thermoelectric generation tubes are inserted, and a plurality of electrically conductive members providing electrical interconnection for the plurality of thermoelectric generation tubes, the container including: a shell surrounding the plurality of thermoelectric generation tubes; and a pair of plates each being fixed to the shell and having the plurality of openings, with channels being formed so as to house the plurality of electrically conductive members and interconnect at least two of the plurality of openings, wherein respective ends of the thermoelectric generation tubes are inserted in the plurality of openings of the plates, the plurality of electrically conductive members being housed in the channels in the plates, and the plurality of thermoelectric generation tubes are connected in electrical series by the plurality of electrically conductive members housed in the channels.

A thermoelectric generation system as one implementation of the present disclosure comprises: the above thermoelectric generation unit; a first medium path communicating with the fluid inlet port and the fluid outlet port of the container; a second medium path encompassing the flow paths of the plurality of thermoelectric generation tubes; and an electric circuit electrically connected to the plurality of electrically conductive members to retrieve power generated in the plurality of thermoelectric generation tubes.

Hereinafter, embodiments of the thermoelectric generator, thermoelectric generation unit, and thermoelectric generation system according to the present disclosure will be described in detail.

### First Embodiment

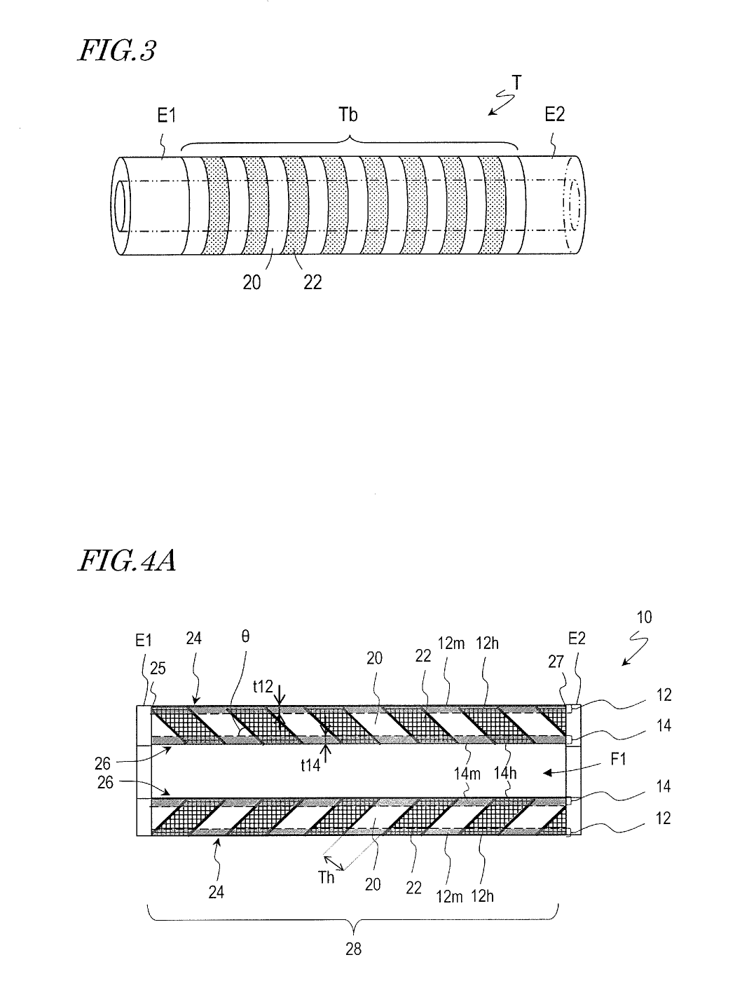

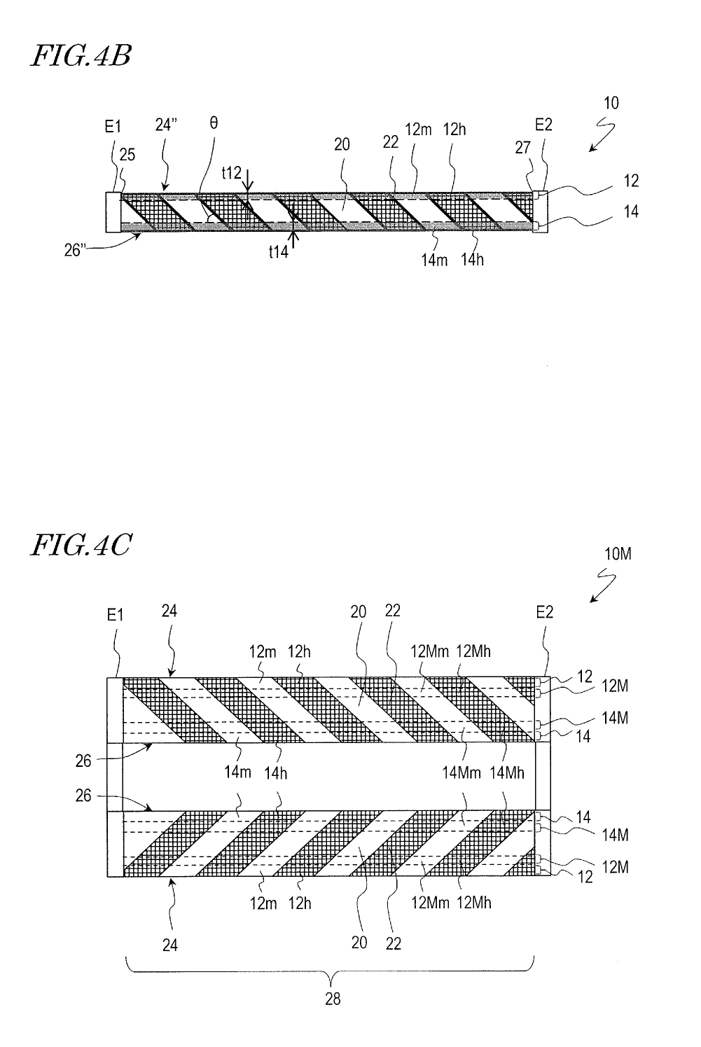

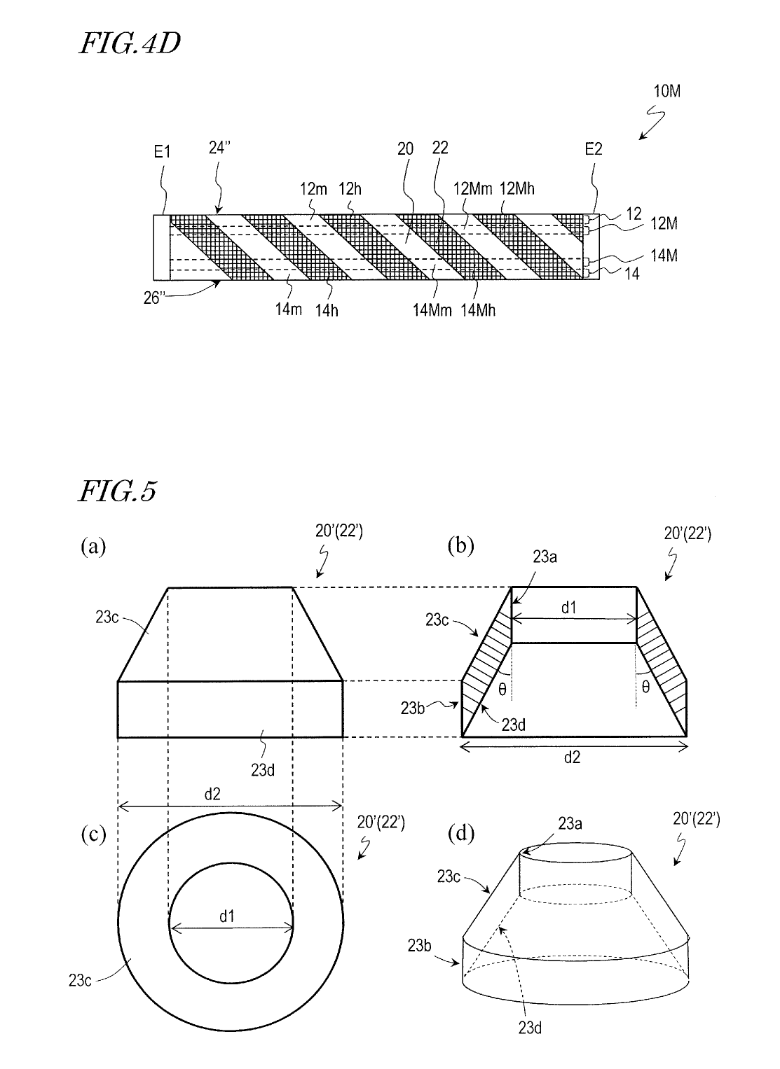

FIG. 4A shows a schematic cross section of the thermoelectric generator 10 of the present embodiment. The thermoelectric generator 10 of the present embodiment has a tubular shape as shown in FIG. 3. FIG. 4A shows a cross section containing the axis of the tube. The thermoelectric generator 10 includes a stacked body 28, and a first electrode E1 and a second electrode E2. The stacked body 28 has an outer peripheral surface 24 which is the first principal face, an inner peripheral surface 26 which is the second principal face, and a first end face 25 and a second end face 27 being located between the outer peripheral surface 24 and the inner peripheral surface 26, such that the first electrode E1 and the second electrode E2 are respectively electrically connected to the first end face 25 and the second end face 27. The stacked body 28 includes a plurality of thermoelectric material layers 22 and a plurality of metal layers 20. The plurality of thermoelectric material layers 22 and the plurality of metal layers 20 are alternately stacked.

A region which is defined by the inner peripheral surface 26 forms a flow path Fl. In the illustrated example, cross sections of the outer peripheral surface 24 and the inner peripheral surface 26 taken perpendicular to the axial direction each present the shape of a circle. However, these shapes are not limited to circles, but may be ellipses or polygons, as mentioned earlier. There is no particular limitation to the cross-sectional area of the flow path as viewed on a plane which is perpendicular to the axial direction. The cross-sectional area of the flow path may be appropriately set in accordance with the flow rate of the medium which is supplied to the internal flow path of the thermoelectric generator.

In the illustrated example, the first electrode E1 and the second electrode E2 both have cylindrical shapes. However, the shapes of the first electrode E1 and the second electrode E2 are not limited thereto. At or near the respective end of the stacked body 28, the first electrode E1 and the second electrode E2 may each have any arbitrary shape which is electrically connectable to at least one of a metal layer 20 or a thermoelectric material layer 22 and which does not obstruct the flow path F1. In the example shown in FIG. 4A, the first electrode E1 and the second electrode E2 have outer peripheral surfaces conforming to the outer peripheral surface 24 of the stacked body 28; however, it is not necessary for the outer peripheral surfaces of the first electrode E1 and the second electrode E2 to conform to the outer peripheral surface 24 of the stacked body 28. For example, the first electrode E1 and the second electrode E2 may have outer peripheral surfaces with a diameter (outer diameter) which is greater or smaller than the diameter (outer diameter) of the outer peripheral surface 24 of the stacked body 28. Moreover, the cross-sectional shapes of the first electrode E1 and the second electrode E2 taken along a plane which is perpendicular to the axial direction may differ from the cross-sectional shape of the outer peripheral surface 24 of the stacked body 28 taken along a plane which is perpendicular to the axial direction.

The first electrode E1 and the second electrode E2 are made of an electrically conductive material, typically a metal. The first electrode E1 or the second electrode E2, or both, may be composed of one or more metal layers 20 located at or near the respective end of the stacked body 28. In that case, it can be said that the stacked body 28 partially functions as the first electrode E1 and/or the second electrode E2. Alternatively, the first electrode E1 and the second electrode E2 may be made of metal layers or annular metal members which partially cover the outer peripheral surface 24 of the stacked body 28, or a pair of cylindrical metal members fitted partially into the flow path F1 from both ends of the stacked body 28 so as to be in contact with the inner peripheral surface 26 of the stacked body 28.

As shown in FIG. 4A, the metal layers 20 and the thermoelectric material layers 22 are alternately stacked while being inclined. A thermoelectric generator with such a construction basically operates under similar principles to the principles which have been described with reference to FIGS. 1A, 1B and 2. Therefore, when a temperature difference is introduced between the outer peripheral surface 24 and the inner peripheral surface 26 of the thermoelectric generator 10, a potential difference occurs between the first electrode E1 and the second electrode E2. The general direction of the temperature gradient at this time is a perpendicular direction to the outer peripheral surface 24 and the inner peripheral surface 26.

The angle of inclination θ of the planes of stacking in the stacked body 28 relative to the direction in which the first electrode E1 and the second electrode E2 oppose each other (hereinafter simply referred to as the “inclination angle”) may be set within a range of not less than 5° and not more than 60°, for example. The inclination angle θ may be not less than 20° and not more than 45°. The appropriate range for the inclination angle θ differs depending on the combination of the first material composing the metal layers 20 and the second material composing the thermoelectric material layers 22.

The ratio between the thickness of each metal layer 20 and the thickness of each thermoelectric material layer 22 (hereinafter simply referred to as the “stacking ratio”) in the stacked body 28 may be set within the range of 20:1 to 1:9, for example. Herein, the thickness of each metal layer 20 means a thickness along a direction which is perpendicular to the planes of stacking (i.e., the thickness indicated by the arrow Th in FIG. 4A). Similarly, the thickness of each thermoelectric material layer 22 means a thickness along a direction which is perpendicular to the planes of stacking. Note that the total numbers of metal layers 20 and thermoelectric material layers 22 being stacked can be appropriately set.

The metal layers 20 may be made of any arbitrary metal material, e.g., nickel or cobalt. Nickel and cobalt are examples of metal materials exhibiting excellent thermoelectric generation characteristics. The metal layers 20 may contain silver or gold. The metal layers 20 may contain any of such exemplary metal materials alone, or an alloy of them. In the case where the metal layers 20 are made of an alloy, this alloy may contain copper, chromium, or aluminum. Examples of such alloys are constantan, CHROMEL™, or ALUNEL™.

The thermoelectric material layers 22 may be made of any arbitrary thermoelectric material depending on the temperature of use. Examples of thermoelectric materials that may be used for the thermoelectric material layers 22 includes: thermoelectric materials of a single element, such as Bi, Sb; alloy-type thermoelectric materials, such as BiTe-type, PbTe-type, and SiGe-type; and oxide-type thermoelectric materials, such as CaₓCoO₂, NaₓCoO₂, and SrTiO₃. The “thermoelectric material” in the present specification means a material having a Seebeck coefficient with an absolute value of 30 μV/K or more and an electrical resistivity of 10 mΩcm or less. Such a thermoelectric material may be crystalline or amorphous. In the case where the temperature of the hot medium is about 200 degrees Celsius or less, the thermoelectric material layers 22 may be made of a dense body of a BiSbTe alloy, for example. The representative chemical composition of a BiSbTe alloy is Bi_{0.5}Sb_{1.5}Te₃, but this is not a limitation. A dopant such as Se may be contained in BiSbTe. The mole fractions of Bi and Sb may be adjusted as appropriate.

Other examples of thermoelectric materials composing the thermoelectric material layers 22 are BiTe, PbTe, and so on. When the thermoelectric material layers 22 are made of BiTe, it may be of the chemical composition Bi₂Teₓ, where 2<X<4. A representative chemical composition is Bi₂Te₃. Sb or Se may be contained in Bi₂Te₃. A BiTe chemical composition containing Sb can be expressed as (Bi_{1-y}Sb_{y})₂Teₓ, where 0<Y<1, and more preferably 0.6<Y<0.9.

The materials composing the first electrode E1 and the second electrode E2 may be any material that has good electrical conductivity. The first electrode E1 and the second electrode E2 may be made of metals such as copper, silver, molybdenum, tungsten, aluminum, titanium, chromium, gold, platinum, and indium. Alternatively, they may be made of nitrides or oxides, such as titanium nitride (TiN), indium tin oxide (ITO), and tin dioxide (SnO₂). The first electrode E1 or second electrode E2 may be made of solder, silver solder, an electrically conductive paste, or the like. In the case where both ends of the tube body Tb1 are metal layers 20, the metal layers 20 may serve as the first electrode E1 and the second electrode E2, as mentioned above.

As a typical example of the thermoelectric generation tube, the present specification illustrates an element in which metal layers and thermoelectric generation material layers are alternately stacked; however, the structure of the stacked body to be used in the present disclosure is not limited to such an example. The above-described thermoelectric generation is possible by stacking first layers that are made of a first material which has a relatively low Seebeck coefficient and a relatively high thermal conductivity, and second layers that are made of a second material which has a relatively high Seebeck coefficient and a relatively low thermal conductivity. The metal layers 20 and the thermoelectric material layers 22 are, respectively, examples of first layers and second layers.

In at least one of the outer peripheral surface 24 and the inner peripheral surface 26, the stacked body 28 of the thermoelectric generator 10 includes a carbon containing layer that contains carbon. In the present embodiment, the stacked body 28 includes a carbon containing layer 12 and a carbon containing layer 14, respectively, at the outer peripheral surface 24 and the inner peripheral surface 26.

The carbon containing layer 12 has a thickness t12 from the outer peripheral surface 24 of the stacked body 28 inwards, such that carbon is diffused in the stacked body 28 in this range. In the example shown in FIG. 4A, the carbon containing layer 12 includes portions 12m, each defining a portion in which carbon is diffused in a metal layer 20, and portions 12h, each defining a portion in which carbon is diffused in a thermoelectric material layer 22.

Similarly, the carbon containing layer 14 has a thickness t14 from the inner peripheral surface 26 of the stacked body 28 inwards, such that carbon is diffused in the stacked body 28 in this range. In this example, the carbon containing layer 14 includes portions 14m, each defining a portion in which carbon is diffused in a metal layer 20, and portions 14h, each defining a portion in which carbon is diffused in a thermoelectric material layer 22. In the case where the metal layers 20 and the thermoelectric material layers 22 are made of carbon-containing materials to begin with, the portions 12m, 12h, 14m, and 14h are defined as regions that contain more carbon than do other parts of the metal layers 20 and the thermoelectric material layers 22.

Due to their carbon content, the carbon containing layer 12 and the carbon containing layer 14 have higher hardnesses than that of the thermoelectric material layers 22 in particular. As a result, even when in contact with fluids such as the hot medium and the cold medium, the outer peripheral surface 24 and the inner peripheral surface 26 are restrained from being ground. Moreover, when a high carbon concentration exists at the outer peripheral surface 24 side of the carbon containing layer 12 and the inner peripheral surface 26 side of the carbon containing layer 14, the outer peripheral surface 24 and the inner peripheral surface 26 will become smooth, whereby any impurity that may be contained in the hot medium and/or the cold medium is restrained from depositing or adhering.

The carbon concentrations and thicknesses t12 and t14 of the carbon containing layer 12 and the carbon containing layer 14 may well affect improvements to be attained in the hardness and surface smoothness of the carbon containing layer 12 and the carbon containing layer 14. Therefore, these factors can be determined in accordance with the durability in terms of abrasion, and the ability to suppress impurity adhesion, that are expected of the thermoelectric generator 10.

For example, as the thickness t12 of the carbon containing layer 12 and the thickness t14 of the carbon containing layer 14 increase, a greater durability in terms of abrasion is obtained. However, as the thickness t12 and the thickness t14 increase, the portion of each metal layer 20 and each thermoelectric material layer 22 that exhibits the designed characteristics becomes reduced, thereby degrading the power generating ability of the thermoelectric generator 10. Thus, the thickness t12 and the thickness t14 may be determined in view of the power generating ability of the thermoelectric generator 10 and the durability in terms of abrasion. For example, when the thickness of the tubular shape of the stacked body 28, i.e., the interval between the outer peripheral surface 24 and the inner peripheral surface 26, is about 1 mm to about 3 mm, the thickness t12 and the thickness t14 may each be set to about 100 μm to about 300 μm.

It is considered that the outer peripheral surface and the inner peripheral surface 26 will become more smooth as the carbon concentration in the outer peripheral surface 24 side of the carbon containing layer 12 and the inner peripheral surface 26 side of the carbon containing layer 14 increases. Therefore, portions that essentially contain carbon alone may exist in the outer peripheral surface 24 side of the carbon containing layer 12 and the inner peripheral surface 26 side of the carbon containing layer 14. However, if thick portions of high carbon concentration exist, electrical conductivity will be conferred to the carbon containing layer 12 and/or carbon containing layer 14, and especially in the portions 14h and/or 12h in which carbon is diffused in the thermoelectric material layers 22, whereby the power generating ability of the thermoelectric generator 10 may be degraded. In other words, it will be advantageous for the carbon containing layer 12 and the carbon containing layer 14 to not be electrically conductive, but be electrically insulative. So far as this aspect is concerned, the carbon concentration in the carbon containing layer 12 and the carbon containing layer 14 may be uniform along the thickness direction, or be higher at the outer peripheral surface 24 and inner peripheral surface 26 sides than at the inside.

Typically, the stacked body 28 is a sintered body, and the carbon containing layer 12 and the carbon containing layer 14 are each a portion of the sintered body. In the case where the carbon containing layer 12 and the carbon containing layer 14 are provided as portions of a sintered body, as will be specifically described below, the following procedure may be taken. Carbon fiber sheets, carbon powder, graphite sheets, or the like may be placed on faces of compacts in the stacked body 28 that correspond to the outer peripheral surface 24 and the inner peripheral surface 26, and the compacts may be sintered, whereby carbon will diffuse into the compacts, and with sintering, a carbon containing layer 12 and a carbon containing layer 14 will form at the outer peripheral surface 24 and the inner peripheral surface 26 of the sintered stacked body 28.

Thus, the thermoelectric generator 10 of the present embodiment includes a carbon containing layer in at least one of the outer peripheral surface 24 and the inner peripheral surface 26. Since the carbon containing layer(s) has high hardness, abrasion of the at least one of the outer peripheral surface 24 and the inner peripheral surface 26 is restrained, even when in contact with a fluid. Moreover, smoothness of the carbon containing layer(s) will restrain any impurity that may be contained in the hot medium and/or the cold medium from depositing or adhering.

As mentioned above, the thermoelectric generator is not limited to a tubular shape, and may have a rectangular solid shape. For example, as shown in FIG. 4B, the thermoelectric generator may have a rectangular solid shape including a first principal face 24″ and a second principal face 26″ which are planes. In this case, the carbon containing layer 12 and the carbon containing layer 14 are located at the first principal face 24″ and the second principal face 26″, respectively.

FIG. 4C shows a thermoelectric generator having intermediate layers as underlying layers of carbon containing layers. A thermoelectric generator 10M shown in FIG. 4C includes an intermediate layer 12M as an underlying layer of a carbon containing layer 12, i.e., on the side of the carbon containing layer 12 away from the outer peripheral surface 24 of the stacked body 28. Moreover, the thermoelectric generator 10M includes an intermediate layer 14M as an underlying layer of a carbon containing layer 14, i.e., on the side of the carbon containing layer 14 away from the inner peripheral surface 26 of the stacked body 28. The intermediate layers 12M and 14M may each be a semiconductor layer or an insulator layer.

As mentioned earlier, the power generating ability of the thermoelectric generator may be degraded when a carbon containing layer is of metallic nature. As will be later described with reference to Examples, however, it is possible by providing the intermediate layers 12M and 14M to reduce decrease in the power generating ability of the thermoelectric generator. Such an intermediate layer(s) may be provided on at least one of the outer peripheral surface side and the inner peripheral surface 26 side of the stacked body 28.

There is no particular limitation to the material of the intermediate layers 12M and 14M so long as a comparatively high electrical resistance is obtained. For example, the material of the intermediate layers 12M and 14M may be selected from among oxides, carbides, nitrides, organic matters, and the like as appropriate. As stable materials, alumina, boron nitride, and the like can be used. The intermediate layers 12M and 14M may be amorphous, without having any regular crystal structure. So long as a sufficient electrical insulation is attained, the thickness of the intermediate layers 12M and 14M does not need to be uniform; they may each have a thickness ranging from about 1 nm to about 100 μm. From the standpoint of preventing decrease in the power generating performance of the thermoelectric generator, it would be advantageous for the semiconductor layer or insulator layer to be sufficiently thin and have a high thermal conductivity. So long as a sufficient electrical resistance is maintained, diffusion of elements into an intermediate layer from the graphite sheet or the like with which to form a carbon containing layer, and/or diffusion of elements into an intermediate layer from the stacked body 28 is tolerable.

In the construction illustrated in FIG. 4C, the intermediate layer 12M includes portions 12Mm (which hereinafter may be referred to as “first portions 12Mm”), each defining a portion in which an insulator material or semiconductor material is diffused in a metal layer 20, and portions 12Mh (which hereinafter may be referred to as “second portions 12Mh”), each defining a portion in which an insulator material or semiconductor material is diffused in a thermoelectric material layer 22. However, the intermediate layer 12M may include at least either one of first portions 12Mm or second portions 12Mh. Similarly, the intermediate layer 14M may include at least either one of portions 14Mm each defining a portion in which an insulator material or semiconductor material is diffused in a metal layer 20, or portions 14Mh each defining a portion in which an insulator material or semiconductor material is diffused in a thermoelectric material layer 22.

As has been described with reference to FIG. 4B, the shape of the thermoelectric generator is not limited to a tubular shape. FIG. 4D shows a schematic cross section of a thermoelectric generator 10M having a rectangular solid shape. The thermoelectric generator 10M shown in FIG. 4D has a rectangular solid shape including a first principal face 24″ and a second principal face 26″ which are planes. In the illustrated example, the carbon containing layer 12 and the carbon containing layer 14 are located at the first principal face 24″ and the second principal face 26″, respectively. Furthermore, an intermediate layer 12M is provided as an underlying layer of a carbon containing layer 12, and an intermediate layer 14M is provided as an underlying layer of a carbon containing layer 14.

Next, with reference to FIG. 5 to FIG. 9, an embodiment of a production method for the thermoelectric generator 10 will be described.

First, compacts of source materials for the materials with which to form the metal layers 20 and the thermoelectric material layers 22 are provided. More specifically, a powdery source material for the material with which to form the metal layers 20 and a powdery source material for the material with which to form the thermoelectric material layers 22 are provided, and the respective powders are compacted via press forming or the like, to thereby form compacts 20′ and compacts 22′.

In FIG. 5, (a) to (d) are respectively a side view, a cross-sectional view, an upper plan view, and a perspective view showing the shape of a compact 20′ to become a metal layer 20 or a compact 22′ to become a thermoelectric material layer 22. The compact 20′ and the compact 22′ each have a tubular shape having an inner peripheral surface 23a and an outer peripheral surface 23b. The inner peripheral surface 23a and the outer peripheral surface 23b are connected by a plane of stacking 23c and a plane of stacking 23d each defining side faces of a truncated cone. The diameters of cylinders which are formed by the inner peripheral surface 23a and the outer peripheral surface 23b are d1 and d2, respectively. When viewed in a cross section through the axis of the tubular shape (FIG. 5(b)), the plane of stacking 23c and the plane of stacking 23d constitute an angle θ with respect to the inner peripheral surface 23a.

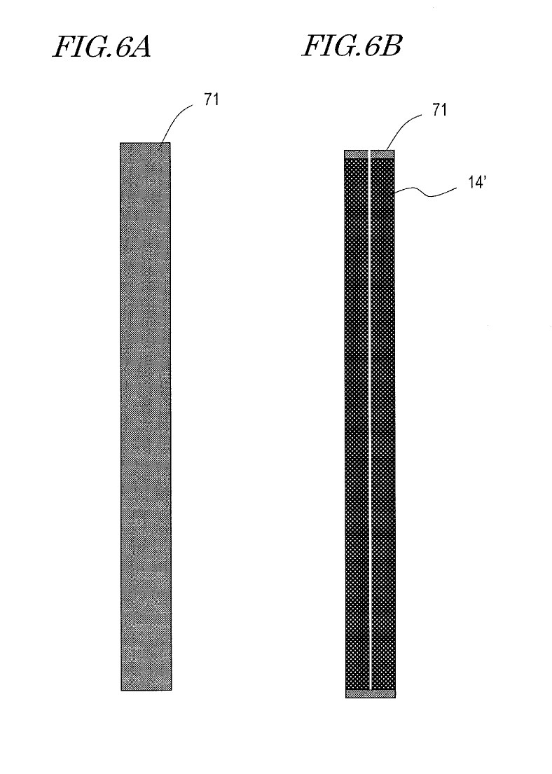

As shown in FIG. 6A, a rod 71 is provided which has a slightly smaller diameter than the diameter d1 of the inner peripheral surface 23a. As shown in FIG. 6B, a graphite sheet 14′ is wound around the outer peripheral surface of the rod 71. As the graphite sheet 14′, a graphite sheet which is available as a release agent for use in the production of sintered bodies can be used, for example. Alternatively, a carbon fiber sheet which is made of carbon fiber or a composite material of carbon fiber and carbon, etc., can be used. A resin sheet, etc., in which carbon powder is dispersed may also be used. The graphite sheet 14′ has a thickness of e.g. 100 μm to 500 μm.

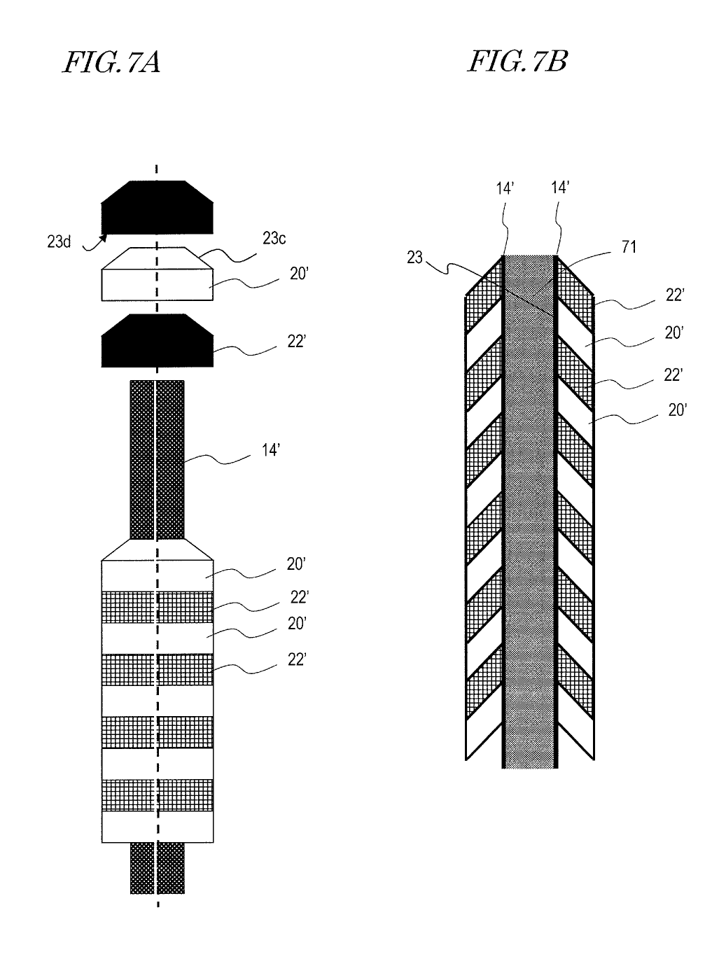

As shown in FIG. 7A, the rod 71, around which the graphite sheet 14′ is wound, is alternately inserted through the compacts 20′ and the compacts 22′, whereby the compacts 20′ and the compacts 22′ become stacked. As a result, the plane of stacking 23d or the plane of stacking 23c of each compact 20′ or compact 22′ comes in contact with the plane of stacking 23c or the plane of stacking 23d of an adjoining compact 22′ or compact 20′. FIG. 7B shows a schematic cross section of stacked compacts 20′ and compacts 22′. As shown in FIG. 7B, the respective inner peripheral surfaces 23a of the compacts 20′ and the compacts 22′ are substantially in contact with or close to the graphite sheet 14′.

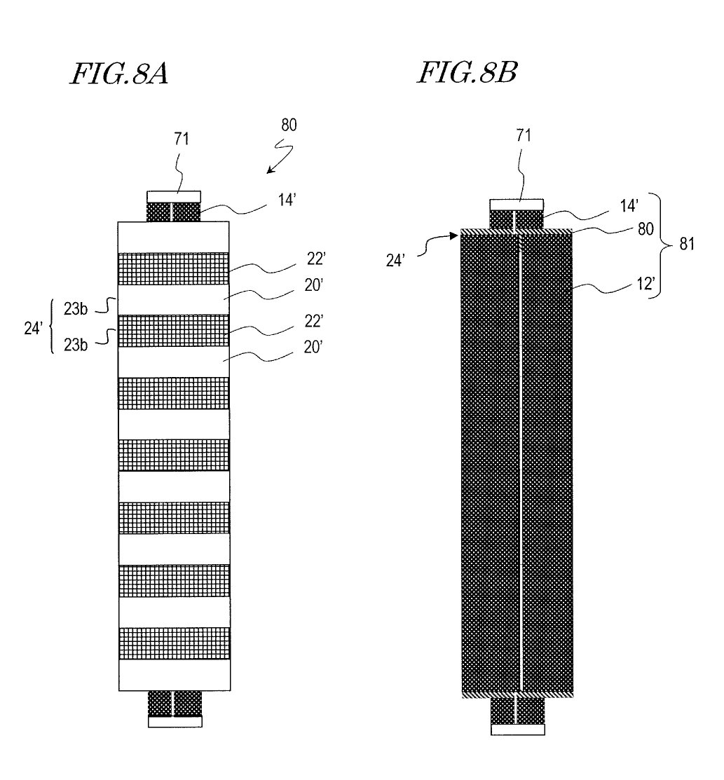

FIG. 8A shows a multilayer compact 80 in which stacking of the compacts 20′ and the compacts 22′ is complete. The outer peripheral surfaces 23b of the compacts 20′ and the compacts 22′ constitute the outer peripheral surface 24′ of the multilayer compact 80. Although not shown in the figure, the inner peripheral surfaces 23a of the compacts 20′ and the compacts 22′ constitute the inner peripheral surface of the multilayer compact 80, with the graphite sheet 14′ being disposed on this inner peripheral surface.

Next, as shown in FIG. 8B, a graphite sheet 12′ is also wound on the outer peripheral surface 24′ of the multilayer compact 80. The aforementioned materials can also be used for the graphite sheet 12′. This completes a tubular-shaped multilayer compact 81, in which the graphite sheet 12′ and the graphite sheet 14′ are provided respectively on the outer peripheral surface 24′ and the inner peripheral surface 26′ of the multilayer compact 80.

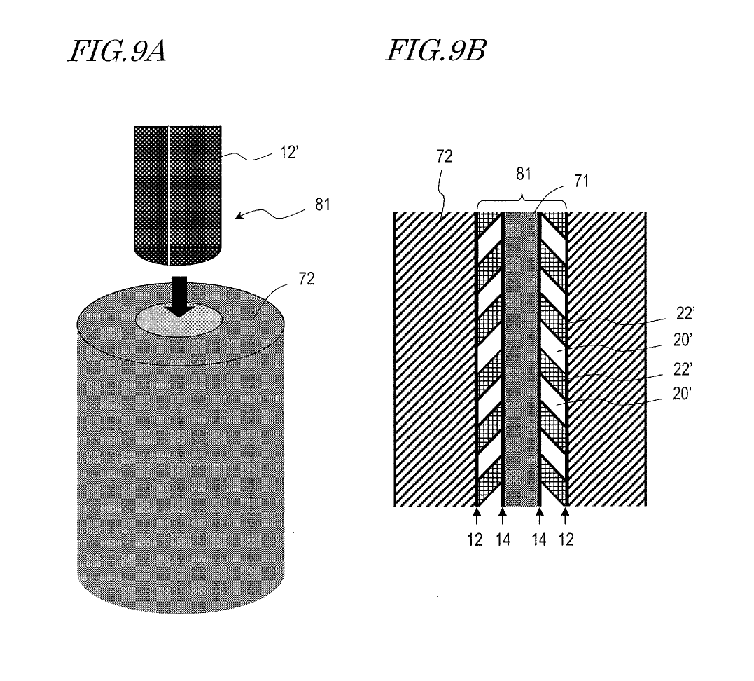

As shown in FIG. 9A, the multilayer compact 81 is inserted into the space of a sintering die 72. FIG. 9B shows a schematic cross section of the multilayer compact 81 having been inserted in the sintering die 72. As described above, the graphite sheet 12′ is disposed on the outer peripheral surface 24′ and the graphite sheet 14′ is disposed on the inner peripheral surface 26′ of the multilayer compact 81.

Next, the multilayer compact 81 is sintered. An appropriate temperature for the sintering can be selected in accordance with the materials composing the metal layers 20 and the thermoelectric material layers 22, the configuration of the source material powders, and the like. For example, in the case where nickel powder is used for the compacts 20′ and powder of a BiSbTe alloy is used for the compacts 22′, an appropriate temperature can be selected within the range of not less than 200 degrees Celsius and not more than 600 degrees Celsius.

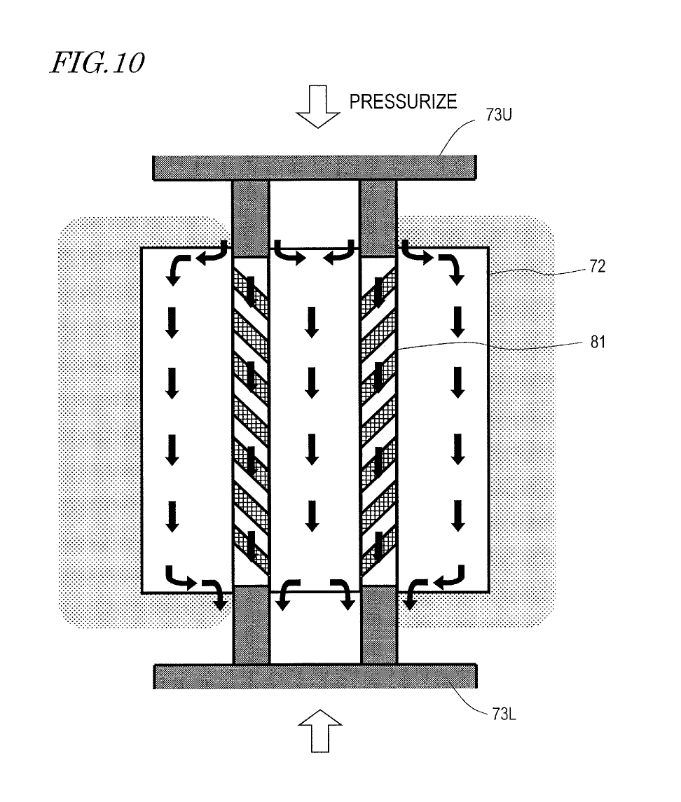

In order to obtain a dense sintered body, the multilayer compact 80 may be pressurized during sintering. For example, a sintering may be conducted by a hot pressing technique or spark plasma sintering. A pressure may be applied from both ends of the tubular shape by using jigs (punches) 73U and 73L as shown in FIG. 10, whereby the multilayer compact 80 receives pressure in three directions within the die 72.

Moreover, with the jigs 73U and 73L, a DC pulse voltage is applied to the multilayer compact 81 and the sintering die 72 as indicated by the arrows, so that the multilayer compact 81 is heated with the pulse voltage. As a result of this, the compacts 20′ and the compacts 22′ are sintered, and joining occurs between the compacts 20′ and the compacts 22′, which are of different materials.

Moreover, the carbon in the graphite sheet 12′ and the graphite sheet 14′ reacts with the compacts 20′ and the compacts 22′, whereby carbon is diffused from the outer peripheral surface 24′ and the inner peripheral surface 26′ of the multilayer compact 80, the compacts 20′ and the compacts 22′ become sintered with carbon contained therein. As a result, the stacked body 28 of the thermoelectric generator 10 as shown in FIG. 4A is obtained. In the stacked body 28, the carbon containing layer 12 and the carbon containing layer 14 are formed on the outer peripheral surface 24 and the inner peripheral surface 26. The carbon containing layer 12 and the carbon containing layer 14 having been formed are not removed. However, the carbon containing layer 12 and the carbon containing layer 14 may be removed partially, so long as the carbon containing layer 12 and the carbon containing layer 14 are not substantially eliminated, in order to enhance the surface smoothness of the outer peripheral surface 24 and the inner peripheral surface 26 and remove unwanted bumps and dents. It is not necessary for all of the carbon in the graphite sheet 12′ and the graphite sheet 14′ to react with the compacts 20′ and the compacts 22′; a layer that essentially contains carbon alone may be left in the surface layer of the outer peripheral surface 24′ and/or the inner peripheral surface 26′.

Thereafter, with the aforementioned method, a first electrode E1 and a second electrode E2 are provided and electrically coupled on the first end face 25 and the second end face 27 of the stacked body 28, thereby completing the thermoelectric generator 10.

Note that an intermediate layer 14M can be formed by, for example, allowing a semiconductor or insulator in powder form to be dispersed in a surface of the graphite sheet 14′ to face the multilayer compact 80 when the graphite sheet 14′ is placed in contact with the inner peripheral surface of the multilayer compact 80. Similarly, an intermediate layer 12M can be formed by allowing a semiconductor or insulator in powder form to be dispersed in a surface of the graphite sheet 12′ to face the multilayer compact 80 when the graphite sheet 12′ is wound on the outer peripheral surface 24′ of the multilayer compact 80. The intermediate layers 12M and 14M may be portions of the sintered body. In this manner, the stacked body 28 of the thermoelectric generator 10M as shown in FIG. 4C can be obtained. However, so long as the aforementioned construction is achieved, the methods of forming the intermediate layers are not limited to any specific methods. In addition to the above methods, a semiconductor or insulator in powder form may be dispersed in the inner peripheral surface and/or outer peripheral surface of the multilayer compact 80 before sintering. The easiest method of dispersing a semiconductor or insulator in powder form includes application by spraying, for example.

### EXAMPLES

Thermoelectric generators according to the present embodiment were produced under the following conditions, and their characteristics were examined. For comparison, thermoelectric generators lacking carbon containing layers (Reference Example and Comparative Example) were also produced by forming stacked bodies without using a graphite sheet 12′ or a graphite sheet 14′, where Comparative Example had a non-electrically conductive epoxy resin provided on each of an outer peripheral surface and an inner peripheral surface of the thermoelectric generator. Their electric generation characteristics and the like were also evaluated.

### Example 1

### (1) Production of Thermoelectric Generator

BiSbTe powder and nickel powder were pressurized with a hydraulic press, and compacted through compression. The materials were weighed so that the compacts produced had a uniform shape, and the respective powder masses were adjusted so that one compact was sized to have an inner diameter of 10 mm, an outer diameter of 14 mm, and a height of 6.4 mm, with a tapered portion having an angle θ of 20° (See portions (a) to (d) of FIG. 5). 17 BiSbTe powder compacts 22′ and 18 nickel powder compacts 20′ as obtained through the aforementioned steps were produced.

Next, as shown in FIGS. 6 to 9, the compacts 20′ and 22′ were alternately stacked on a rod 71 around which a graphite sheet 14′ with a thickness of 200 microns had been wound, thereby forming a multilayer compact 80. A graphite sheet 12′ with a thickness of 200 microns was wound on the outer peripheral surface 24′ of the multilayer compact 80, whereby a multilayer compact 81 having the graphite sheets 12′ and 14′ wound thereon was obtained.

Spark plasma sintering technique was used for the pressure sintering and joining of the multilayer compact 81. Joining was conducted at about 500 degrees Celsius, under a pressurize of 50 MPa. The sintering atmosphere was a vacuum of 5×10⁻³ Pa. After the joining in a high-temperature/high-pressure environment, cooling was effected down to room temperature in a vacuum, and the stacked body, now joined, was retrieved. Note that the stacked body of compacts simultaneously experienced sintering and joining of the differing materials through the aforementioned sinter process. Also, carbon containing layers 12 and 14 were formed at the same time. The resultant tube had a length along the center axis direction of about 55 to 60 mm. The above step was repeated, and the two resultant members were soldered together. Thereafter, an end of the resultant tube was cut and planarized, whereby a thermoelectric generation device of about 110 mm was obtained. As electrodes at both ends of the thermoelectric generation tube, copper tubes were soldered onto the ends. This element was designated the thermoelectric generator of Example 1.

The stacked body of metal layers 20 and thermoelectric material layers 22 obtained by the above method was observed with a TEM (transmission electron microscope), with respect to its cross section containing the axial direction of the tube. It was thus found that, in the metal layers 20, portions 12m having carbon diffused therein were formed from the outer peripheral surface 24 of the stacked body 28 inwards (see FIG. 4C), and an oxide layer of nickel oxide with a thickness of about 10 nm was formed further inside (i.e., on the side away from the outer peripheral surface 24). Moreover, in the metal layers 20, portions 14m having carbon diffused therein were formed from the inner peripheral surface 26 of the stacked body 28 inwards (see FIG. 4C), and an oxide layer of nickel oxide with a thickness of about 10 nm was formed further inside (i.e., on the side away from inner peripheral surface 26). It is considered that these oxide layers occurred through heating during the tube fabrication.

### Example 2

A similar method to that of Example 1 was used to form 17 BiSbTe powder compacts 22′ and 18 nickel powder compacts 20′. Next, boron nitride was sprayed onto the inner peripheral surface and outer peripheral surface of these compacts, thereby forming boron nitride films (insulative films) on the inner peripheral surface and outer peripheral surface of the compacts. Thereafter, similarly to Example 1, the compacts 20′ and 22′ were alternately stacked on a rod 71, around which a graphite sheet 14′ with a thickness of 200 microns had been wound, thereby forming a multilayer compact 80. Moreover, a graphite sheet 12′ with a thickness of 200 microns was wound on the outer peripheral surface 24′ of the multilayer compact 80, whereby a multilayer compact 81 having the graphite sheets 12′ and 14′ wound thereon was obtained. Furthermore, pressure sintering/joining, electrode installment, and the like were performed similarly to Example 1, whereby a thermoelectric generator of Example 2 was obtained.

### Example 3

A thermoelectric generator was produced by a similar method to that of Example 1. Thereafter, the outer peripheral surface and the inner peripheral surface of the thermoelectric generator were ground to remove the carbon containing layer 12 and the carbon containing layer 14. The outer peripheral surface and inner peripheral surface of the thermoelectric generator were further ground to remove also the aforementioned oxide layers. Thereafter, an electrically conductive carbon paste was applied on the outer peripheral surface and inner peripheral surface of the thermoelectric generator, and then dried to form carbon containing layers. Thus, a thermoelectric generator of Example 3 was obtained.

### Reference Example

A thermoelectric generator of Reference Example was produced in a similar manner to the thermoelectric generator of Example 1, except that no graphite sheet was wound around the rod 71 and that no graphite sheet was wound on the outer peripheral surface 24′ of the multilayer compact 80. As would be clear from the method of forming the thermoelectric generator of Reference Example, the thermoelectric generator of Reference Example lacks carbon containing layers.

### Comparative Example

A thermoelectric generator was produced through a similar procedure to that of the thermoelectric generator of Example 1. Thereafter, carbon containing layers 12 and 14 were completely removed with an electric die grinder, and an epoxy resin was applied on the inner peripheral surface and outer peripheral surface. This element was designated the thermoelectric generator of Comparative Example.

### (2) Electric Generation Characteristics Measurement and Results

Voltage measurements were taken while hot water at 90 degrees Celsius was flowed inside each of the thermoelectric generator tubes of Example 1, Reference Example, and Comparative Example at a flow rate of 20 L/min and cold water at 10 degrees Celsius was flowed outside the respective tube at a flow rate of 20 L/min.

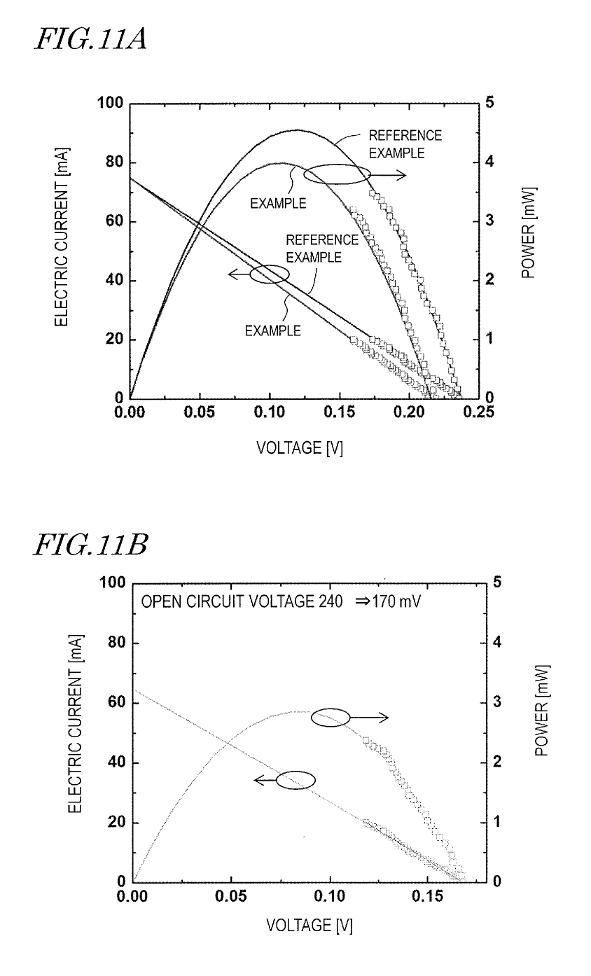

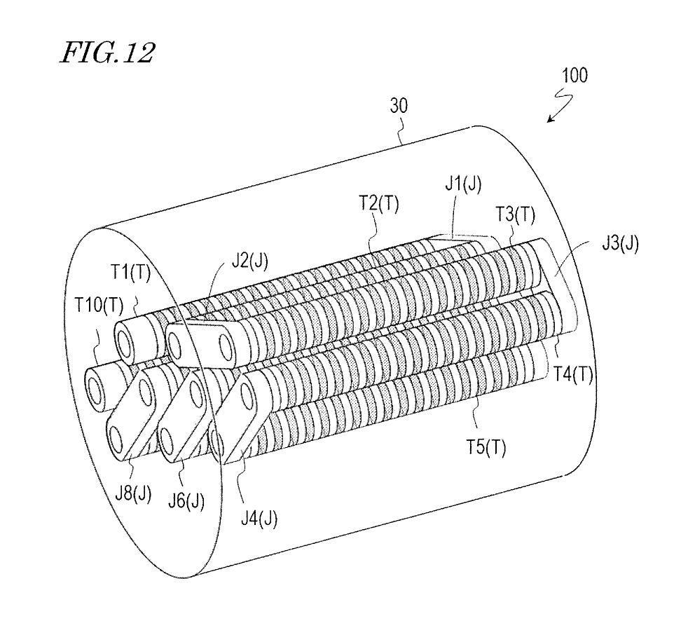

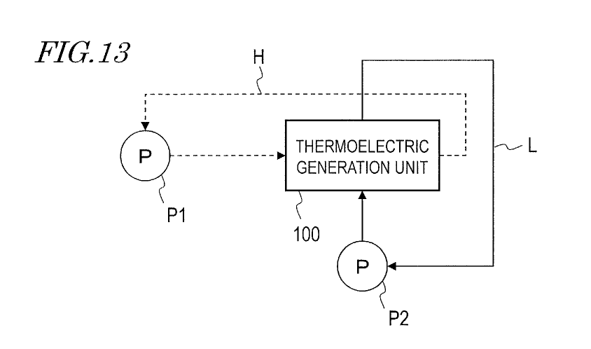

Electric generation characteristics of the thermoelectric generator of Example 1, the thermoelectric generator of Reference Example, and the thermoelectric generator of Comparative Example thus produced are shown in FIGS. 11A and 11B.

As shown in FIG. 11A, the thermoelectric generator of Example 1 had its open circuit voltage slightly reduced from that of the thermoelectric generator of Reference Example (which lacked carbon containing layers). However, the voltage decrease was about 10%. Thus, the decrease in the resultant maximum power was also about 90%.

On the other hand, as shown in FIG. 11B, the open circuit voltage was significantly decreased in the thermoelectric generator of Comparative Example. Specifically, the open circuit voltage was lower by 30% or more. The resultant maximum power was also lower by 30% or more than that of Reference Example.

This is considered to be because the volume of the portion of the thermoelectric material layers having electric generation characteristics as designed had decreased in the thermoelectric generator of Example 1 because of the carbon containing layers being provided, or because the carbon containing layers were electrically conductive.

Moreover, as shown in FIG. 11B, in the case where an epoxy resin was provided on the outer peripheral surface and the inner peripheral surface for protection of the outer peripheral surface and the inner peripheral surface of the thermoelectric generator, presumably the poor thermal conductivity of the epoxy resin made it impossible to introduce a significant temperature difference between the outer peripheral surface and the inner peripheral surface of the thermoelectric generator, thus resulting in the considerable decrease in the open circuit voltage.

Measurement results of the generated power of the thermoelectric generator of Examples 1 to 3 are shown in Table 1.

TABLE 1

| | generated power (W) |
|---|---|
| Example 1 | 4 |
| Example 2 | 5 |
| Example 3 | 1.5 |

As shown in Table 1, while a high generated power is obtained in the thermoelectric generator of Example 3, an even higher generated power is obtained in the thermoelectric generators of Example 1 and Example 2 than in the thermoelectric generator of Example 3. This indicates that forming a semiconductor layer containing nickel oxide, etc., or an insulating layer containing boron nitride, etc., as an underlying layer of a carbon containing layer contributes to higher generated power.

### (3) Long-Time Running Test for Thermoelectric Generator and Results

An experiment concerning abrasion of the outer and inner peripheral surfaces and impurity deposition was conducted, with respect to the case where the thermoelectric generators of Examples 1 to 3, Reference Example, and Comparative Example were subjected to a long-term use. Specifically, hot water at 90 degrees Celsius was flowed inside each of the thermoelectric generator tubes of Examples 1 to 3, Reference Example, and Comparative Example at a flow rate of 10 L/min, while cold water at 10 degrees Celsius was flowed outside the respective tube at a flow rate of 10 L/min for 30 days, during which time measurements were continuously taken. As a result, the thermoelectric generator of Reference Example exhibited evident discoloration and material exfoliation at the tube surface, which were caused by adhesion of impurities. On the other hand, no significant changes in the appearance or performance were observed in the thermoelectric generators of Examples 1 to 3.

Thus, it was confirmed that, without hardly deteriorating the electric generation characteristics, the thermoelectric generator according to the present embodiment can reduce abrasion of the stacked body and adhesion of impurities through contact with fluids, this being enabled by the carbon containing layers. It was also found that, by forming a semiconductor layer or an insulator layer as an underlying layer of a carbon containing layer, deteriorations in the electric generation characteristics are reduced, so that a higher generated power can be obtained while reducing abrasion of the stacked body and adhesion of impurities through contact with fluids. Thus, with the thermoelectric generator according to the present embodiment, a stacked body including thermoelectric material layers, i.e., a tube body, is employed to function as a tube or a wall surface that comes in contact with a hot medium and a cold medium to define flow paths thereof, whereby heat losses are reduced and a temperature difference can be formed in the thermoelectric material layer with a high efficiency. Thus, a thermoelectric generator which can perform highly efficient electric generation is realized. Moreover, the carbon containing layers allow to realize a thermoelectric generator with good durability, in which abrasion of the stacked body and adhesion of impurities are reduced.

### Second Embodiment

An embodiment of a thermoelectric generation unit and a thermoelectric generation system in which the thermoelectric generator of the first embodiment is used will be described. FIG. 12 is a perspective view showing a schematic construction of an illustrative thermoelectric generation unit 100 included in a thermoelectric generation system according to an embodiment of the present disclosure. The thermoelectric generation unit 100 shown in FIG. 12 includes a plurality of thermoelectric generation tubes T, a container which houses these thermoelectric generation tubes T inside, and a plurality of electrically conductive members J which electrically connect the thermoelectric generation tubes T. In the example of FIG. 12, ten thermoelectric generation tubes T1 to T10 are housed in the container 30. Typically, the ten thermoelectric generation tubes T1 to T10 are disposed substantially in parallel to one another, but such disposition is not the only implementation. The thermoelectric generator of the first embodiment is used as each of the thermoelectric generation tubes T1 to T10. The number of thermoelectric generators may be appropriately set in accordance with the flow rate of the medium which is supplied to the internal flow paths of the thermoelectric generators.

The thermoelectric generation tubes T1 to T10 each have an outer peripheral surface and an inner peripheral surface, and an internal flow path which is defined by the inner peripheral surface, as described earlier. The thermoelectric generation tubes T1 to T10 are each constructed so as to generate an electromotive force in the respective axial direction because of a temperature difference between the inner peripheral surface and the outer peripheral surface. In other words, by introducing a temperature difference between the outer peripheral surface and the inner peripheral surface in each of the thermoelectric generation tubes T1 to T10, electric power is retrieved from the thermoelectric generation tubes T1 to T10. For example, by placing a hot medium in contact with the internal flow path of each of the thermoelectric generation tubes T1 to T10 and a cold medium in contact with the outer peripheral surface of each of the thermoelectric generation tubes T1 to T10, electric power can be retrieved from the thermoelectric generation tubes T1 to T10. Conversely, a cold medium may be placed in contact with the inner peripheral surface of each of the thermoelectric generation tubes T1 to T10 and a hot medium may be placed in contact with their outer peripheral surface.

In the example shown in FIG. 12, the medium which comes in contact with the outer peripheral surface of the thermoelectric generation tubes T1 to T10 inside the container 30 and the medium which comes in contact with the inner peripheral surface of each thermoelectric generation tube T1 to T10 in the internal flow path of the respective thermoelectric generation tube are supplied through separate conduits (not shown), thus being isolated so as not to intermix.

FIG. 13 is a block diagram showing an exemplary construction for introducing a temperature difference between the outer peripheral surface and the inner peripheral surface of each thermoelectric generation tube T. In FIG. 13, arrows H in broken lines schematically represent a flow of the hot medium, and arrows L in solid lines schematically represent a flow of the cold medium. In the example shown in FIG. 13, the hot medium and the cold medium are circulated by pumps P1 and P2, respectively. For example, the hot medium is supplied in the internal flow path of each thermoelectric generation tube T1 to T10, while the cold medium is supplied inside the container 30. Although omitted from illustration in FIG. 13, heat to the hot medium is supplied from a high-temperature heat source (e.g., a heat exchanger) not shown, and heat from the cold medium is supplied to a low-temperature heat source not shown. As the high-temperature heat source, steam, hot water, exhaust gas, or the like of relatively low temperature (e.g., 200 degrees Celsius or less), which has conventionally been dumped unused into the ambient, can be used. It will be appreciated that a heat source of higher temperature may be used.

In the example shown in FIG. 13, the hot medium and the cold medium are illustrated as being circulated by the pumps P1 and P2, respectively; however, the thermoelectric generation system of the present disclosure is not limited to such an example. Both or one of the hot medium and the cold medium may be dumped into the ambient from the respective heat source(s), without constituting a circulating system. For example, high-temperature hot spring water that has sprung from the ground may be supplied to thermoelectric generation unit 100 as the hot medium, and thereafter utilized for purposes other than power generation in the form of hot spring water which has cooled down, or dumped as it is. As the cold medium, too, phreatic water, river water, or sea water may be drawn up to be supplied to the thermoelectric generation unit 100. After such is used as the cold medium, it may be lowered to an appreciated temperature as necessary, and returned to the original water source, or dumped into the ambient.

FIG. 12 is referred to again. In the thermoelectric generation unit 100 of the present disclosure, a plurality of thermoelectric generation tubes T are electrically connected via the electrically conductive members J. In the example of FIG. 12, each adjacent pair consisting of two thermoelectric generation tubes T is interconnected by a respective electrically conductive member J. As a whole, the plurality of thermoelectric generation tubes T are connected in electrical series. For example, the two thermoelectric generation tubes T3 and T4 appearing foremost in FIG. 12 are interconnected by the electrically conductive member J3 at their right end. At their left end, these two thermoelectric generation tubes T3 and T4 are connected to other thermoelectric generation tubes T2 and T5, respectively, by the electrically conductive members J2 and J4.

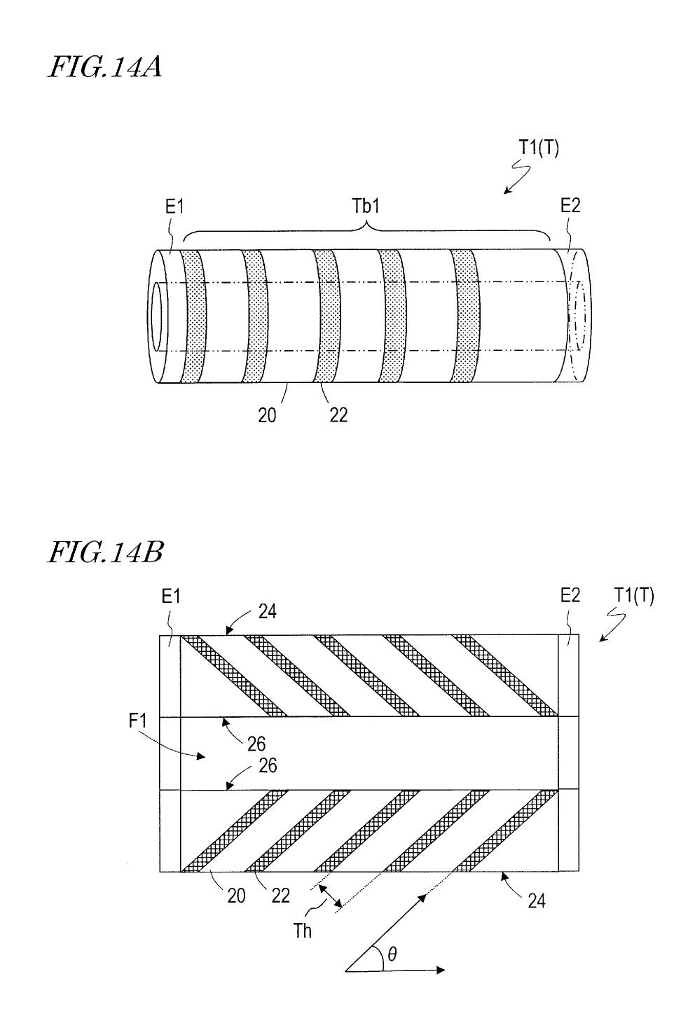

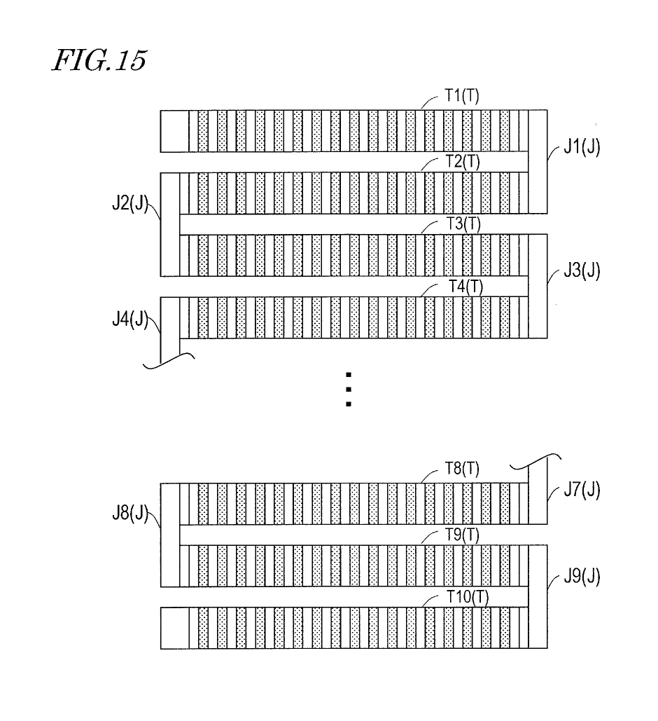

FIG. 14A shows a perspective view of one of the thermoelectric generation tubes T included in the thermoelectric generation unit 100 (which herein is the thermoelectric generation tube T1). As shown in the figure, the thermoelectric generation tube T1 includes a tube body Tb1, in which metal layers 20 and thermoelectric material layers 22 are alternately stacked, and a pair of electrodes E1 and E2. FIG. 14B shows a schematic cross section when the thermoelectric generation tube T1 as viewed on a plane that contains the axis (center axis) of the thermoelectric generation tube T1.

FIG. 15 schematically shows an example of electrical connection of the thermoelectric generation tubes T1 to T10. As shown in FIG. 15, each of the electrically conductive members J1 to J9 electrically connects two thermoelectric generation tubes. The electrically conductive members J1 to J9 are arrayed so as to connect the thermoelectric generation tubes T1 to T10 in electrical series as a whole. In this example, the circuit that is constituted by the thermoelectric generation tubes T1 to T10 and the electrically conductive members J1 to J9 is traversable. This circuit may partially include thermoelectric generation tubes which are connected in parallel, and it is not essential that the circuit be traversable.

In the example of FIG. 15, an electric current flows from the thermoelectric generation tube T1 to the thermoelectric generation tube T10, for example. The electric current may flow from the thermoelectric generation tube T10 to the thermoelectric generation tube T1. The direction of this electric current is determined by the type of thermoelectric material used for the thermoelectric generation tubes T, the direction of heat flow occurring at the inner peripheral surface and the outer peripheral surface of the thermoelectric generation tube T, the direction of inclination of the planes of stacking in the thermoelectric generation tubes T, and so on. The connection of the thermoelectric generation tubes T1 to T10 is determined so that electromotive forces occurring in the respective thermoelectric generation tubes T1 to T10 do not cancel one another, but are superposed.

Note that the direction of the electric current flowing through the thermoelectric generation tubes T1 to T1° and the flow direction of the medium (hot medium or the cold medium) flowing through the internal flow paths of the thermoelectric generation tubes T1 to T10 are unrelated. For example, in the example of FIG. 15, the flow direction of the medium flowing through the internal flow paths of the thermoelectric generation tubes T1 to T10 may universally be from the left to the right in the figure, for example.

### <One Implementation of Thermoelectric Generation Unit>

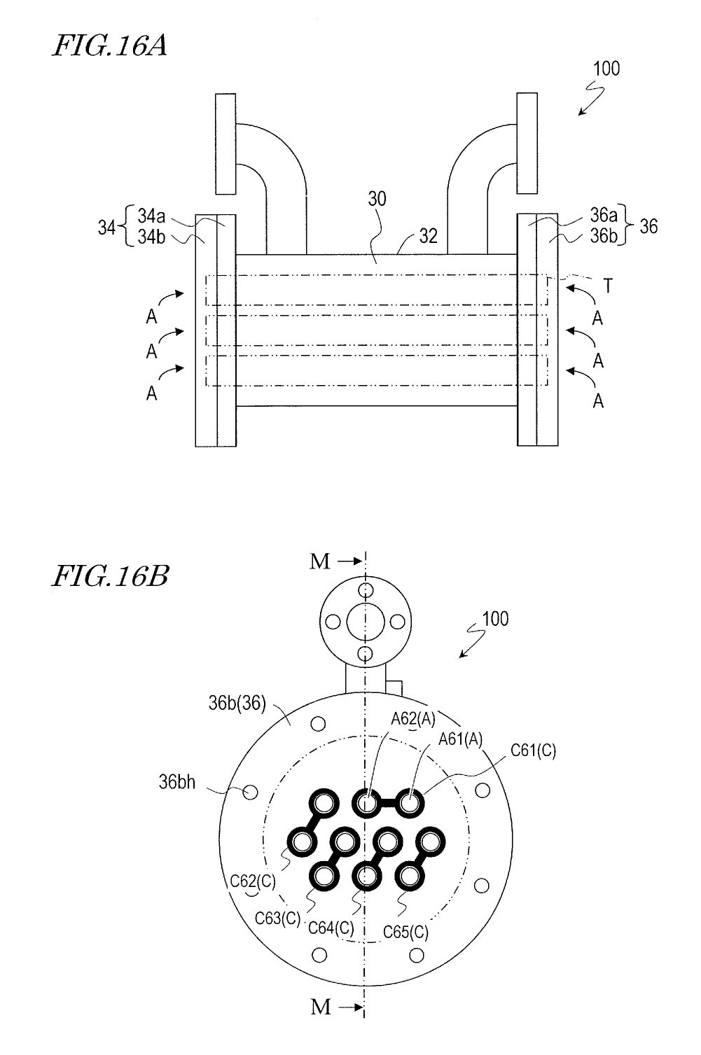

Next, FIGS. 16A and 16B are referred to. FIG. 16A is a front view showing one implementation of the thermoelectric generation unit according to the present disclosure, and FIG. 16B is a diagram showing one of the side faces of the thermoelectric generation unit 100 (shown herein is a right side view). As shown in FIG. 16A, this implementation of the thermoelectric generation unit 100 includes a plurality of thermoelectric generation tubes T and a container 30 housing the plurality of thermoelectric generation tubes T inside. Such a structure may appear to resemble the “shell and tube structure” of a heat exchanger. In a heat exchanger, however, the plurality of tubes merely function as pipelines for a fluid to flow through, which do not require electrical connection. In a thermoelectric generation system according to the present disclosure, stable electrical connection needs to be achieved between tubes for practicality, unlike in a heat exchanger.

As has been described with reference to FIG. 13, the hot medium and the cold medium are supplied to the thermoelectric generation unit 100. For example, through a plurality of openings A, a hot medium is supplied in the internal flow path of each of the thermoelectric generation tubes T1 to T10. On the other hand, a cold medium is supplied inside the container 30 via a fluid inlet port 38a described later. As a result, a temperature difference is introduced between the outer peripheral surface and the inner peripheral surface of each thermoelectric generation tube T. At this time, in the thermoelectric generation unit 100, heat exchange occurs between the hot medium and the cold medium, and an electromotive force occurs in each of the thermoelectric generation tubes T1 to T10 in the respective axial direction.

The container 30 in the present embodiment includes a cylindrical shell 32 surrounding the thermoelectric generation tubes T, and a pair of plates 34 and 36 provided so as to close both open ends of the shell 32. More specifically, the plate 34 is fixed on the left end of the shell 32, whereas the plate 36 is fixed on the right end of the shell 32. The plates 34 and 36 each have a plurality of openings A through which the thermoelectric generation tubes T are respectively inserted, such that both ends of each thermoelectric generation tube T are inserted into the corresponding pair of openings A in the plates 34 and 36.

Similarly to the tube sheets of a shell and tube heat exchanger, the plates 34 and 36 have the function of supporting a plurality of tubes (i.e., the thermoelectric generation tubes T) so that these tubes are spatially separated from each other. However, as will be described in detail later, the plates 34 and 36 of the present embodiment have an electrical connection capability that the tube sheets of a heat exchanger do not have.

In the example shown in FIG. 16A, the plate 34 includes a first plate portion 34a which is fixed on the shell 32, and a second plate portion 34b which is detachably mounted to the first plate portion 34a. Similarly, the plate 36 includes a first plate portion 36a which is fixed on the shell 32, and a second plate portion 36b which is detachably mounted to the first plate portion 36a. The openings A in the plates 34 and 36 penetrate through, respectively, the first plate portions 34a and 36a and the second plate portions 34b and 36b, thus leaving the flow paths of the thermoelectric generation tubes T open to the exterior of the container 30.

Examples of materials to compose the container 30 include metals such as stainless steels, HASTELLOY™ or INCONEL™. Examples of other materials to compose the container 30 include polyvinyl chloride and acrylic resin. The shell 32 and the plates 34, 36 may be made of the same material, or made of different materials. If the shell 32 and the first plate portions 34a and 36a are made of a metal(s), the first plate portions 34a and 36a may be welded onto the shell 32. If flanges are provided at both ends of the shell 32, the first plate portions 34a and 36a may be fixed onto such flanges.

During operation, a fluid (i.e., the cold medium or the hot medium) is introduced into the container 30. Therefore, the inside of the container 30 should be kept either airtight or watertight. As will be described later, each opening A of the plates 34, 36 is sealed in an airtight or watertight manner once the ends of a thermoelectric generation tube T are inserted through the opening A. Also, no gap is left between the shell 32 and the plates 34 and 36, thus realizing a structure which is kept airtight or watertight throughout the operation.

As shown in FIG. 16B, ten openings A are provided in the plate 36. Similarly, ten openings A are provided in the plate 34. In the example shown in FIGS. 16A and 16B, the openings A in the plate 34 and the openings A in the plate 36 are placed in mirror symmetric relationship, such that the ten lines connecting the center points of the corresponding pair of openings A are parallel to one another. With this construction, each thermoelectric generation tube T can be supported in parallel by the corresponding pair of openings A. In the container 30, the plurality of thermoelectric generation tubes T do not need to be in a parallel relationship, but may be in a “non-parallel” or “skew” relationship.

As shown in FIG. 16B, the plate 36 has channels (which hereinafter may be referred to as “connection grooves”) C which are formed so as to interconnect at least two of the openings A in the plate 36. In the example shown in FIG. 16B, the channel C61 interconnects the opening A61 and the opening A62. Any other channel C62 to C65 similarly interconnects two of the openings A in the plate 36. As will be described later, an electrically conductive member is housed in each of the channels C61 to C65.

FIG. 17 partially shows an M-M cross section in FIG. 16B. In FIG. 17, a lower half of the container 30 is not shown in cross section; rather, its front is shown. As shown in FIG. 17, the container 30 has the fluid inlet port 38a and a fluid outlet port 38b for allowing a fluid to flow inside. In the thermoelectric generation unit 100, the fluid inlet port 38a and fluid outlet port 38b are disposed in an upper portion of the container 30. The place of the fluid inlet port 38a is not limited to the upper portion of the container 30, but may be the lower portion of the container 30, for example. The same is also true of the fluid outlet port 38b. The fluid inlet port 38a and the fluid outlet port 38b do not need to be used fixedly as an inlet and an outlet of fluid; the inlet and outlet of fluid may be inverted on a regular or irregular basis. The flow direction of fluid does not need to be fixed. The numbers of the fluid inlet port 38a and fluid outlet port 38b do not need to be one each; both or one of the fluid inlet port 38a and fluid outlet port 38b may exist in plurality.

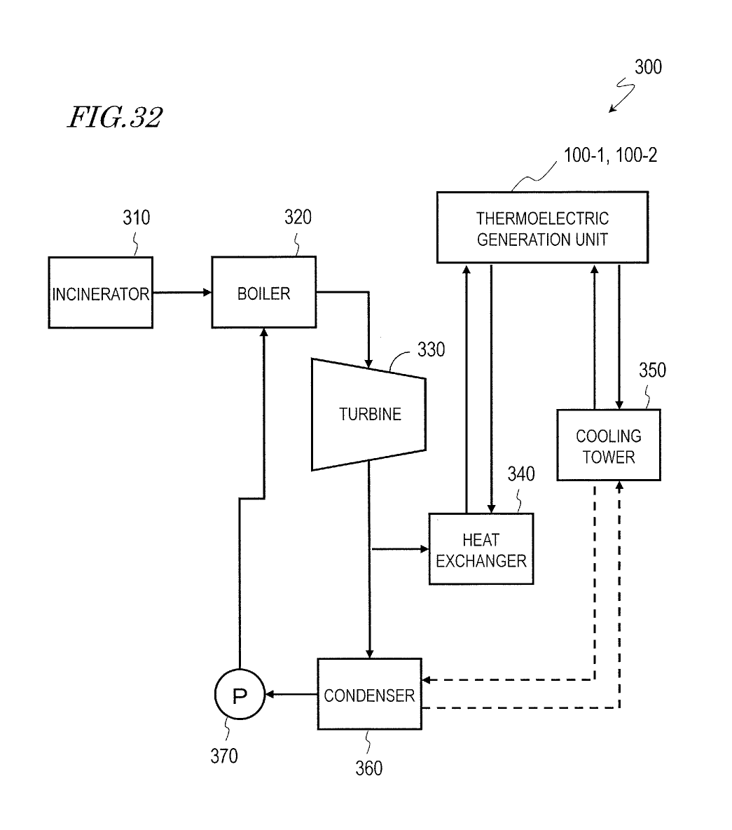

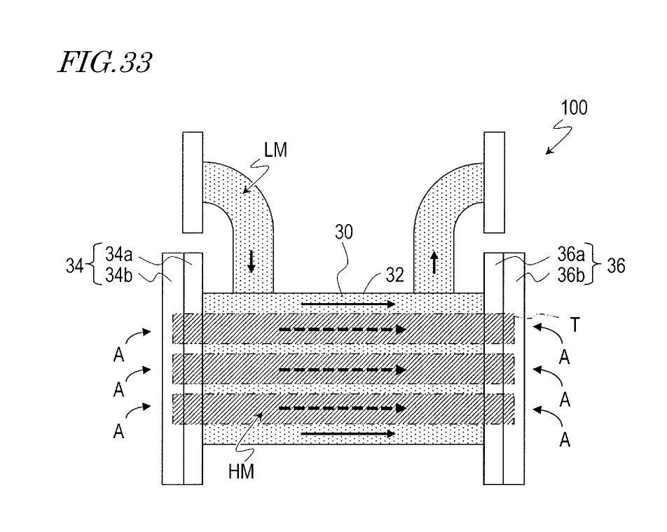

FIG. 33 is a diagram schematically showing an example of flow directions of the hot medium and the cold medium introduced in the thermoelectric generation unit 100. In the example of FIG. 33, a hot medium HM is supplied in the internal flow path of each of the thermoelectric generation tubes T1 to T10, whereas a cold medium LM is supplied inside the container 30. In this case, via the openings A in the plate 34, the hot medium HM is introduced in the internal flow path of each thermoelectric generation tube. The hot medium HM introduced in the internal flow path of each thermoelectric generation tube comes in contact with the inner peripheral surface of the thermoelectric generation tube. On the other hand, the cold medium LM is introduced inside the container 30 from the fluid inlet port 38a. The cold medium LM introduced inside the container 30 comes in contact with the outer peripheral surface of each thermoelectric generation tube.

In the example shown in FIG. 33, while flowing through the internal flow path of each thermoelectric generation tube, the hot medium HM exchanges heat with the cold medium LM. The hot medium HM whose temperature has lowered through heat exchange with the cold medium LM is discharged to the exterior of the thermoelectric generation unit 100 via the openings A in the plate 36. On the other hand, while flowing inside the container 30, the cold medium LM exchanges heat with the hot medium HM. The cold medium LM whose temperature has increased through heat exchange with the hot medium HM is discharged to the exterior of the thermoelectric generation unit 100 from the fluid outlet port 38b. The flow direction of the hot medium HM and the flow direction of the cold medium LM shown in FIG. 33 are only an example. One or both of the hot medium HM and the cold medium LM may flow from the right to the left in the figure.

In one implementation, the hot medium HM (e.g., hot water) may be introduced in the flow path of each thermoelectric generation tube T, and the cold medium LM (e.g., cooling water) may be introduced from the fluid inlet port 38a to fill the inside of the container 30. Conversely, the cold medium LM (e.g., cooling water) may be introduced in the flow path of each thermoelectric generation tube T, and the hot medium HM (e.g., hot water) may be introduced from the fluid inlet port 38a to fill the inside of the container 30. Thus, a temperature difference which is necessary for power generation can be introduced between the outer peripheral surface 24 and the inner peripheral surface 26 of each thermoelectric generation tube T.

<Implementations of Sealing from Fluids and Electrical Connection Between Thermoelectric Generation Tubes>

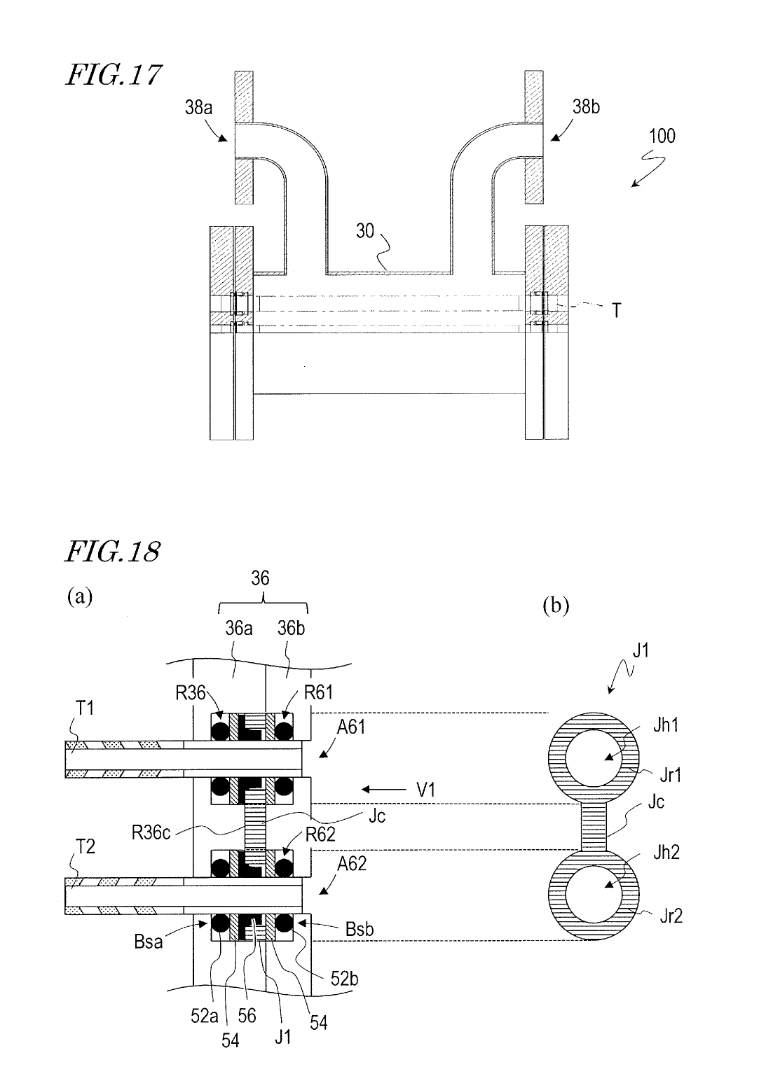

Portion (a) of FIG. 18 schematically illustrates a partial cross-sectional view of the plate 36. Specifically, portion (a) of FIG. 18 schematically illustrates a cross section of the plate 36 as viewed on a plane containing the center axes of both of two thermoelectric generation tubes T1 and T2. More specifically, portion (a) of FIG. 18 illustrates the structure of openings A61 and A62 among multiple openings A that the plate 36 has and a region surrounding them. Portion (b) of FIG. 18 schematically illustrates the appearance of an electrically conductive member J1 as viewed in the direction indicated by the arrow V1 in portion (a) of FIG. 18. This electrically conductive member J1 has two throughholes Jh1 and Jh2. More specifically, this electrically conductive member J1 includes a first ring portion Jr1 having the throughhole Jh1, a second ring portion Jr2 having the throughhole Jh2, and a connecting portion Jc which connects these two ring portions Jr1 and Jr2 together.

As shown in portion (a) of FIG. 18, one end of the thermoelectric generation tube T1 (on the second electrode side) is inserted into the opening A61 of the plate 36 and one end of the thermoelectric generation tube T2 (on the first electrode side) is inserted into the opening A62. In this state, these ends of the thermoelectric generation tubes T1 and T2 are respectively inserted into the throughholes Jh1 and Jh2 of the electrically conductive member J1. This end of the thermoelectric generation tube T1 (on the second electrode side) and this end of the thermoelectric generation tube T2 (on the first electrode side) are electrically connected together via this electrically conductive member J1. In the present specification, an electrically conductive member to connect two thermoelectric generation tubes electrically together will be hereinafter referred to as a “connection plate”.

It should be noted that the first and second ring portions Jr1 and Jr2 do not need to have an annular shape. As long as electrical connection is established between the thermoelectric generation tubes, the throughhole Jh1 or Jh2 may also have a circular, elliptical or polygonal shape. For example, the shape of the throughhole Jh1 or Jh2 may be different from the cross-sectional shape of the first or second electrode E1 or E2 as viewed on a plane that intersects with the axial direction at right angles. In the present specification, a “ring” shape includes not only an annular shape but also other shapes.

In the example illustrated in portion (a) of FIG. 18, the first plate portion 36a has a recess R36 which has been cut for the openings A61 and A62. The recess R36 includes a groove portion R36c to connect the openings A61 and A62 together. The connecting portion Jc of the electrically conductive member J1 is located in this groove portion R36c. On the other hand, recesses R61 and R62 have been cut in the second plate portion 36b for the openings A61 and A62, respectively. In this example, various members to establish sealing and electrical connection are arranged inside the space formed by these recesses R36, R61 and R62. That space forms a channel C61 to house the electrically conductive member J1 and the openings A61 and A62 are connected together via the channel C61.

In the example illustrated in portion (a) of FIG. 18, not only the electrically conductive member J1 but also a first O-ring 52a, washers 54, an electrically conductive ring member 56 and a second O-ring 52b are housed in the channel C61. The respective ends of the thermoelectric generation tubes T1 and T2 go through the holes of these members. The first O-ring 52a arranged closest to the shell 32 of the container 30 is in contact with the seating surface Bsa that has been formed in the first plate portion 36a and establishes sealing so as to prevent a fluid that has been supplied into the shell 32 from entering the channel C61. On the other hand, the second O-ring 52b arranged most distant from the shell 32 of the container 30 is in contact with a seating surface Bsb that has been formed in the second plate portion 36b and establishes sealing so as to prevent a fluid located outside of the second plate portion 36b from entering the channel C61.

The O-rings 52a and 52b are annular seal members with an O (i.e., circular) cross section. The O-rings 52a and 52b may be made of rubber, metal or plastic, for example, and have the function of preventing a fluid from leaking out, or flowing into, through a gap between the members. In portion (a) of FIG. 18, there is a space which communicates with the flow paths of the respective thermoelectric generation tubes T on the right-hand side of the second plate portion 36b and there is a fluid (the hot or cold medium in this example) in that space. According to the present embodiment, by using the members shown in FIG. 18, electrical connection between the thermoelectric generation tubes T and sealing from the fluids (the hot and cold media) are established. The structure and function of the electrically conductive ring member 56 will be described in detail later.

The same members as those described for the plate are provided for the plate 34, too. Although the respective openings A of the plates 34 and 36 are arranged mirror symmetrically, the groove portions connecting any two openings A together on the plate 34 are not arranged mirror symmetrically with the groove portions connecting any two openings A together on the plate 36. If the arrangement patterns of the electrically conductive members to electrically connect the thermoelectric generation tubes T together on the plates 34 and 36 were mirror symmetric to each other, then those thermoelectric generation tubes T could not be connected together in series.

When a plate (such as the plate 36) fixed onto the shell 32 includes first and second plate portions (36a and 36b) as in the present embodiment, each of the multiple openings A cut through the first plate portion (36a) has a first seating surface (Bsa) associated therewith to receive the first O-ring 52a, and each of the multiple openings A cut through the second plate portion (36b) has a second seating surface (Bsb) associated therewith to receive the second O-ring 52b. However, the plates 34 and 36 do not need to have the construction shown in FIG. 18, and the plate 36 does not need to be divided into the first and second plate portions 36a and 36b, either. If the electrically conductive member J1 is pressed by another member instead of the second plate portion 36b, the respective first O-rings 52a press against the first seating surface (Bsa) to establish sealing, too.

In the example shown in portion (a) of FIG. 18, the electrically conductive ring member 56 is interposed between the thermoelectric generation tube T1 and the electrically conductive member J1. Likewise, another electrically conductive ring member 56 is interposed between the thermoelectric generation tube T2 and the electrically conductive member J1, too.

The electrically conductive member J1 is typically made of a metal. Examples of materials to compose the electrically conductive member J1 include copper (oxygen-free copper), brass and aluminum. The material may be plated with nickel or tin for anticorrosion purposes. As long as electrical connection is established between the electrically conductive member J (e.g., J1 in this example) and the thermoelectric generation tubes T (e.g., T1 and T2 in this example) inserted into the two throughholes of the electrically conductive member J (e.g., Jh1 and Jh2 in this example), the electrically conductive member J may be partially coated with an insulator. That is, the electrically conductive member J may include a body made of a metallic material and an insulating coating which covers the surface of the body at least partially. The insulating coating may be made of a resin such as TEFLON™, for example. When the body of the electrically conductive member J is made of aluminum, the surface may be partially coated with an oxide skin as an insulating coating.

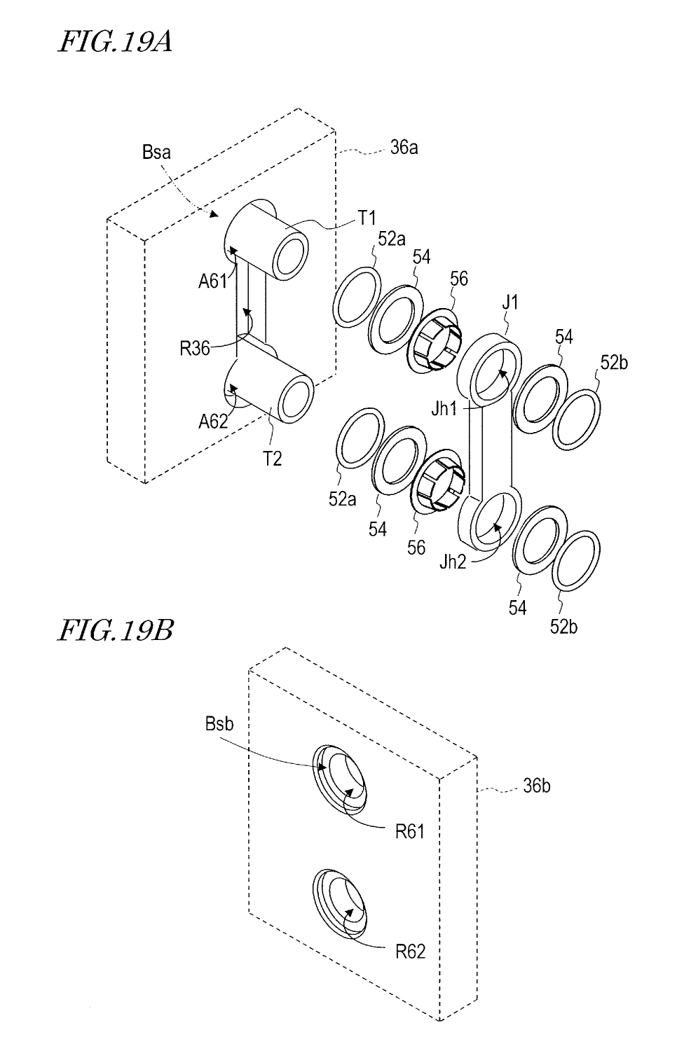

FIG. 19A is an exploded perspective view schematically illustrating the channel C61 to house the electrically conductive member J1 and its vicinity. As shown in FIG. 19A, the first O-rings 52a, electrically conductive ring members 56, electrically conductive member J1 and second O-rings 52b are inserted into the openings A61 and A62 from outside of the container 30. In this example, washers 54 are arranged between the first O-rings 52a and the electrically conductive ring members 56. Washers 54 may also be arranged between the electrically conductive member J1 and the second O-rings 52b. The washers 54 are inserted between the flat portions 56f of the electrically conductive ring members 56 to be described later and the O-rings 52a (or 52b).

FIG. 19B schematically illustrates a portion of the sealing surface of the second plate portion 36b (i.e., the surface that faces the first plate portion 36a) associated with the openings A61 and A62. As described above, the openings A61 and A62 of the second plate portion 36b each have a seating surface Bsb to receive the second O-ring 52b. Therefore, when the respective sealing surfaces of the first and second plate portions 36a and 36b are arranged to face each other and fastened together by flange connection, for example, the first O-rings 52a in the first plate portion 36a can be pressed against the seating surfaces Bsa. More specifically, the second seating surfaces Bsb press the first O-rings 52a against the seating surfaces Bsa through the second O-rings 52b, electrically conductive member J1 and electrically conductive ring members 56. In this manner, the electrically conductive member J1 can be sealed from the hot and cold media.

When the first and second plate portions 36a and 36b are made of an electrically conductive material such as a metal, the sealing surfaces of the first and second plate portions 36a and 36b may be coated with an insulator material. Parts of the first and second plate portions 36a and 36b to come in contact with the electrically conductive member J during operation may be coated with an insulator so as to be electrically insulated from the electrically conductive member J. In one implementation, the sealing surfaces of the first and second plate portions 36a and 36b may be sprayed and coated with a fluoroethylene resin.

<Detailed Construction for Electrically Conductive Ring Members>

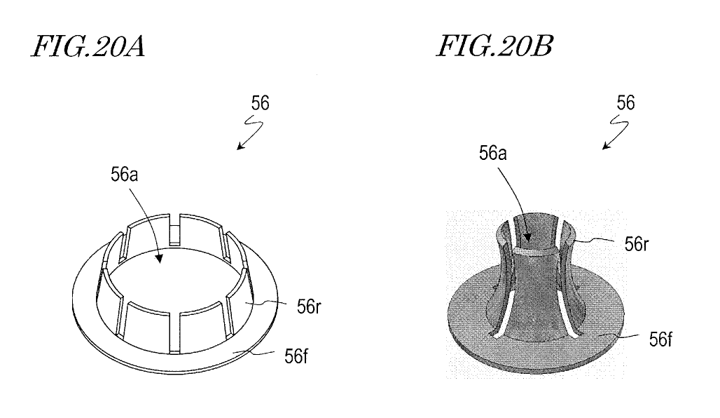

A detailed construction for the electrically conductive ring members 56 will be described with reference to FIGS. 20A and 20B.

FIG. 20A is a perspective view illustrating an exemplary shape of an electrically conductive ring member 56. The electrically conductive ring member 56 shown in FIG. 20A includes an annular flat portion 56f and a plurality of elastic portions 56r. The flat portion 56f has a throughhole 56a. Those elastic portions 56r project from the periphery of the throughhole 56a of the flat portion 56f and are biased toward the center of the throughhole 56a with elastic force. Such an electrically conductive ring member 56 can be easily made by patterning a single metallic plate (with a thickness of 0.1 mm to a few mm, for example). Likewise, the electrically conductive members J can also be easily made by patterning a single metallic plate (with a thickness of 0.1 mm to a few mm, for example).

An end (on the first or second electrode side) of an associated thermoelectric generation tube T is inserted into the throughhole 56a of each electrically conductive ring member 56. Therefore, the shape and size of the throughhole 56a of the annular flat portion 56f are designed so as to match the shape and size of that end (on the first or second electrode side) of the thermoelectric generation tube T.

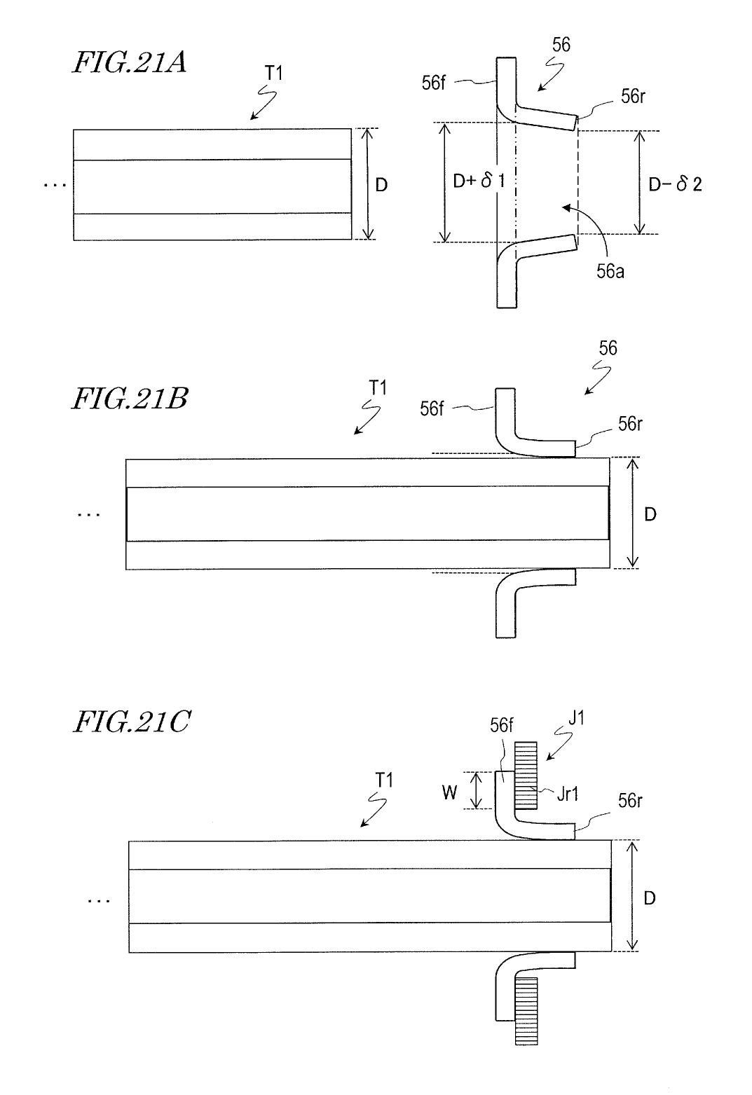

Next, the shape of the electrically conductive ring member 56 will be described in further detail with reference to FIGS. 21A, 21B and 21C. FIG. 21A is a cross-sectional view schematically illustrating portions of the electrically conductive ring member 56 and thermoelectric generation tube T1. FIG. 21B is a cross-sectional view schematically illustrating a state where an end of the thermoelectric generation tube T1 has been inserted into the electrically conductive ring member 56. FIG. 21C is a cross-sectional view schematically illustrating a state where an end of the thermoelectric generation tube T1 has been inserted into the respective throughholes of the electrically conductive ring member 56 and electrically conductive member J1. The cross sections illustrated in FIGS. 21A, 21B and 21C are viewed on a plane containing the axis (i.e., the center axis) of the thermoelectric generation tube T1.

Suppose the outer peripheral surface of the thermoelectric generation tube T1 at that end (on the first or second electrode side) is a circular cylinder with a diameter D as shown in FIG. 21A. In that case, the throughhole 56a of the electrically conductive ring member 56 is formed in a circular shape with a diameter D+δ1 (where ≡1>0) so as to allow the end of the thermoelectric generation tube T1 to pass through. On the other hand, the respective elastic portions 56r have been formed so that biasing force is applied toward the center of the throughhole 56a. The respective elastic portions 56r may be formed so as to be tilted toward the center of the throughhole 56a as shown in FIG. 21A. That is, the elastic portions 56r have been shaped so as to be circumscribed by the outer peripheral surface of a circular cylinder, of which a cross section has a diameter that is smaller than D (and that is represented by D−δ2 (where δ2>0)) unless any external force is applied.

D+δ1>D>D−δ2 is satisfied. Thus, when the end of the thermoelectric generation tube T1 is inserted into the throughhole 56a, the respective elastic portions 56r are brought into physical contact with the outer peripheral surface at the end of the thermoelectric generation tube T1 as shown in FIG. 21B. In this case, since elastic force is applied to the respective elastic portions 56r toward the center of the throughhole 56a, the respective elastic portions 56r press the outer peripheral surface at the end of the thermoelectric generation tube T1 with the elastic force. In this manner, the outer peripheral surface of the thermoelectric generation tube T1 inserted into the throughhole 56a establishes stabilized physical and electrical contact with those elastic portions 56r.

Next, look at FIG. 21C. Inside the opening A cut through the plate 34, 36, the electrically conductive member J1 is in contact with the flat portion 56f of the electrically conductive ring member 56. More specifically, when the end of the thermoelectric generation tube T1 is inserted into the electrically conductive ring member 56 and electrically conductive member J1, the surface of the flat portion 56f of the electrically conductive ring member 56 is in contact with the surface of the ring portion Jr1 of the electrically conductive member J1 as shown in FIG. 21C. As can be seen, in the present embodiment, the electrically conductive ring member 56 and the electrically conductive member J1 may be electrically connected together by bringing their planes into contact with each other. Since the electrically conductive ring member 56 and the electrically conductive member J1 are in contact with each other on their planes, a contact area which is large enough to make the electric current generated in the thermoelectric generation tube T1 flow can be secured. The width W of the flat portion 56f is set appropriately to secure a contact area which is large enough to make the electric current generated in the thermoelectric generation tube T1 flow. So long as a contact area can be secured between the electrically conductive ring member 56 and the electrically conductive member J1, either the surface of the flat portion 56f or the surface of the ring portion Jr1 of the electrically conductive member J1 may have some unevenness. For example, an even larger area of contact can be secured when the surface of the ring portion Jr1 of the electrically conductive member J1 is allowed to have an embossed pattern matching that on the surface of the flat portion 56f.

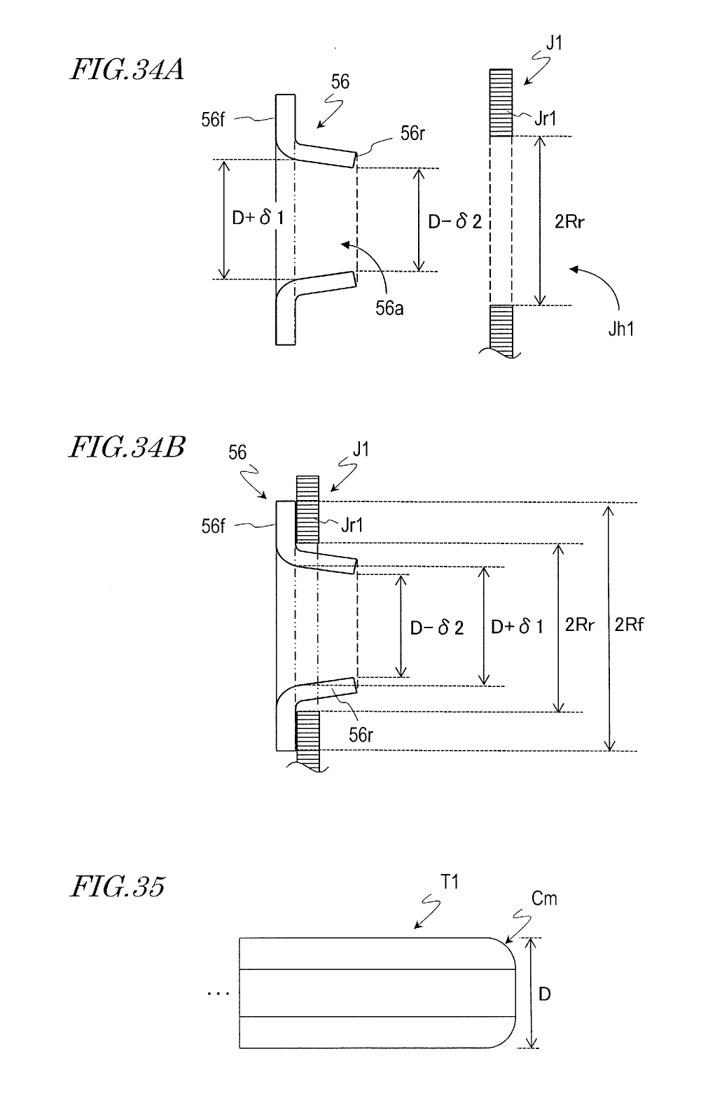

Next, look at FIGS. 34A and 34B. FIG. 34A is a cross-sectional view schematically illustrating the electrically conductive ring member 56 and a portion of the electrically conductive member J1. FIG. 34B is a cross-sectional view schematically illustrating a state where the elastic portions 56r of the electrically conductive ring member 56 have been inserted into the throughhole Jh1 of the electrically conductive member J1. The cross sections shown in FIGS. 34A and 34B are obtained by viewing the electrically conductive ring member 56 and the electrically conductive member J1 on a plane containing the axis (center axis) of the thermoelectric generation tube T1.

Assuming a diameter 2Rr of the throughhole (e.g., Jh1 in this case) of the electrically conductive member J, the throughhole of the electrically conductive member J is formed so as to satisfy D<2Rr (i.e., so as to allow the end of the thermoelectric generation tube T1 to pass through). Also, assuming a diameter 2Rf of the flat portion 56f of the electrically conductive ring member 56, the throughhole of the electrically conductive member J is formed so as to satisfy 2Rr<2Rf, so that the respective surfaces of the flat portion 56f and ring portion Jr1 are in contact with each other just as intended.

Optionally, the end of the thermoelectric generation tube T may have a chamfered portion Cm as shown in FIG. 35. The reason is that, when the end of the thermoelectric generation tube T (e.g., thermoelectric generation tube T1) is inserted into the throughhole 56a of the electrically conductive ring member 56, the elastic portions 56r of the electrically conductive ring member 56 and the end of the thermoelectric generation tube T are in contact with each other, thus possibly damaging the end of the thermoelectric generation tube T. However, by providing such a chamfered portion Cm at the end of the thermoelectric generation tube T, such damage to the end of the thermoelectric generation tube T arising from contact between the elastic portions 56r and the end of the thermoelectric generation tube T can be avoided. By avoiding the occurrence of the damage on the end of the thermoelectric generation tube T, the electrically conductive member J can be sealed more securely from the hot and cold media. In addition, electrical contact failure between the outer peripheral surface of the thermoelectric generation tube T and the elastic portions 56r can also be reduced. The chamfered portion Cm may have a curved surface as shown in FIG. 35, or have a planar surface.

In this manner, the electrically conductive member J1 is electrically connected to the outer peripheral surface at the end of the thermoelectric generation tube T via the electrically conductive ring member 56. According to the present embodiment, by fastening the first and second plate portions 36a and 36b together, the flat portion 56f of the electrically conductive ring member 56 and the electrically conductive member J can make electrical contact with each other with good stability, and sealing described above can be established.

Furthermore, by arranging the electrically conductive ring member 56 with respect to the end of the thermoelectric generation tube T, the electrically conductive member J1 can be sealed more tightly. As described above, the first O-ring 52a is pressed against the seating surface Bsa via the electrically conductive member J1 and the electrically conductive ring member 56. In this case, the electrically conductive ring member 56 has the flat portion 56f. That is, the pressure is applied to the first O-ring 52a through the flat portion 56f of the electrically conductive ring member 56. In other words, since the electrically conductive ring member 56 has the flat portion 56f, the pressure can be applied evenly to the first O-ring 52a. As a result, the first O-ring 52a can be pressed against the seating surface Bsa firmly enough to achieve sealing just as intended from the fluid in the container. In the same way, proper pressure can also be applied to the second O-ring 52b, so that sealing with respect to any fluid outside of the container can be achieved, too.

Next, it will be described how the electrically conductive ring member 56 may be fitted into the thermoelectric generation tube T.

First, as shown in FIG. 19A, the respective ends of the thermoelectric generation tubes T1 and T2 are inserted into the openings A61 and A62 of the first plate portion 36a. After that, the first O-rings 52a (and the washers 54 if necessary) are fitted into the thermoelectric generation tubes through their tip ends and pushed deeper into the openings A61 and A62. Next, the electrically conductive ring members 56 are fitted into the thermoelectric generation tubes through their tip ends and pushed deeper into the openings A61 and A62. Subsequently, the electrically conductive member J1 (and the washers 54 and second O-rings 52b if necessary) is/are fitted into the thermoelectric generation tubes through their tip ends and pushed deeper into the openings A61 and A62. Finally, the sealing surface of the second plate portion 36b is arranged to face the first plate portion 36a and the first and second plate portions 36a and 36b are fastened together by flange connection, for example, so that the respective tip ends of the thermoelectric generation tubes are inserted into the openings of the second plate portion 36b. In this case, the first and second plate portions 36a and 36b may be fastened together with bolts and nuts through the holes 36bh cut through the second plate portion 36b (shown in FIG. 16B) and the holes cut through the first plate portion 36a.

The electrically conductive ring member 56 is not connected permanently to, and is readily removable from, the thermoelectric generation tube T. For example, when the thermoelectric generation tube T is replaced with a new thermoelectric generation tube T, to remove the electrically conductive ring member 56 from the thermoelectric generation tube T, the operation of fitting the electrically conductive ring members 56 into the thermoelectric generation tubes T may be performed in reverse order. The electrically conductive ring member 56 may be used a number of times (i.e., is recyclable) or replaced with a new one.

The electrically conductive ring member 56 does not always need to have the exemplary shape shown in FIG. 20A. The ratio of the width of the flat portion 56f (as measured radially) to the radius of the throughhole 56a may also be defined arbitrarily. The respective elastic portions 56r may have any of various shapes, and the number of elastic portions 56r to be provided may be set arbitrarily, too.

FIG. 20B is a perspective view illustrating another exemplary shape of the electrically conductive ring member 56. The electrically conductive ring member 56 shown in FIG. 20B also has an annular flat portion 56f and a plurality of elastic portions 56r. The flat portion 56f has a throughhole 56a. Each of the elastic portions 56r projects from around the throughhole 56a of the flat portion 56f and is biased toward the center of the throughhole 56a with elastic force. In this example, the number of the elastic portions 56r to provide is four. The number of the elastic portions 56r may be two but is suitably three or more. For example, six or more elastic portions 56r may be provided.

It should be noted that according to such an arrangement in which the flat-plate electrically conductive member J is brought into contact with the flat portion 56f of the electrically conductive ring member 56, some gap (or clearance) may be left between the throughhole inside the ring portion of the electrically conductive member J and the thermoelectric generation tube to be inserted into the hole. Thus, even if the thermoelectric generation tube is made of a brittle material, the thermoelectric generation tube can also be connected with good stability without allowing the ring portion Jr1 of the electrically conductive member J to damage the thermoelectric generation tube.

<Electrical Connection Via Connection Plate>

As described above, the electrically conductive member (connection plate) is housed inside the channel C which has been cut to interconnect at least two of the openings A that have been cut through the plate 36. Note that the respective ends of the two thermoelectric generation tubes may be electrically connected together with a member other than the electrically conductive ring members 56. In other words, the electrically conductive ring members 56 may be omitted from the channel C. In that case, the respective ends of the two thermoelectric generation tubes may be electrically connected together via an electric cord, a conductor bar, or electrically conductive paste, for example. If the ends of the two thermoelectric generation tubes are electrically connected together via an electric cord, those ends of the thermoelectric generation tubes and the cord may be electrically connected together by soldering, crimping or crocodile-clipping, for example.

However, by electrically connecting the respective ends of the two thermoelectric generation tubes via the electrically conductive member that is housed in the channel C as shown in FIGS. 18, 19A and 19B, the respective ends of the thermoelectric generation tubes T and the electrically conductive member J1 can be electrically connected together more stably. When the electrically conductive member J has a flat plate shape (e.g., when the connecting portion Jc has a broad width), the electrical resistance between the two thermoelectric generation tubes can be reduced compared to a situation where an electric cord is used. In addition, since no terminals are fixed onto the ends of the thermoelectric generation tubes T, the thermoelectric generation tubes T can be replaced easily. Alternatively, with the electrically conductive ring members 56, the respective ends of the two thermoelectric generation tubes can be not only fixed to each other but also electrically connected together.

In the thermoelectric generator unit 100, the plate 34 or 36 has the channel C formed so as to connect together at least two of the openings A. Thus, an electrical connecting function which has never been provided by any tube sheet for a heat exchanger is realized. In addition, since the thermoelectric generator unit 100 can be constructed so that the first and second O-rings 52a and 52b press the seating surfaces Bsa and Bsb, respectively, sealing can be established so that either airtight or watertight condition is maintained with the ends of the thermoelectric generation tubes T inserted. As can be seen, by providing the channel C for the plate 34 or 36, even in an implementation in which the electrically conductive ring members 56 are omitted, the ends of the two thermoelectric generation tubes can also be electrically connected together and sealing from the fluids (e.g., the hot and cold media) can also be established.

<Relationship Between the Direction of Heat Flow and the Direction of Inclination of Planes of Stacking>

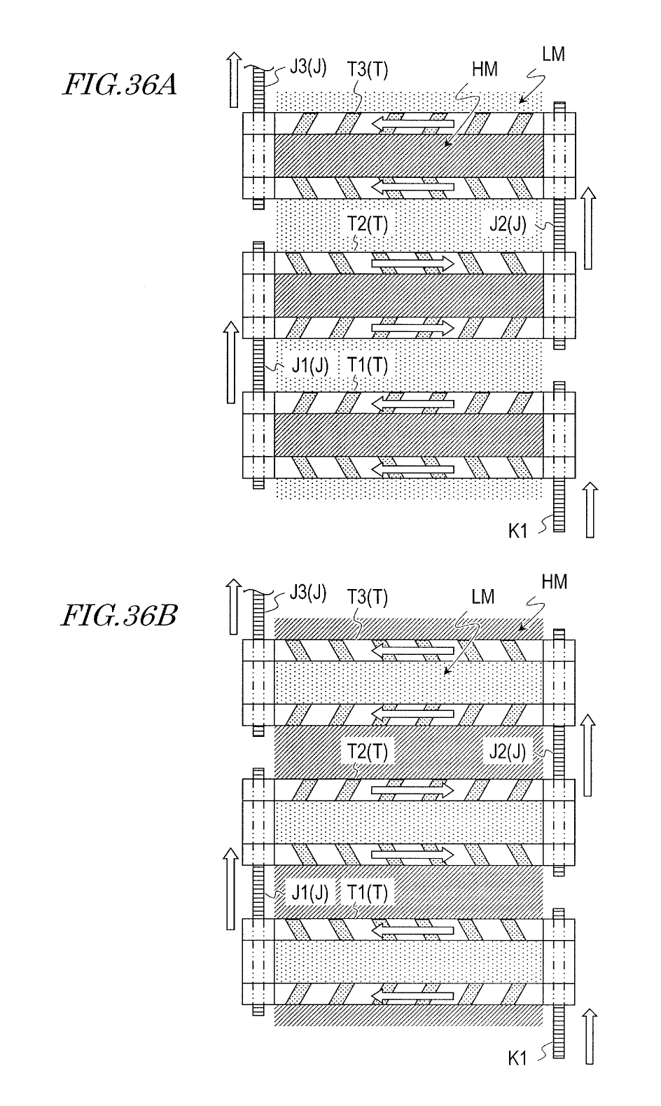

Now, with reference to FIGS. 36A and 36B, the relationship between the direction of heat flow in each thermoelectric generation tube T and the direction of inclination of the planes of stacking in the thermoelectric generation tube T will be described.

FIG. 36A is a diagram schematically showing an electric current flowing in thermoelectric generation tubes T which are connected in electrical series. FIG. 36A schematically shows cross sections of three (T1 to T3) of the thermoelectric generation tubes T1 to T10.

In FIG. 36A, an electrically conductive member K1 is connected to one end of the thermoelectric generation tube T1 (e.g., the end at the first electrode side), whereas the electrically conductive member (connection plate) J1 is connected to the other end (e.g., the end at the second electrode side) of the thermoelectric generation tube T1. The electrically conductive member J1 is also connected to one end (i.e., the end at the first electrode side) of the thermoelectric generation tube T2, whereby the thermoelectric generation tube T1 and the thermoelectric generation tube T2 are electrically connected. Furthermore, the other end (i.e., the end at the second electrode side) of the thermoelectric generation tube T2 and one end (i.e., the end at the first electrode side) of the thermoelectric generation tube T3 are electrically connected by the electrically conductive member J2.

In this case, as shown in FIG. 36A, the direction of inclination of the planes of stacking in the thermoelectric generation tube T1 is opposite to the direction of inclination of the planes of stacking in the thermoelectric generation tube T2. Similarly, the direction of inclination of the planes of stacking in the thermoelectric generation tube T2 is opposite to the direction of inclination of the planes of stacking in the thermoelectric generation tube T3. In other words, in the thermoelectric generation unit 100, between each thermoelectric generation tube T1 to T10 and the thermoelectric generation tube that is connected thereto via a connection plate, the direction of inclination of the planes of stacking is reversed.

Now, assume that the hot medium HM is placed in contact with the inner peripheral surface of each of the thermoelectric generation tubes T1 to T3, and the cold medium LM in contact with their outer peripheral surface, as shown in FIG. 36A. Then, in the thermoelectric generation tube T1, an electric current flows from the right to the left in the figure, for example. On the other hand, in the thermoelectric generation tube T2, in which the direction of inclination of the planes of stacking is opposite from that of the thermoelectric generation tube T1, an electric current flows from the left to the right in the figure.

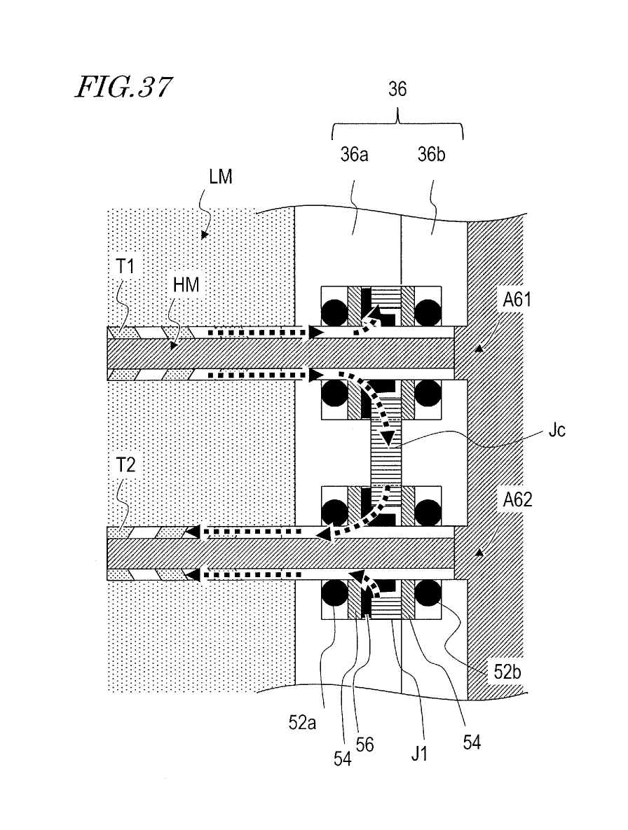

FIG. 37 schematically shows the directions in which an electric current flows through the two openings A61 and A62 and their surrounding region. FIG. 37 is a drawing corresponding to FIG. 19A. In FIG. 37, the flow directions of the electric current are schematically indicated by dotted arrows. As shown in FIG. 37, the electric current generated in the thermoelectric generation tube T1 flows toward the thermoelectric generation tube T2 through the electrically conductive ring member 56 in the opening A61, the electrically conductive member J1, and the electrically conductive ring member 56 in the opening A62 in this order. The electric current that has flowed into the thermoelectric generation tube T2 is combined with electric current generated in the thermoelectric generation tube T2, and the electric current thus combined flows toward the thermoelectric generation tube T3. As shown in FIG. 36A, the planes of stacking of the thermoelectric generation tube T3 are tilted in the opposite direction from those of the thermoelectric generation tube T2. Thus, in the thermoelectric generation tube T3, the electric current flows from the right to the left in FIG. 36A. Consequently, the electromotive forces generated in the respective thermoelectric generation tubes T1 to T3 become superposed upon one another, without canceling one another. By sequentially connecting a plurality of thermoelectric generation tubes T together in this manner so that the tilt direction of their planes of stacking is alternately inverted between generators, an even greater voltage can be extracted from the thermoelectric generator unit.

Next, FIG. 36B is referred to. Similarly to FIG. 36A, FIG. 36B schematically shows directions of an electric current flowing in thermoelectric generation tubes T which are connected in electrical series. As in the example shown in FIG. 36A, FIG. 36B illustrates a case where the thermoelectric generation tubes T1 to T3 are consecutively connected so that the direction of inclination of the planes of stacking is alternately opposite. In this case, too, the direction of inclination of the planes of stacking is reversed between every two interconnected thermoelectric generation tubes, so that the electromotive forces occurring in the thermoelectric generation tubes T1 to T3 do not cancel one another, but are superposed.

If the cold medium LM is placed in contact with the inner peripheral surface of each of the thermoelectric generation tubes T1 to T3 and the hot medium HM in contact with their outer peripheral surface, as shown in FIG. 36B, the polarity of voltages occurring in the respective thermoelectric generation tubes T1 to T3 become opposite to those illustrated in FIG. 36A. In other words, when the direction of temperature gradient in each thermoelectric generation tube is inverted, the polarity of the electromotive force in each thermoelectric generation tube (which may also be said to be the direction of the electric current flowing through each thermoelectric generation tube) is inverted. Therefore, for example, in order to ensure that an electric current flows from the electrically conductive member K1 to the electrically conductive member J3 as in FIG. 36A, the first electrode side and the second electrode side of each of the thermoelectric generation tubes T1 to T3 are to be reversed from the state illustrated in FIG. 36A. Note that electric current directions illustrated in FIGS. 36A and 36B are mere examples. Depending on the material composing the metal layers 20 and the thermoelectric material composing the thermoelectric material layers 22, the electric current directions may become opposite to the electric current directions shown in FIGS. 36A and 36B.

As already described with reference to FIGS. 36A and 36B, the polarity of the voltage generated in a thermoelectric generation tube T depends on the tilt direction of the planes of stacking of that thermoelectric generation tube T. Therefore, when the thermoelectric generation tube T is to be replaced, for example, the thermoelectric generation tube T is appropriately arranged by taking into account the temperature gradient between the inner and outer peripheral surfaces of the thermoelectric generation tube T in the thermoelectric generator unit 100.

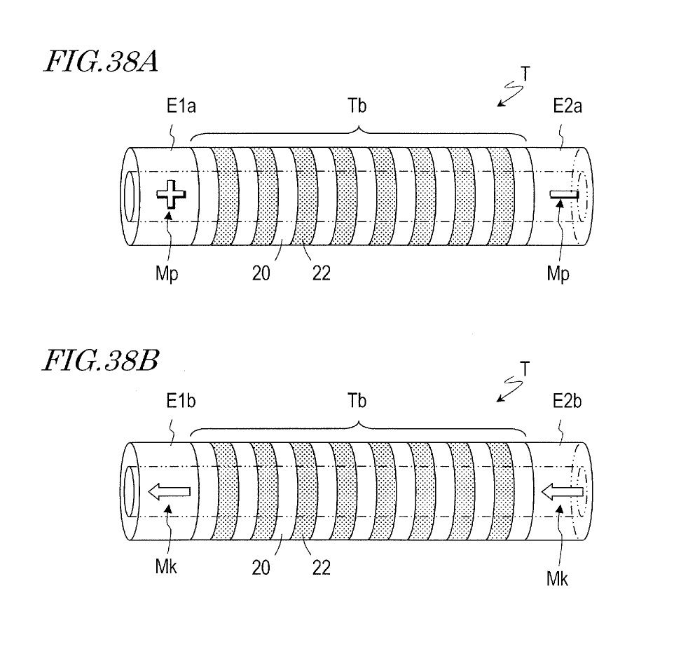

FIGS. 38A and 38B are perspective views each illustrating an exemplary thermoelectric generation tube, the electrodes of which have indicators of their polarity. In the thermoelectric generation tube T shown in FIG. 38A, molded portions (embossed marks) rip indicating the polarity of the voltage generated in the thermoelectric generation tube are formed on the first and second electrodes E1a and E2a. On the other hand, in the thermoelectric generation tube T shown in FIG. 38B, marks Mk indicating whether the planes of stacking in the thermoelectric generation tube T are tilted toward the first electrode E1b or the second electrode E2b are provided on the first and second electrodes E1b and E2b. These molded portions (e.g., convex or concave portions) and marks may be combined together. These molded portions and marks may be added to the tube body Tb, or to only one of the first and second electrodes.

In this manner, molded portions or marks indicating the polarity of the voltage generated in the thermoelectric generation tube T may be added to the first and second electrodes, for example. In that case, it can be known from the appearance of the thermoelectric generation tube T whether the planes of stacking of the thermoelectric generation tube T are tilted toward the first electrode or the second electrode. Instead of adding such molded portions or marks, the first and second electrodes may be given mutually different shapes. For example, difference may be introduced between the first and second electrodes with respect to their lengths, thicknesses or cross-sectional shapes as viewed on a plane that intersects with the axial direction at right angles.

<Electrical Connection Structure for Retrieving Electric Power to the Exterior of the Thermoelectric Generation Unit 100>

FIG. 15 is referred to again. In the example shown in FIG. 15, ten thermoelectric generation tubes T1 to T10 are connected in electrical series by the electrically conductive members J1 to J9. The connection between two thermoelectric generation tubes T provided by each of the electrically conductive members J1 to J9 is as described above. Hereinafter, an example electrical connection structure for retrieving electric power to the exterior of the thermoelectric generation unit 100 from the two generation tubes T1 and T10 located at both ends of the series circuit will be described.

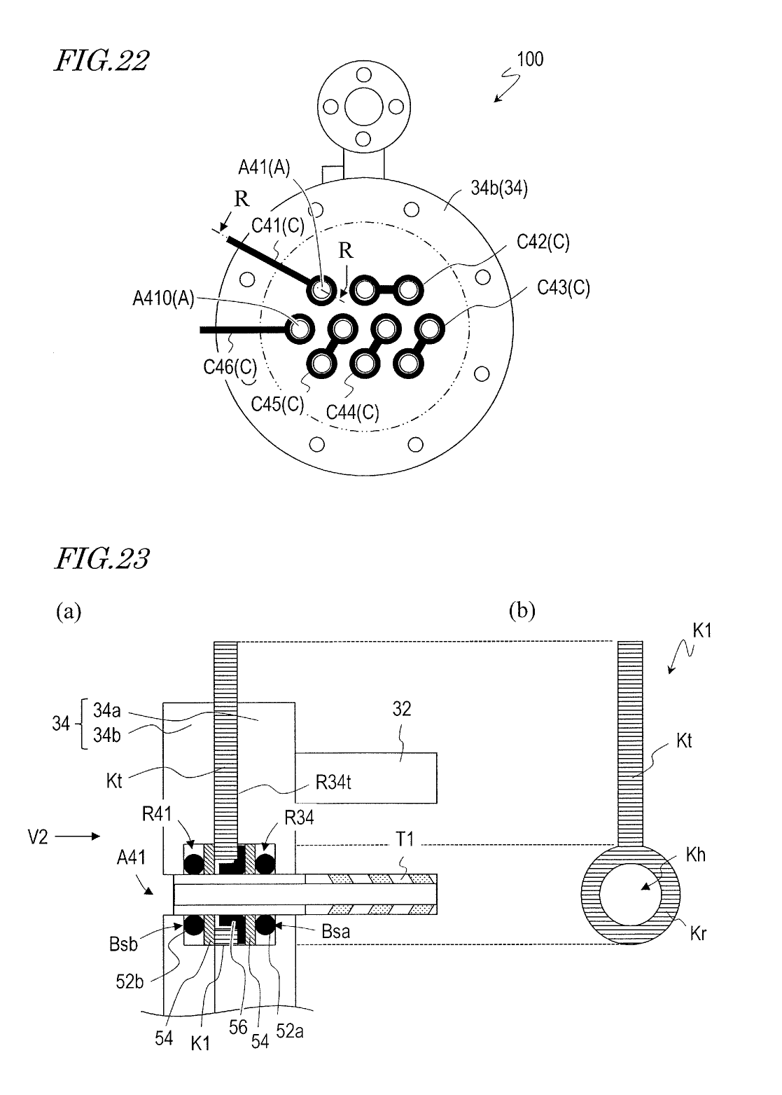

FIG. 22 is referred to. FIG. 22 is a diagram showing the other side face of the thermoelectric generation unit 100 shown in FIG. 16A (left side view). While FIG. 16B shows construction around the plate 36, FIG. 22 shows construction around the plate 34. Description of any constituent or operation that has been described with respect to the plate 36 will not be repeated.

As shown in FIG. 22, the channels C42 to C45 interconnect at least two of the openings A provided in the plate 34. In the present specification, such channels may be referred to as “interconnections”. The electrically conductive members housed in these interconnections have similar construction to that of the electrically conductive member J1. On the other hand, the channel C41 in the plate extends from the opening A41 to the outer edge of the plate 34. In the present specification, a channel which extends from an opening in a plate to its outer edge may be referred to as a “terminal connection”. The channels C41 and C46 shown in FIG. 22 are terminal connections. In each terminal connection, the electrically conductive member functioning as a terminal for connecting to an external circuit is housed.

Portion (a) of FIG. 23 is a schematic partial cross-sectional view of the plate 34. Specifically, portion (a) of FIG. 23 schematically illustrates a cross section of the plate 34 as viewed on a plane containing the center axis of the thermoelectric generation tube T1 and corresponding to the plane R-R shown in FIG. 22. More specifically, portion (a) of FIG. 23 illustrates the structure of one A41 of multiple openings A in the plate 34 and its surrounding region. Portion (b) of FIG. 23 illustrates the appearance of an electrically conductive member K1 as viewed in the direction indicated by the arrow V2 in portion (a) of FIG. 23. This electrically conductive member K1 has a throughhole Kh at one end. More specifically, this electrically conductive member K1 includes a ring portion Kr with the throughhole Kh and a terminal portion Kt extending outward from the ring portion Kr. Similarly to the electrically conductive member J1, this electrically conductive member K1 is also typically made of a metal.

As shown in portion (a) of FIG. 23, one end of the thermoelectric generation tube T1 (on the first electrode side) is inserted into the opening A41 of the plate 34. In this state, the end of the thermoelectric generation tube T1 is inserted into the throughhole Kh of the electrically conductive member K1. As can be seen, an electrically conductive member J or K1 according to the present embodiment can be said to be an electrically conductive plate with at least one hole to allow the thermoelectric generation tube T to pass through. The structure of the opening A410 and its surrounding region is the same as that of the opening A41 and its surrounding region except that the end of the thermoelectric generation tube T10 is inserted into the opening A410 of the plate 34.

In the example illustrated in portion (a) of FIG. 23, the first plate portion 34a has a recess R34 which has been cut for the opening A41. The recess R34 includes a groove portion R34t which extends from the opening A41 to the outer edge of the first plate portion 34a. In this groove portion R34t, the terminal portion Kt of the electrically conductive member K1 is located. In this example, the space defined by the recess R34 and a recess R41 which has been cut in the second plate portion 34b forms a channel to house the electrically conductive member K1. As in the example illustrated in portion (a) of FIG. 18, not only the electrically conductive member K1 but also a first O-ring 52a, washers 54, an electrically conductive ring member 56 and a second O-ring 52b are housed in the channel C41 in the example illustrated in portion (a) of FIG. 23, too. The end of the thermoelectric generation tube T1 goes through the holes of these members. The first O-ring 52a establishes sealing so as to prevent a fluid that has been supplied into the shell 32 from entering the channel C41. On the other hand, the second O-ring 52b establishes sealing so as to prevent a fluid located outside of the second plate portion 34b from entering the channel C41.

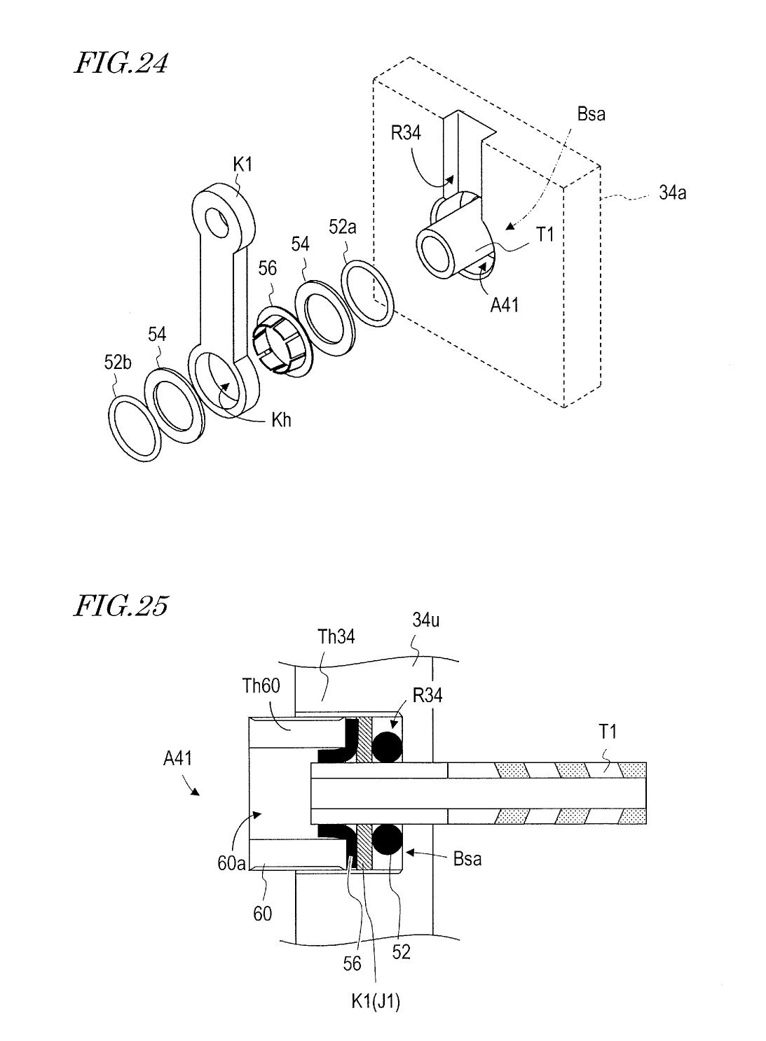

FIG. 24 is an exploded perspective view schematically illustrating the channel C41 to house the electrically conductive member K1 and its vicinity. For example, a first O-ring 52a, a washer 54, an electrically conductive ring member 56, the electrically conductive member K1, another washer 54 and a second O-ring 52b may be inserted into the opening A41 from outside of the container 30. The sealing surface of the second plate portion 34b (i.e., the surface that faces the first plate portion 34a) has substantially the same construction as the sealing surface of the second plate portion 36b shown in FIG. 19B. Thus, by fastening the first and second plate portions 34a and 34b together, the second seating surface Bsb of the second plate portion 34b presses the first O-ring 52a against the seating surface Bsa of the first plate portion 34a through the second O-ring 52b, electrically conductive member K1 and electrically conductive ring member 56. In this manner, the electrically conductive member K1 can be sealed from the hot and cold media.

The ring portion Kr of the electrically conductive member K1 is in contact with the flat portion 56f of the electrically conductive ring member 56 inside the opening A cut through the plate 34. In this manner, the electrically conductive member K1 is electrically connected to the outer peripheral surface at the end of the thermoelectric generation tube T via the electrically conductive ring member 56. In this case, one end of the electrically conductive member K1 (i.e., the terminal portion Kt) sticks out of the plate 34 as shown in portion (a) of FIG. 23. Thus, the portion of the terminal portion Kt that protrudes to the exterior of the plate 34 functions as a terminal for connecting the thermoelectric generation unit to the external circuit. As shown in FIG. 24, the portion of the terminal portion Kt that protrudes to the exterior of the plate 34 may be formed in an annular shape. In the present specification, an electrically conductive member having a thermoelectric generation tube inserted to one end thereof, and the other end of which protrudes to the exterior, may be referred to as a “terminal plate”.

Thus, in the thermoelectric generation unit 100, the thermoelectric generation tube T1 and the thermoelectric generation tube T10 are respectively connected to two terminal plates which are housed in the terminal connections. Moreover, the plurality of thermoelectric generation tubes T1 to T10 are connected in electrical series between the two terminal plates, via the connection plates housed in the channel interconnections. Therefore, via the two terminal plates whose one end protrudes to the exterior of plate (e.g., plate 34), the electric power which is generated by the plurality of thermoelectric generation tubes T1 to T10 can be retrieved to the exterior.

The arrangements of the electrically conductive ring member 56 and electrically conductive member J, K1 may be changed appropriately inside the channel C. In that case, the electrically conductive ring member 56 and the electrically conductive member (J, K1) may be arranged so that the elastic portions 56r of the electrically conductive ring member 56 are inserted into the throughhole Jh1, Jh2 or Kh of the electrically conductive member. Also, in an implementation in which the electrically conductive ring member 56 is omitted, the end of the thermoelectric generation tube T may be electrically connected to the electrically conductive member K1. Optionally, part of the flat portion 56f of the electrically conductive ring member 56 may be extended and used in place of the terminal portion Kt of the electrically conductive member K1. In that case, the electrically conductive member K1 may be omitted.

In the embodiments described above, a channel C is formed by respective recesses cut in the first and second plate portions. However, the channel C may also be formed by a recess which has been cut in one of the first and second plate portions. If the container 30 is made of a metallic material, the inside of the channel C may be coated with an insulator to prevent electrical conduction between the electrically conductive members (i.e., the connection plates and the terminal plates) and the container 30. For example, the plate 34 (consisting of the plate portions 34a and 34b) may be comprised of a body made of a metallic material and an insulating coating which covers the surface of the body at least partially. Likewise, the plate 36 (consisting of the plate portions 36a and 36b) may also be comprised of a body made of a metallic material and an insulating coating which covers the surface of the body at least partially. If the respective surfaces of the recesses cut in the first and second plate portions are coated with an insulator, the insulating coating can be omitted from the surface of the electrically conductive member.

### <Another Exemplary Structure to Establish Sealing and Electrical Connection>

FIG. 25 is a cross-sectional view schematically illustrating an exemplary structure for separating the medium which flows in contact with the outer peripheral surfaces of the thermoelectric generation tubes T from the medium which flows in contact with the inner peripheral surface of each of the thermoelectric generation tubes T1 to T10 so as to prevent those media from mixing together. In the example illustrated in FIG. 25, a bushing 60 is inserted from outside of the container 30, thereby separating the hot and cold media from each other and electrically connecting the thermoelectric generation tube and the electrically conductive member together.

In the example illustrated in FIG. 25, the opening A41 cut through the plate 34u has an internal thread portion Th34. More specifically, the wall surface of the recess R34 that has been cut with respect to the opening A41 of the plate 34u is threaded. The bushing 60 with an external thread portion Th60 is inserted into the recess R34. The bushing 60 has a throughhole 60a that runs in the axial direction. In this case, the end of the thermoelectric generation tube T1 has been inserted into the opening A41 of the plate 34u. Thus, when the bushing 60 is inserted into the recess R34, the throughhole 60a communicates with the internal flow path of the thermoelectric generation tube T1.

Inside the space left between the recess R34 and the bushing 60, various members are arranged to establish sealing and electrical connection. In the example illustrated in FIG. 25, an O-ring 52, the electrically conductive member K1 and the electrically conductive ring member 56 are arranged in this order from the seating surface Bsa of the plate 34u toward the outside of the container 30. The end of the thermoelectric generation tube T1 is inserted into the respective holes of these members. The O-ring 52 is in contact with the seating surface Bsa of the plate 34u and the outer peripheral surface at the end of the thermoelectric generation tube T1. In this case, when the external thread portion Th60 is inserted into the internal thread portion Th34, the external thread portion Th60 presses the O-ring 52 against the seating surface Bsa via the flat portion 56f of the electrically conductive ring member 56 and the electrically conductive member K1. As a result, sealing can be established so as to prevent the fluid supplied into the shell 32 and the fluid supplied into the internal flow path of the thermoelectric generation tube T1 from mixing with each other. In addition, since the outer peripheral surface of the thermoelectric generation tube T1 is in contact with the elastic portions 56r of the electrically conductive ring member 56 and since the flat portion 56f of the electrically conductive ring member 56 is in contact with the ring portion Kr of the electrically conductive member K1, the thermoelectric generation tube and the electrically conductive member can be electrically connected together.

Thus, by using the members shown in FIG. 25, the hot and cold media can be separated from each other, and the thermoelectric generation tube and the electrically conductive member can be electrically connected together with a simpler construction.

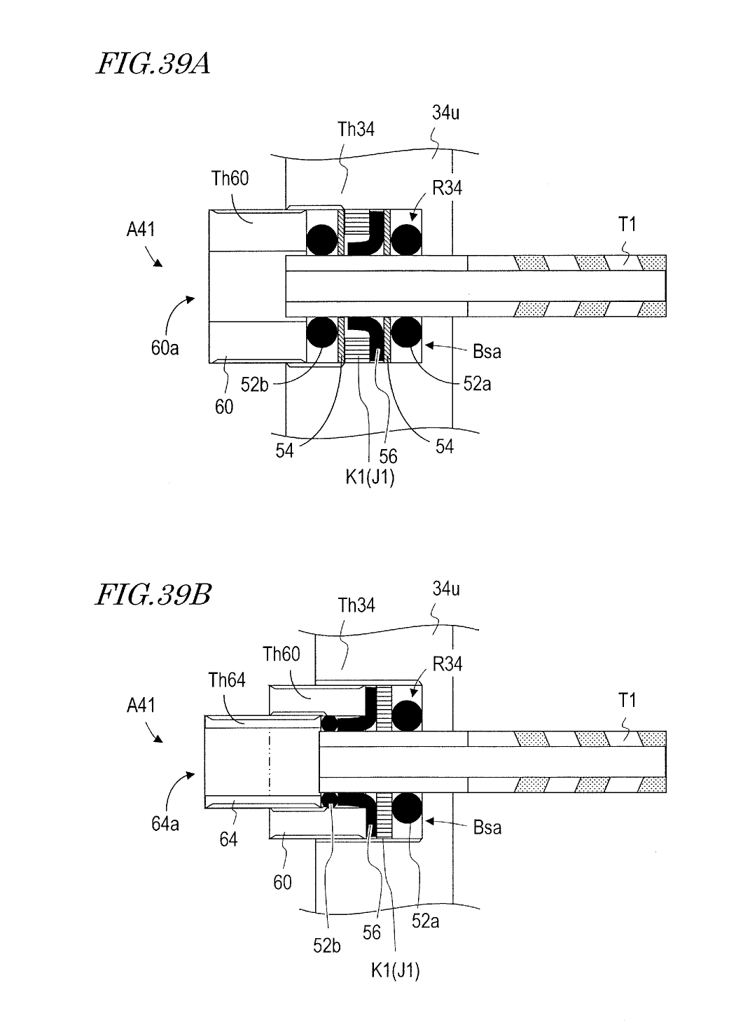

FIGS. 39A and 39B are cross-sectional views schematically illustrating two other exemplary structures for separating the hot and cold media from each other and electrically connecting the thermoelectric generation tube and the electrically conductive member together. Specifically, in the example shown in FIG. 39A, a first O-ring 52a, a washer 54, the electrically conductive ring member 56, the electrically conductive member K1, another washer 54 and a second O-ring 52b are arranged in this order from the seating surface Bsa of the plate 34u toward the outside of the container 30. In the example illustrated in FIG. 39A, the external thread portion Th60 presses the O-ring 52a against the seating surface Bsa via the electrically conductive member K1 and the flat portion 56f of the electrically conductive ring member 56. On the other hand, in the example shown in FIG. 39B, a first O-ring 52a, the electrically conductive member K1, the electrically conductive ring member 56 and a second O-ring 52b are arranged in this order from the seating surface Bsa of the plate 34u toward the outside of the container 30. In addition, in FIG. 39B, another bushing 64 with a throughhole 64a has been inserted into the throughhole 60a of the bushing 60. The throughhole 64a also communicates with the internal flow path of the thermoelectric generation tube T1. In the example illustrated in FIG. 39B, the external thread portion Th64 of the bushing 64 presses the second O-ring 52b against the seating surface Bsa. Sealing from both of the fluids (the hot and cold media) can be established by arranging the first and second O-rings 52a and 52b in this manner. By establishing sealing from both of the fluids (the hot and cold media), corrosion of the electrically conductive ring member 56 can be reduced.

As described above, one end of the terminal portion Kt of the electrically conductive member K1 sticks out of the plate 34u and can function as a terminal to connect the thermoelectric generator unit to an external circuit. In the implementations shown in FIGS. 25, 39A and 39B, the electrically conductive member K1 (terminal plate) may be replaced with a connection plate such as the electrically conductive member J1. In that case, the end of the thermoelectric generation tube T1 is inserted into the throughhole Jh1. If necessary, a washer 54 may be arranged between the O-ring and the electrically conductive member, for example.

### <Embodiment of Thermoelectric Generation System>

Next, an embodiment of a thermoelectric generation system according to the present disclosure will be described.

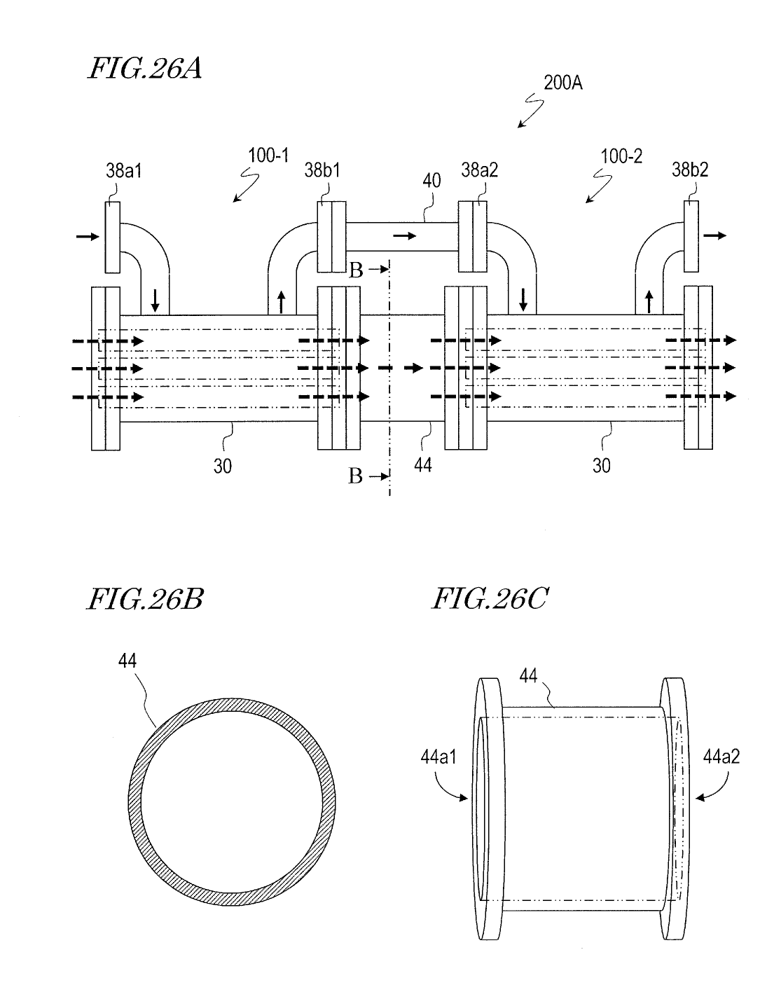

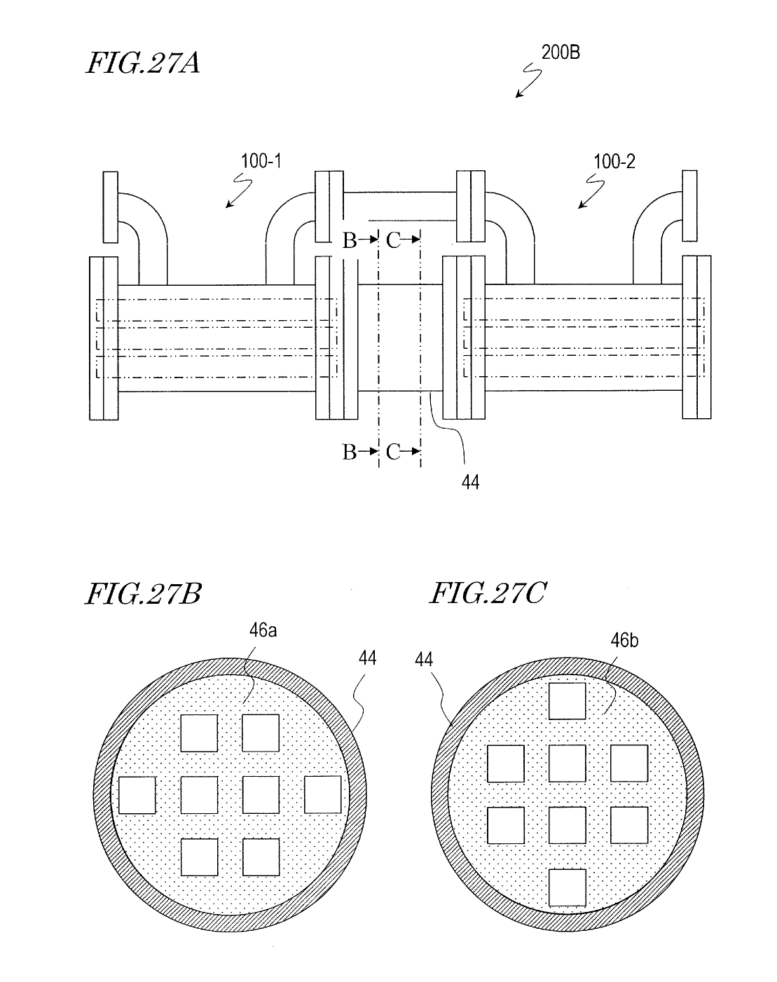

FIG. 26A illustrates an embodiment of a thermoelectric generation system according to the present disclosure. FIG. 26B is a cross-sectional view of the system taken along line B-B shown in FIG. 26A. FIG. 26C is a perspective view illustrating an exemplary construction for a buffer vessel included in the thermoelectric generation system shown in FIG. 26A. In FIG. 26A, bold solid arrows generally indicate the flow direction of the medium in contact with the outer peripheral surface of a thermoelectric generation tube (i.e., the medium flowing inside of the container 30 (and outside of the thermoelectric generation tube)). On the other hand, bold dashed arrows generally indicate the flow direction of the medium in contact with the inner peripheral surface of a thermoelectric generation tube (i.e., the medium flowing through the throughhole (i.e., the inner flow path) of the thermoelectric generation tube). In the present specification, a path communicating with the fluid inlet port and outlet ports of each container 30 may occasionally be referred to as a “first medium path” and a path encompassing the flow path of each thermoelectric generation tube may occasionally be referred to as a “second medium path” hereinbelow.

The thermoelectric generation system 200A shown in FIG. 26A includes first and second thermoelectric generator units 100-1 and 100-2, each of which has the same construction as the thermoelectric generator unit 100 described above. This thermoelectric generation system 200A further includes a thick circular cylindrical buffer vessel 44 which is arranged between the first and second thermoelectric generator units 100-1 and 100-2. This buffer vessel 44 has a first opening 44a1 communicating with the respective flow paths of multiple thermoelectric generation tubes in the first thermoelectric generator unit 100-1 and a second opening 44a2 communicating with the respective flow paths of multiple thermoelectric generation tubes in the second thermoelectric generator unit 100-2.

In this thermoelectric generation system 200A, the medium that has been introduced through the fluid inlet port 38a1 of the first thermoelectric generator unit 100-1 sequentially flows through the container 30 of the first thermoelectric generator unit 100-1, the fluid outlet port 38b1 of the first thermoelectric generator unit 100-1, a conduit 40, the fluid inlet port 38a2 of the second thermoelectric generator unit 100-2 and the container 30 of the second thermoelectric generator unit 100-2 in this order to reach a fluid outlet port 38b2 (which is the first medium path). That is, the medium that has been supplied into the container 30 of the first thermoelectric generator unit 100-1 is supplied to the inside of the container 30 of the second thermoelectric generator unit 100-2 through the conduit 40. It should be noted that this conduit 40 does not need to be straight, but may be bent.

On the other hand, the internal flow paths of the multiple thermoelectric generation tubes in the first thermoelectric generator unit 100-1 communicate with the internal flow paths of the multiple thermoelectric generation tubes in the second thermoelectric generator unit 100-2 through the first and second openings 44a1 and 44a2 of the buffer vessel 44 (which is the second medium path). The medium that has been introduced into the respective internal flow paths of the multiple thermoelectric generation tubes in the first thermoelectric generator unit 100-1 becomes confluent with each other in the buffer vessel 44, and then introduced into the respective internal flow paths of the multiple thermoelectric generation tubes in the second thermoelectric generator unit 100-2.

In a thermoelectric generation system including a plurality of thermoelectric generator units, the second medium path encompassing the flow paths of the respective thermoelectric generation tubes may be designed arbitrarily. Note that the degree of heat exchange to be carried out in a single container 30 via multiple thermoelectric generation tubes may vary from one generator to another. For this reason, between two adjacent thermoelectric generator units, if the internal flow paths of the respective thermoelectric generation tubes in one thermoelectric generator unit are connected in series to the internal flow paths of the respective thermoelectric generation tubes in the other thermoelectric generator unit, the temperature of the medium flowing through the internal flow paths will vary even more. With increased variations in the temperature of the medium among the internal flow paths of the respective thermoelectric generation tubes, the power output levels of the respective thermoelectric generation tubes may also vary from one generator to another.

In this thermoelectric generation system 200A, the medium that has flowed through the respective internal flow paths of the multiple thermoelectric generation tubes in the first thermoelectric generator unit 100-1 into the buffer vessel 44 exchanges heat in the buffer vessel 44, and then is supplied to the internal flow paths of the multiple thermoelectric generation tubes in the second thermoelectric generator unit 100-2. Since the medium that has flowed through the internal flow paths of the multiple thermoelectric generation tubes in the first thermoelectric generator unit 100-1 into the buffer vessel 44 exchanges heat in the buffer vessel 44, the temperature of the medium can become uniform. By thus mixing the medium flowing through the internal flow path of one thermoelectric generation tube with the medium flowing through the internal flow path of another thermoelectric generation tube, the temperature of the media flowing through the respective internal flow paths of multiple thermoelectric generation tubes can become uniform, which is advantageous.

In the example illustrated in FIG. 26A, the second medium path is designed so that the fluid flows in the same direction through the respective flow paths of multiple thermoelectric generation tubes T. However, the flow direction of the fluid through the flow paths of multiple thermoelectric generation tubes T does not need to be the same direction. The flow direction of the fluid through the flow paths of multiple thermoelectric generation tubes T may be set in various manners according to the design of the flow paths of the hot and cold media. Also, in the thermoelectric generation system of the present disclosure, multiple thermoelectric generator units may be connected either in series to each other or parallel with each other.

### <Another Embodiment of Thermoelectric Generation System>

FIG. 27A illustrates another embodiment of a thermoelectric generation system according to the present disclosure. FIG. 27B is a cross-sectional view of the system taken along line B-B shown in FIG. 27A. FIG. 27C is a cross-sectional view of the system taken along line C-C shown in FIG. 27A.

In the thermoelectric generation system 200B of the present embodiment, the buffer vessel 44 has two baffle plates 46a and 46b inside. A number of rectangular openings are cut through one of these two baffle plates 46a or 46b, and a number of rectangular openings are also cut through the other baffle plate 46b or 46a, the distribution pattern of rectangular openings being dissimilar between the two baffle plates 46a and 46b (see FIGS. 27B and 27C). The medium flowing inside the buffer vessel 44 passes through those openings cut through each of the two baffle plates 46a, 46b, whereby a turbulent flow is generated and a stirring effect emerges to promote uniformity of the temperature of the medium. In this manner, the buffer vessel 44 may have such a baffle structure for disturbing the flow of the fluid which has flowed into the buffer vessel 44 through the respective flow paths of those thermoelectric generation tubes.

It suffices if the baffle plates 46a, 46b have such a shape as to at least partially change the flow direction of the fluid. Thus, the shape, size and locations of those openings cut through the baffle plates 46a, 46b are not limited to the illustrated examples, but may be set arbitrarily. Each baffle plate may be divided into multiple pieces, and each opening may be a slit. Any arbitrary number of baffle plates may be provided. For example, the stirring effect can also be achieved with only one baffle plate. The baffle plate does not need to have a flat plate shape, but may have a helical, radial or grid shape.

So long as the effect of uniformizing the temperature distribution by stirring the medium is achieved, any structure other than baffle plates may either be provided inside of the buffer vessel, or form part of the buffer vessel. For example, the inner wall of the buffer vessel 44 may have unevenness, fins, or grooves. Alternatively, the buffer vessel 44 may be narrowed in the middle.

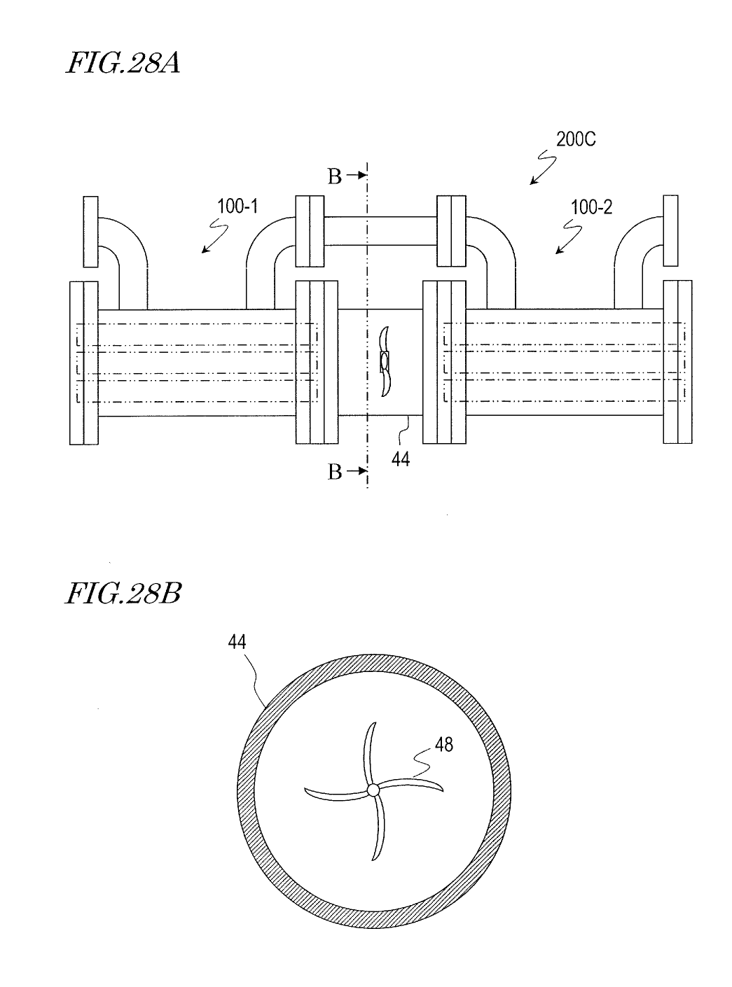

FIG. 28A illustrates yet another embodiment of a thermoelectric generation system according to the present disclosure. FIG. 28B is a cross-sectional view of the system taken along line B-B shown in FIG. 28A.

The structure arranged inside the buffer vessel 44 may include a movable portion to change at least partially the flow direction of the fluid that has flowed into the buffer vessel 44. In the thermoelectric generation system 200C of the present embodiment, the buffer vessel 44 internally has rotating blades 48. The blades 48 are supported rotatably by a supporting member (not shown) and rotated by the medium flow. The blades 48 may be driven by an external power unit such as a motor. As the blades 48 rotate, a turbulent flow is generated and the stirring effect is produced to make the temperature of the medium more uniform. Even if fixed so as not to rotate, the blades 48 still disturb the medium flow as would a baffle plate, thus allowing for more uniform medium temperature. If necessary, multiple sets of blades 48 (or propellers) may be provided inside the buffer vessel 44.

Instead of in addition to the blades 48, any other stirring mechanism which is rotated, swung or deformed by the medium flow may also be provided inside the buffer vessel 44.

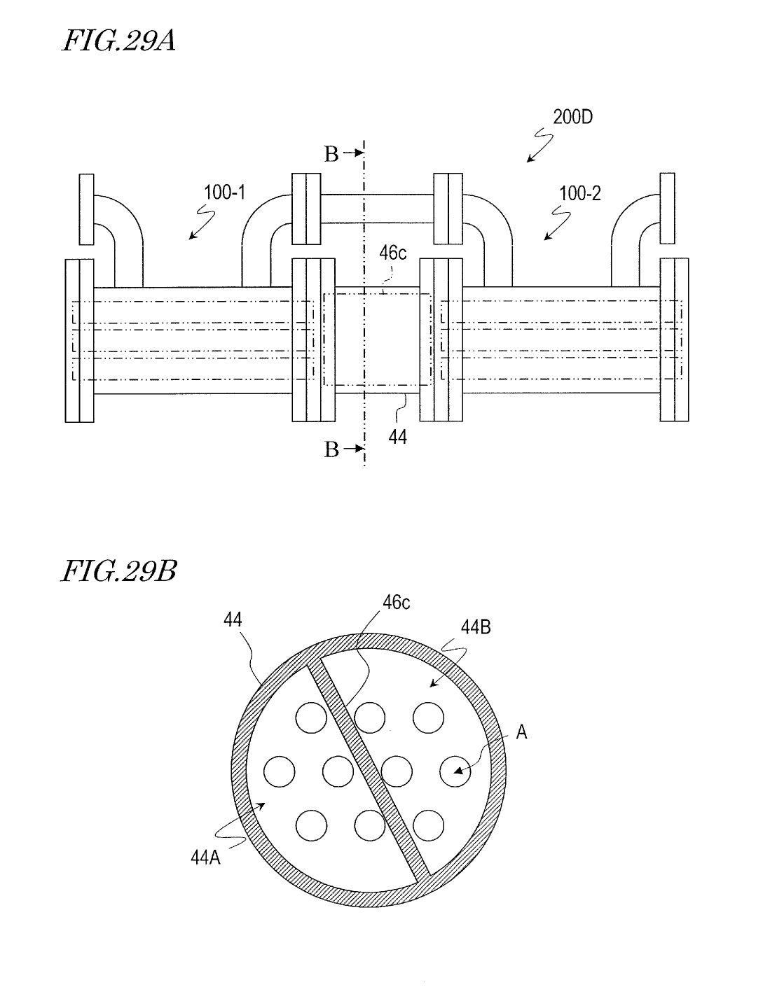

FIG. 29A illustrates yet another embodiment of a thermoelectric generation system according to the present disclosure. FIG. 29B is a cross-sectional view of the system taken along line B-B shown in FIG. 29A.

In the thermoelectric generation system 200D of the present embodiment, the buffer vessel 44 has a partition 46c inside. Thus, the space inside of the buffer vessel 44 is divided into two spaces 44A and 44B. For example, as shown in FIG. 29B, the space 44A communicates with half of the openings A cut through the container of the second thermoelectric generator unit 100-2. On the other hand, the space 44B communicates with the other half of the openings A cut through the container of the second thermoelectric generator unit 100-2.

In this thermoelectric generation system 200D, part of the medium flows into the space 44A inside the buffer vessel 44 from a half of the thermoelectric generation tubes in the first thermoelectric generator unit 100-1. The rest of the medium flows into the space 44B from the other half of the thermoelectric generation tubes in the first thermoelectric generator unit 100-1. In each of the two spaces 44A and 44B created inside the buffer vessel 44, the medium that has flowed in from the respective internal flow paths of the thermoelectric generation tubes of the first thermoelectric generator unit 100-1 is subjected to heat exchange. In this manner, the inside of the buffer vessel 44 may be divided into multiple spaces and the medium that has flowed into the buffer vessel 44 may be subjected to heat exchange in each divided space.

The shape, number and arrangement of the partition 44c do not need to be those shown in the figures, but may be determined arbitrarily. When three or more thermoelectric generator units are connected together in series, the shape, number or arrangement of the partitions 44c may be varied from one buffer vessel, inserted between two adjacent ones of the thermoelectric generator unit, to another. In that case, the medium temperature can be made even more uniform.

The baffles (e.g., baffle plates), stirring mechanism, and partitions that have been described with reference to FIGS. 27A through 29B may be used in combination. If three or more thermoelectric generator units are connected together in series, the buffer vessel 44 may be inserted either between each pair of two adjacent thermoelectric generator units or between only some pair(s) of two adjacent thermoelectric generator units.

Alternatively, the baffles, stirring mechanism and partitions may be provided inside the container 30. For example, when the hot medium flows through the internal flow paths of the thermoelectric generation tubes, the cold medium flows inside the container 30. The cold medium is heated by the thermoelectric generation tubes in the container 30 to have its temperature raised locally. However, the temperature of the cold medium remains relatively low distant from the thermoelectric generation tubes. Thus, by disturbing the flow of the cold medium inside the container 30 with the baffles or stirring mechanism, the temperature distribution of the cold medium can be made more uniform, and the temperature of the cold medium can be lowered in a region where the cold medium is in contact with the thermoelectric generation tubes.

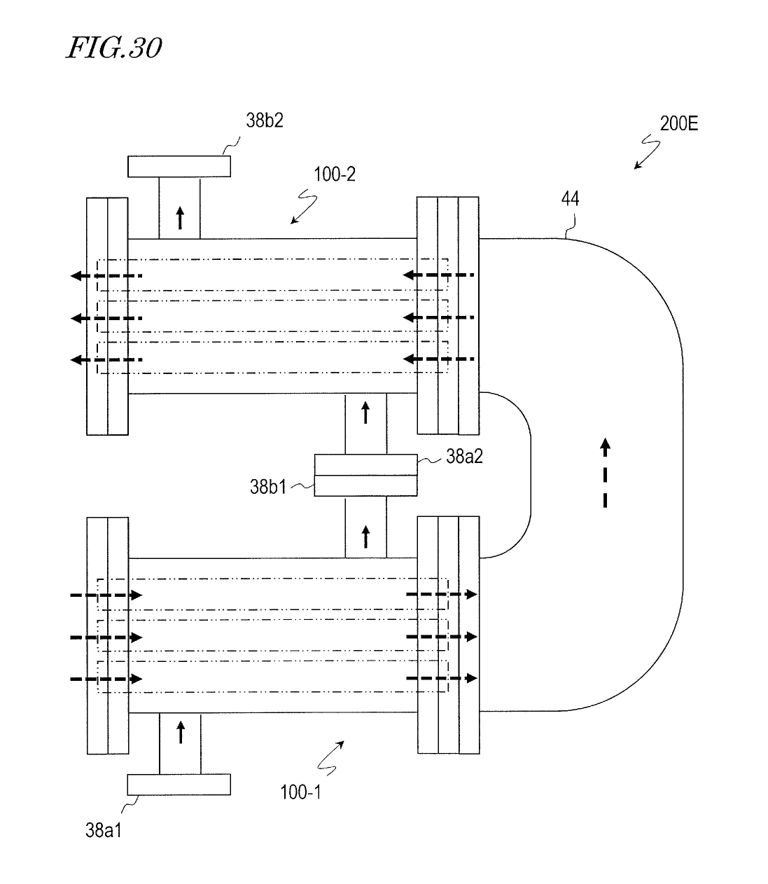

Next, look at FIG. 30, which illustrates still another exemplary construction for a thermoelectric generation system according to the present disclosure. In FIG. 30, the bold solid arrows generally indicate the flow direction of the medium in contact with the outer peripheral surface of a thermoelectric generation tube. On the other hand, the bold dashed arrows generally indicate the flow direction of the medium in contact with the inner peripheral surface of the thermoelectric generation tube as in FIG. 26A. This thermoelectric generation system 200E is constructed so that the flow direction of the fluid flowing through the respective flow paths of the multiple thermoelectric generation tubes T in the first thermoelectric generator unit 100-1 is antiparallel to that of the fluid flowing through the respective flow paths of the multiple thermoelectric generation tubes T in the second thermoelectric generator unit 100-2.

In this thermoelectric generation system 200E, the first and second thermoelectric generator units 100-1 and 100-2 are arranged spatially parallel with each other. For example, the second thermoelectric generator unit 100-2 may be arranged by the first thermoelectric generator unit 100-1. Note that the first and second thermoelectric generator units 100-1 and 100-2 may be vertically stacked one upon the other. In that case, the medium will flow vertically through the first medium path.

As shown in FIG. 30, the buffer vessel 44 may have a bent shape. As can be seen, in a thermoelectric generation system according to the present disclosure, the flow paths for hot and cold media may be designed in various manners. For example, the flow paths may be designed flexibly according to the area of the place where the thermoelectric generation system is installed. The arrangements shown in FIGS. 26A through 30 are mere examples. Rather, the first medium path communicating with the fluid inlet port and outlet port of each container and the second medium path encompassing the respective flow paths of the thermoelectric generation tubes may be designed arbitrarily. Also, those thermoelectric generator units may be electrically connected either in series to each other or parallel with each other.

### <Exemplary Construction of an Electric Circuit Included in the Thermoelectric Generation System>

Next, with reference to FIG. 31, an exemplary construction of an electric circuit included in the thermoelectric generation system according to the present disclosure will be described.

In the example of FIG. 31, a thermoelectric generation system 200 according to the present embodiment includes an electric circuit 250 which receives the electric power that is output from the thermoelectric generation units 100-1 and 100-2. In other words, in one implementation, at least one of the plurality of electrically conductive members may have an electric circuit connected thereto, the electric circuit being electrically connected to the plurality of thermoelectric generation tubes.

The electric circuit 250 includes a boost converter 252 which boosts the voltage of the electric power that is output from the thermoelectric generation units 100-1 and 100-2, and an inverter (DC-AC inverter) circuit 254 which converts the DC power that is output from the boost converter 252 into AC power (whose frequency may be e.g. 50/60 Hz or any other frequency). The AC power which is output from the inverter circuit 254 may be supplied to a load 400. The load 400 may be any of various electrical devices or electronic devices that operate by using AC power. The load 400 may in itself have a charging function, and does not need to be fixed on the electric circuit 250. Any AC power that has not been consumed by the load 400 may be connected to a commercial grid 410, thus to sell electricity.

The electric circuit 250 in the example of FIG. 31 includes a charge-discharge control section 262 and an accumulator 264 for storing the DC power that is obtained from the thermoelectric generation units 100-1 and 100-2. The accumulator 264 may be a chemical battery such as a lithium ion secondary battery, or a capacitor such as an electric double-layer capacitor, for example. As necessary, the electric power which is stored in the accumulator 264 may be fed to the boost converter 252 by the charge-discharge control section 262, and, via the inverter circuit 254, used or sold as AC power.

The level of electric power which is obtained from the thermoelectric generation units 100-1 and 100-2 may fluctuate over time, either periodically or irregularly. For example, when the heat source for the hot medium is waste heat from a factory, the temperature of the hot medium may fluctuate depending on the operating schedule of the factory. In such a case, the state of power generation of the thermoelectric generation units 100-1 and 100-2 may fluctuate, thus causing the voltage and/or electric current of the electric power obtained from the thermoelectric generation units 100-1 and 100-2 to fluctuate in magnitude. Despite such fluctuations in the state of power generation, the thermoelectric generation system 200 shown in FIG. 31 can suppress the influence of fluctuations of power generation output by storing electric power in the accumulator 264 via the charge-discharge control circuit 262.

In the case where electric power is to be consumed in real time along with the power generation, the boost ratio of the boost converter 252 may be adjusted according to the fluctuations in the state of power generation. Moreover, fluctuations in the state of power generation may be detected or predicted, and the flow rate, temperature, or the like of the hot medium or cold medium to be supplied to the thermoelectric generation units 100-1 and 100-2 may be adjusted, thus achieving a control to maintain the state of power generation to be in a stationary state.

FIG. 13 is referred to again. In the exemplary system illustrated in FIG. 13, the flow rate of the hot medium can be adjusted with a pump P1. Similarly, the flow rate of the cold medium can be adjusted with a pump P2. By adjusting the flow rate of both or one of the hot medium and the cold medium, it is possible to control the power generation output from the thermoelectric generation tube.

It is also possible to control the temperature of the hot medium by adjusting the amount of heat to be supplied to the hot medium from a high-temperature heat source not shown. Similarly, it is also possible to control the temperature of the cold medium by adjusting the amount of heat to be released from the cold medium to a low-temperature heat source not shown.

Although not shown in FIG. 13, a valve and branches may be provided for at least one of the flow path of the hot medium and the flow path of the cold medium, thus adjusting the flow rate of the respective medium supplied to the thermoelectric generation system.

### <Another Embodiment of Thermoelectric Generation System>

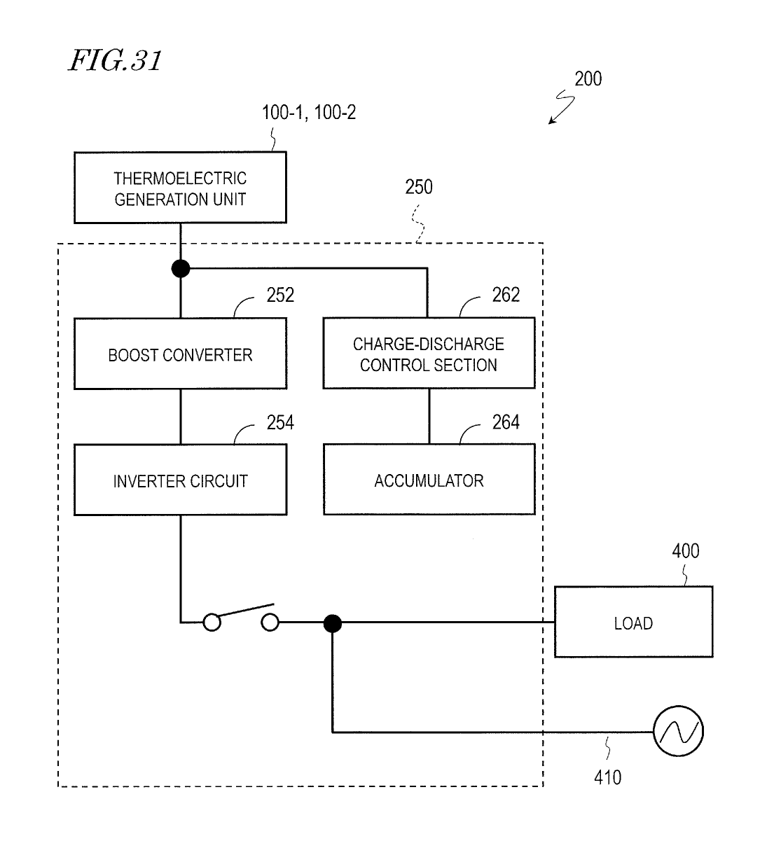

Another embodiment of a thermoelectric generation system according to the present disclosure will now be described with reference to FIG. 32.

In the present embodiment, thermoelectric generator units (such as the thermoelectric generator unit 100-1, 100-2) are provided for a general waste disposal facility (that is, a so-called “garbage disposal facility” or a “clean center”). In recent years, at a waste disposal facility, high-temperature, high-pressure steam (at a temperature of 400 to 500 degrees Celsius and at a pressure of several MPa) is sometimes generated from the thermal energy produced when garbage (waste) is incinerated. Such steam energy is converted into electricity by turbine generator and the electricity thus generated is used to operate the equipment in the facility.

The thermoelectric generation system 300 of the present embodiment includes a plurality of thermoelectric generator units. In the example illustrated in FIG. 32, the hot medium supplied to the thermoelectric generator units 100-1 and 100-2 has been produced based on the heat of combustion generated at the waste disposal facility. More specifically, this system includes an incinerator 310, a boiler 320 to produce high-temperature, high-pressure steam based on the heat of combustion generated by the incinerator 310, and a turbine 330 which is driven by the high-temperature, high-pressure steam produced by the boiler 320. The energy generated by the turbine 330 driven is given to a synchronous generator (not shown), which converts the energy into AC power (such as three-phase AC power).

The steam that has been used to drive the turbine 330 is turned back into liquid water by a condenser 360, and then is supplied by a pump 370 to the boiler 320. This water is a working medium that circulates through a “heat cycle” formed by the boiler 320, turbine 330 and condenser 360. Part of the heat given by the boiler 320 to the water does work to drive the turbine 330 and then is given by the condenser 360 to cooling water. In general, cooling water circulates between the condenser 360 and a cooling tower 350 as indicated by the dotted arrows in FIG. 32.

Thus, only a part of the heat generated by the incinerator 310 is converted by the turbine 330 into electricity, and the thermal energy that the low-temperature, low-pressure steam possesses after the turbine 330 is rotated is often not converted into, and used as, electrical energy, but instead dumped into the ambient conventionally. According to the present embodiment, however, the low-temperature steam or hot water that has done work at the turbine 330 can be used effectively as a heat source for the hot medium. In the present embodiment, heat is obtained by the heat exchanger 340 from the steam at such a low temperature (e.g. 140 degrees Celsius) and hot water of e.g. 99 degrees Celsius is obtained. This hot water is supplied as the hot medium to the thermoelectric generator units 100-1, 100-2.

As the cold medium, on the other hand, a part of the cooling water used at a waste disposal facility may be utilized, for example. When the waste disposal facility has the cooling tower 350, water at about 10 degrees Celsius can be obtained from the cooling tower 350 and used as the cold medium. Alternatively, the cold medium does not need to be obtained from a special cooling tower, but may also be well water or river water inside the facility or in the neighborhood.

The thermoelectric generator units 100-1, 100-2 shown in FIG. 32 may be connected to the electric circuit 250 shown in FIG. 31, for example. The electricity generated by the thermoelectric generator units 100-1, 100-2 may be either used in the facility, or accumulated in the accumulator 264. Any extra electric power may be converted into AC power and then sold through the commercial grid 410.

The thermoelectric generation system 300 shown in FIG. 32 has a construction in which a plurality of thermoelectric generator units are incorporated into the waste heat utilization system of a waste disposal facility that includes the boiler 320 and the turbine 330. However, the boiler 320, turbine 330, condenser 360 and heat exchanger 340 are not indispensable elements to operate the thermoelectric generator units 100-1, 100-2. If there is any gas or hot water of relatively low temperature which would conventionally have been disposed of, such gas or water can be effectively used as the hot medium in a direct manner, or utilized to heat another gas or liquid with a heat exchanger, which can then be used as a hot medium. The system shown in FIG. 32 is just one of many practical examples.

As is clear from the foregoing description of embodiments, an embodiment of a thermoelectric generation system according to the present disclosure can collect and effectively utilize such thermal energy as has conventionally been dumped into the ambient unused. For example, by generating a hot medium based on the heat of combustion of garbage at a waste disposal facility, the thermal energy of a gas or hot water of relatively low temperature, which would conventional have been disposed of, can be effectively utilized.

Note that an exemplary production method for a thermoelectric generation system according to the present disclosure includes: a step of providing the aforementioned plurality of thermoelectric generation tubes; a step of inserting the plurality of thermoelectric generation tubes into a plurality of openings of first and second containers each having the above construction so that the plurality of thermoelectric generation tubes are retained inside the first and second containers; a step of providing electrical connection between the plurality of thermoelectric generation tubes with a plurality of electrically conductive members; and a step of placing a buffer vessel between the first container and the second container, the buffer vessel having a first opening communicating with the respective flow paths of the plurality of thermoelectric generation tubes retained inside the first container, and a second opening communicating with the respective flow paths of the plurality of thermoelectric generation tubes retained inside the second container.

Moreover, an exemplary electric generation method according to the present disclosure includes a step of allowing a first medium to flow in each container of the aforementioned thermoelectric generation system via a fluid inlet port and a fluid outlet port of the container, so that the first medium is in contact with the outer peripheral surface of the respective thermoelectric generation tube; a step of allowing a second medium having a different temperature from a temperature of the first medium to flow in the flow path in each thermoelectric generation tube; and a step of retrieving power generated in the plurality of thermoelectric generation tubes via a plurality of electrically conductive members.

A thermoelectric generator unit according to the present disclosure may be used by itself, without being connected with other units via the buffer vessel. An exemplary thermoelectric generator unit according to the present disclosure includes a plurality of thermoelectric generation tubes, each of which has an outer peripheral surface, an inner peripheral surface and a flow path defined by the inner peripheral surface, and is configured to generate electromotive force in an axial direction of each thermoelectric generation tube based on a difference in temperature between the inner and outer peripheral surfaces. Typically, such thermoelectric generation tubes are electrically connected together in series via a plurality of plate electrically conductive members. Such electrically conductive members may be located inside or outside of the container that surrounds the thermoelectric generation tubes so long as the plate electrically conductive members are insulated from the heat transfer medium.

The thermoelectric generation system according to the present disclosure can be used as an electric generator that utilizes the heat of effluent gas, etc., which is discharged from an automobile, a factory, or the like.

While the present invention has been described with respect to exemplary embodiments thereof, it will be apparent to those skilled in the art that the disclosed invention may be modified in numerous ways and may assume many embodiments other than those specifically described above. Accordingly, it is intended by the appended claims to cover all modifications of the invention that fall within the true spirit and scope of the invention.

What is claimed is:

1. A thermoelectric generator comprising:
a first electrode and a second electrode opposing each other; and
a stacked body having a first principal face and a second principal face and a first end face and a second end face, the first end face and the second end face being located between the first principal face and the second principal face, and the first electrode and the second electrode being respectively electrically connected to the first end face and the second end face, wherein,
the stacked body is structured so that a plurality of first layers of a first material having a relatively low Seebeck coefficient and a relatively high thermal conductivity and a plurality of second layers of a second material having a relatively high Seebeck coefficient and a relatively low thermal conductivity are alternately stacked;
planes of stacking of the plurality of first layers and the plurality of second layers are inclined with respect to a direction in which the first electrode and the second electrode oppose each other;
the stacked body includes a semiconductor layer or an insulator layer in at least one of the first principal face and the second principal face, and a carbon containing layer on at least a partial surface of the semiconductor layer or insulator layer; and
a potential difference occurs between the first electrode and the second electrode due to a temperature difference between the first principal face and the second principal face.

2. The thermoelectric generator of claim 1, wherein the first principal face and the second principal face are planes, and the stacked body has a rectangular solid shape.

3. The thermoelectric generator of claim 1, wherein the stacked body has a tubular shape, and the first principal face and the second principal face are, respectively, an outer peripheral surface and an inner peripheral surface of the tubular shape.

4. The thermoelectric generator of claim 1, wherein
the second material contains Bi; and
the first material does not contain Bi but contains a metal different from Bi.

5. The thermoelectric generator of claim 1, wherein the carbon containing layer includes a first portion containing the first material and carbon and a second portion containing the second material and carbon.

6. The thermoelectric generator of claim 1, wherein the stacked body is a sintered body, and the carbon containing layer is a portion of the sintered body.

7. A thermoelectric generation tube comprising the thermoelectric generator of claim 1,
the stacked body having a tubular shape.

8. A production method for a thermoelectric generator comprising:
step (A) of providing: a plurality of first compacts having a pair of planes of stacking and a first side face and a second side face being located between the pair of planes of stacking and not perpendicular to the pair of planes of stacking, the plurality of first compacts being made of a source material for a first material having a relatively low Seebeck coefficient and a relatively high thermal conductivity; and a plurality of second compacts having a pair of planes of stacking and a first side face and a second side face being located between the pair of planes of stacking and not perpendicular to the pair of planes of stacking, the plurality of second compacts being made of a source material for a second material having a relatively high Seebeck coefficient and a relatively low thermal conductivity;
step (B) of forming a multilayer compact by alternately stacking the plurality of first compacts and the plurality of second compacts so that the respective planes of stacking are in contact with each other, and that the first side faces and the second side faces of the plurality of first compacts and the plurality of second compacts respectively constitute a first principal face and a second principal face of the multilayer compact, wherein one selected from among a carbon fiber sheet, a carbon powder, and a graphite sheet is provided on at least one of the first principal face and the second principal face; and
step (C) of sintering the multilayer compact with the selected one provided thereon, wherein,
after step (C) of sintering, carbon-containing portions are not substantially eliminated from the at least one of the first principal face and the second principal face that had the selected one provided thereon.

9. The production method for a thermoelectric generator of claim 8, wherein, in step (C) of sintering, the multilayer compact is sintered while applying a pressure to the multilayer compact.

10. The production method for a thermoelectric generator of claim 9, wherein step (C) of sintering is conducted by a hot pressing technique or a spark plasma sintering technique.

11. The production method for a thermoelectric generator of claim 10, wherein each of the plurality of first compacts and the plurality of second compacts has a tubular shape of which first and second side faces define an outer peripheral surface and an inner peripheral surface, the first side face and the second side face being connected by the pair of planes of stacking, and the planes of stacking each defining side faces of a truncated cone.

12. A thermoelectric generation unit comprising a plurality of thermoelectric generation tubes of claim 7, wherein
each of the plurality of thermoelectric generation tubes has an outer peripheral surface and an inner peripheral surface, and a flow path defined by the inner peripheral surface, and generates an electromotive force in an axial direction of the thermoelectric generation tube based on a temperature difference between the inner peripheral surface and the outer peripheral surface; and
the thermoelectric generation unit further includes
a container housing the plurality of thermoelectric generation tubes inside, the container having a fluid inlet port and a fluid outlet port for allowing a fluid to flow inside the container and a plurality of openings into which the respective thermoelectric generation tubes are inserted, and
a plurality of electrically conductive members providing electrical interconnection for the plurality of thermoelectric generation tubes,
the container including:
a shell surrounding the plurality of thermoelectric generation tubes; and
a pair of plates each being fixed to the shell and having the plurality of openings, with channels being formed so as to house the plurality of electrically conductive members and interconnect at least two of the plurality of openings, wherein
respective ends of the thermoelectric generation tubes are inserted in the plurality of openings of the plates, the plurality of electrically conductive members being housed in the channels in the plates, and
the plurality of thermoelectric generation tubes are connected in electrical series by the plurality of electrically conductive members housed in the channels.

13. A thermoelectric generation system comprising:
the thermoelectric generation unit of claim 12;
a first medium path communicating with the fluid inlet port and the fluid outlet port of the container;
a second medium path encompassing the flow paths of the plurality of thermoelectric generation tubes; and
an electric circuit electrically connected to the plurality of electrically conductive members to retrieve power generated in the plurality of thermoelectric generation tubes.
